(19) United States
(12) Patent Application Publication
(10) Pub. No.: US 2005/0179565 A1
(43) Pub. Date: Aug. 18, 2005

(54) Information processor for visually disabled person and tactile input/output device

(76) Inventors: Yasufumi Mase, Chita-gun (JP); Yasuhiro Watanabe, Tokoname (JP)

Correspondence Address: OLIFF & BERRIDGE, PLC, P.O. BOX 19928, ALEXANDRIA, VA, 22320, US

(21) Appl. No.: 11/099,557

(22) Filed: Apr. 6, 2005

Related U.S. Application Data
(63) Continuation of application No. 09/787,776, filed on Mar. 26, 2001, now abandoned.

(30) Foreign Application Priority Data
Sep. 22, 1998 (JP) 10-268805
Apr. 30, 1999 (JP) 11-125399

(51) Int. Cl. H03M 11/00; H03K 17/94

(52) U.S. Cl. 341/21; 341/27; 340/825.19

(57) ABSTRACT

In an information processing apparatus for the visually impaired, information having, a structure that can be two-dimensionally expanded is divided into pieces of block unit information. The block unit information are mapped to key tops that can be set their protrusion amount from an operating plane at three different height. Attributes and descriptions are represented by sound/voice and the block unit information of a subordinate level is expanded and represented when a predetermined key top is operated. Even if the key tops are limited in number, a complicated hierarchical structure and a layout can be effectively browsed and information can be edited using voice input. Accordingly, the visually impaired can effectively read and edit information. This principal can be applied to specifying and using functions of a personal computer that is hierarchically structured and displaying drawings or mathematical expressions.

### TECHNICAL FIELD

The invention relates to an information processing apparatus for the visually impaired, in which the visually impaired can read or edit information while easily recognizing a hierarchical structure and a layout of the information including layout information and a hierarchical structure and can perform a predetermined function while easily recognizing an operating state of the information processing apparatus, and also relates to a tactile input/output apparatus used in the information processing apparatus.

### BACKGROUND ART

Japanese Laid-Open Patent Publication No. 10-232600 discloses technology for representing a document made by a word processor, with an array of key tops, such as tactile pins, and also representing characters corresponding to the key tops by voice by touching the key tops so that a visually impaired person can confirm a text, including its layout (hereinafter referred to as a prior art reference A). Further, Japanese Laid-Open Patent Publication No. 10-69218 discloses technology for using a system having a graphical user interface by the visually impaired person (hereinafter referred to as a prior art reference B).

However, the prior art references have the following problems.

1. In the prior art reference A, when a number of characters are included in a sentence, a plurality of display dots 1a are needed. Therefore, a tactile input/output apparatus becomes expensive and large in size.

2. The display dots 1a can be operated only for confirming characters corresponding to the display dots 1a by voice. Therefore, a type of information to be read can not be switched according to an operating pattern.

3. Functions of the information processing apparatus are performed by selecting it on a menu screen appearing on a display. However, the visually impaired person can not see the display. Therefore, in the prior art B, windows to be displayed on the screen and operation parts are represented using a plurality of tactile cells 1 including a plurality of tactile pins 3. However, the tactile cells 1 are fixedly positioned, so that a parent-child relationship of functions corresponding to the tactile cells 1 can not be represented. Accordingly, a user's desired function can not be performed by selecting it from hierarchically structured program functions.

4. The prior art references are useful to confirm a layout by the character. However, a layout of entire sentence can not be displayed in a way easy to understand. For example, even when the tactile input/output apparatus can be manufactured in small size at low cost and all characters are displayed on the apparatus, a layout and a structure of appropriate groups structuring a document, such as “complements of the season”, an “address” and a “body” as shown in FIGS. 11 and 12, can not be recognized through intuition and a subordinate structure can not be expanded and read as necessary. Accordingly, sentences can not be read in a way easy to understand.

5. In order that the visually impaired person can read necessary information by selecting it by his/herself, it is necessary to propose a method for appropriately selecting a desired sentence from a plurality of documents hierarchically classified as in a library. Further, a method that a desired portion in the sentence can be easily specified and details can be looked through needs to be proposed. However, the prior art A discloses only technology that a layout of a character string in several lines can be confirmed by which a character is assigned to one or two display dots 1a. Further, the prior art B discloses only technology for representing a structure of a window of a program. Therefore, the aforementioned subjects have yet to be accomplished.

6. A change of setting of key tops according to display conditions may be effective. For example, it is effective if the setting of the key tops is changed to show that view can be expanded into other key tops or to show whether the view has been expanded into other key tops, when the key top is operated. However, the change of the setting of the key tops can not be made in the prior art references.

7. In the prior art reference A, when a table is represented with the display dots 1a, a blank line is used in order to distinguish characters from ruled lines. However, in this method, a number of the display dots 1a become needed.

8. In the prior art references, it is nagging because sound representing such as a text or a window name is output only by touching the display dot 1a or the tactile pin 3 to confirm a display pattern.

9. In the prior art reference A, in order to modify description of a sentence, the sentence needs to be edited using word processor software. Therefore, the operation is complicated. It is desired that a method that modification information can be easily input by specifying a portion needing to be modified in the sentence using a tactile display is to be proposed. However, this method can not be used in the prior art reference A.

10. There has been proposed an idea that a monochrome photograph is expressed in relief with a plurality of tactile pins. However, the prior art reference A has relatively small number of display dots 1a, so that it is difficult to express details of the photograph.

11. The prior art reference B discloses technology for displaying a hierarchical structure of parts in a window with the tactile pins 3 in the tactile cell 1. However, an information processing method for inputting information having the hierarchical structure and displaying the information on the tactile display is not disclosed in the prior art reference B. Therefore, it is unknown how to achieve the information processing in the prior art reference B.

12. In the prior art references, a structure of the display dots 1a and the tactile pins 3 whose amount of protrusion can be individually controlled is not described in detail. In order to individually control the amount of protrusion, a plurality of actuators and complicated mechanisms are needed resulting in increased costs and upsizing of the tactile input/output apparatus. Accordingly, the tactile input/output apparatus is interfered with the widespread use.

It is an object of the invention to provide an information processing apparatus for the visually impaired and a tactile input/output apparatus that can solve the conventional problems described above.

### DISCLOSURE OF INVENTION

In order to achieve the technical problems described above, an information processing apparatus for the visually impaired claimed in claim 1 of the invention includes a plurality of tactile operation means that can be set in two or more identification states based on tactile operation with a fingertip in a predetermined area that is one of areas individually set, and are arranged in a two-dimensional matrix with rows and columns so that the operation performed in the predetermined area can be detected; operation signal selecting means that selects and outputs an operation signal corresponding to a predetermined operating method based on the operation performed in the predetermined area; information storage means that stores information having a data structure that can be two-dimensionally expanded, by dividing the information into a plurality of pieces of block unit information, and stores a correspondence between the block information and the plurality of tactile operation means; information setting means that sets predetermined information in the information storage means; tactile operation means setting means that sets the plurality of the tactile operation means in respective predetermined states based on the tactile operation means setting information; tactile operation means setting information supply means that receives input of information related to a correspondence with the tactile operation means stored in the information storage means and supplies the tactile operation means setting information to the tactile operation means setting means; sound generating means that generates sound by inputting sound related information; sound related information supply means that receives input of the operation signal and selects and supplies the sound related information by reading the block unit information corresponding to the operated tactile operation means; and information modification means that receives input of the operation signal and modifies a content in the information storage means in accordance with the operated tactile operation means.

With this structure, information having a structure that can be two-dimensionally expanded is stored by dividing into pieces of block unit information. The block unit information are assigned to tactile operation means of a tactile input/output apparatus. The block unit information that are assigned to the tactile operation means according to operation can be represented by sound/voice. Therefore, even when information includes a plurality of numbers of characters that is far larger in number than the number of the tactile operation means, the information can be effectively browsed in the tactile input/output apparatus having limited numbers of the tactile operation means when a visually impaired person browses the information.

In the information processing means for the visually impaired as claimed in claim 1, the invention claimed in claim 2 is that at least one piece of block unit information include display information regarding a display and attribute information regarding the display information, the operation signal selecting means selects at least a display browse signal according to operation for browsing the display information and an attribute browse signal according to operation for browsing the attribute information, and the sound related information supply means generates sound related to the display information of the block unit information assigned to the tactile operation means when receiving input of the display browse signal, and generates sound related to the attribute information of the block unit information assigned to the tactile operation means when receiving the attribute browse signal.

With this structure, attribute information and display information of block unit information assigned to an operated tactile operation means can be selectively browsed according to operation, so that attribute information of an interesting portion can be selectively browsed. Accordingly, an outline of the information can be effectively browsed without browsing the entire information. In particular, an application can be implemented such that the number of characters included in the block unit information or the number of pieces of the block unit information included in a subordinate level as amount of information included in the block unit information to which the tactile operation means attribute. Therefore, information can be effectively browsed.

In the information processing means for the visually impaired as claimed in claim 1, the invention claimed in claim 3 is that the information having a data structure that can be two-dimensionally expanded includes information related to functions of a predetermined apparatus structured with unit functions, at least one piece of the block unit information includes unit function information regarding performance of the unit function and attribute information that is attribute information of the unit function, the operation signal selecting means selects at least unit function performing operation signal according to operation for performing the unit function and attribute browse information according to operation for browsing the attribute information, the sound related information supply means generates sound related to the attribute information of the block unit information assigned to the tactile operation means when receiving input of the attribute browse information and the sound related information supply means includes unit function performing means that performs the unit function, and the unit function performing means performs the unit function based on the unit function information included in the block unit information assigned to the tactile operation means when receiving input of the unit function performing operation signal.

With this structure, a desired unit function can be appropriately selected and performed while an outline of a plurality of hierarchically classified unit functions of a predetermined apparatus are being browsed.

In the information processing means for the visually impaired as claimed in any one of claims 1 to 3, the invention claimed in claim 4 is that the block unit information can be hierarchically structured so that one piece of the block unit information is assigned to one or more pieces of subordinate block unit information, the operation signal selecting means can select a subordinate level expanding signal generated according to operation for expanding information in a subordinate level of the block unit information corresponding to the operated tactile operation means, and the information modification means modifies at least the information related to a correspondence with the tactile operation means so that the block unit information in the subordinate level of the block unit information corresponding to the operated tactile operation means is newly assigned to the tactile operation means when receiving input of the subordinate level expanding signal.

With this structure, block unit information attributing to a predetermined level can be displayed by which the block unit information is selected and assigned to the tactile operation means. Therefore, information having a complicated structure including several levels can be hierarchically displayed on respective displays in a display pattern that is easy to recognize. Further, the information can be easily browsed while an outline of the information is being understood.

In the information processing means for the visually impaired as claimed in claim 4, the invention claimed in claim 5 is that the information related to a correspondence with the tactile operation means is set so that the plurality of block information included in a corresponding level correspond to a layout at the time when the block unit information are displayed or printed.

With this structure, a position of the tactile operation means shows a place where description of block unit information corresponding to the tactile operation means is displayed or printed. Accordingly, a layout included in the information can be understood by a pattern of the tactile operation means through intuition.

In the information processing means for the visually impaired as claimed in claim 4, the invention claimed in claim 6 is that a direction of depth of a hierarchical structure of data of the information related to a correspondence with the tactile operation means is assigned to one direction in the matrix of the tactile operation means and a direction of a list of the block unit information included in the same level is assigned to a direction perpendicular to the one direction.

With this structure, when document data to be browsed is hierarchically classified as bibliographical classification at a library, the document data can be two-dimensionally displayed. Accordingly, a desired document can be easily selected.

In the information processing means for the visually impaired as claimed in claim 6, the invention claimed in claim 7 is the information modification means is structured to modify the information related to a correspondence with the tactile operation means so that the information in the subordinate level of the block unit information corresponding to the operated tactile operation means is assigned to the tactile operation means other than the operated tactile means when receiving input of the subordinate level expanding signal.

With this structure, a higher level is kept displaying, so that a relationship between a newly expanded level and the, higher level can be easy to understand.

In the information processing means for the visually impaired as claimed in any one of claims 4 to 7, the invention claimed in claim 8 is the identification states that are set to the tactile operation means can be set in at least three states or more, wherein at least one identification state is used to indicate to effect that the block unit information corresponding to predetermined tactile operation means can be expanded in associated with the block unit information in the subordinate level or that the block unit information corresponding to the predetermined tactile operation means has been already expanded and displayed by other tactile operation means.

With this structure, unassigned tactile operation means can be specifically distinguished from tactile operation means that is assigned with a subordinate level.

In the information processing means for the visually impaired as claimed in claim 8, the invention claimed in claim 9 is that the tactile operation means can be set in a another state, which indicates the block unit information in the subordinate level corresponding to the predetermined tactile operation means has been already expanded and displayed by the other tactile operation means, being different from a state indicating that the block unit information has not been expanded yet, when the block unit information corresponding to the tactile operation means is expandable in conjunction with the block unit information in the subordinate level.

With this structure, when tactile operation means is used on the assumption that block unit information is expanded into a subordinate level, a setting state of the tactile operation means can indicate whether the block unit information has been expanded.

In the information processing means for the visually impaired as claimed in any one of claims 1 to 9, the invention claimed in claim 10 is that the tactile operation means are classified into a plurality of groups, and the sound related information supply means outputs an area identification sound assigned to each block unit information to discriminate a group, to which the operated tactile operation means attributes, from other groups when generating sound regarding the attribute information.

With this structure, areas occupied by groups to which each block unit information attributes, in a layout, can be exactly understood by hearing attribute information.

In the information processing means for the visually impaired as claimed in any one of claims 1 to 10, the invention claimed in claim 11 is that the tactile operation means setting means is structured so that a setting operational status can be recognized by sound.

With this structure, a state that the tactile operation means are under setting operation can be confirmed by a sense of hearing. Therefore, caution can be provided to prevent misunderstanding and improper operation when a display pattern is not correct.

In the information processing means for the visually impaired as claimed in any one of claims 1 to 11, the invention claimed in claim 12 is that the tactile operation means provides a plurality of identification states with amount of protrusion of an operating portion from a predetermined reference plane.

With this structure, a setting state of tactile operation means can be recognized through intuition by the sense of touch. A difference of the setting states can be effectuated by changing the height of the tactile operation means. Accordingly, a plurality of setting states can be provided within a limited space in a plane direction.

In the information processing means for the visually impaired as claimed in any one of claims 1 to 11, the invention claimed in claim 13 is that the tactile operation means provides the plurality of identification states by a sound pattern output based on pressing operation performed on the operating portion set in the predetermined area which is one of the areas individually set.

With this structure, a mechanical moving member is not needed to set the tactile operation means in the plurality of setting states. The tactile operation means can be structured with a push switch. Therefore, a low-priced tactile input/output apparatus can be manufactured depending on a usage pattern.

In the information processing means for the visually impaired as claimed in any one of claims 1 to 13, the invention claimed in claim 14 further includes vibration means that can transmit vibrations to a fingertip touching the predetermined area which is one of the areas individually set, wherein the tactile operation means provides the plurality of the identification states by a vibration pattern of the vibration means.

With this structure, the setting state can be represented by a vibration pattern. Accordingly, there is a possibility to manufacture a tactile input/output apparatus having a plurality of tactile operation means at low cost.

In the information processing means for the visually impaired as claimed in claim 14, the invention claimed in claim 15 is that the tactile operation means includes fingertip detecting means that detects an approach of the fingertip to the predetermined area which is one of the area individually set, and the vibration means vibrates upon detecting the approach of the fingertip by the fingertip detecting means.

With this structure, the number of vibration means needing to be vibrated can be reduced when the vibration means is provided to every tactile operation means. Therefore, power consumption is low and noise occurring due to vibration is reduced. Further, it is possible to reduce the number of vibration means by which vibration means that vibrates a plurality of tactile operation means in common is provided and a structure that vibrates a touched tactile operation means by a vibration pattern corresponding to an identification state set to the tactile operation means is adopted.

In the information processing means for the visually impaired as claimed in any one of claims 1 to 11, the invention claimed in claim 16 is that the tactile operation means includes a tactile portion, such as a protrusion, that is disposed in the predetermined area which is one of the areas individually set and that can be recognized by tactile sense and includes the fingertip detecting means that detects the approach of the fingertip to the tactile portion, and the tactile operation means provides the plurality of the identification means by sound output upon detecting the approach of the fingertip by the fingertip detecting means.

With this structure, the setting state can be recognized by sound/voice according to tactile operation of the tactile operation. A mechanical moving member is not needed. Therefore, a low-priced, tactile input/output apparatus can be manufactured.

In the information processing means for the visually impaired as claimed in any one of claims 1 to 16, the invention claimed in claim 17 is that the tactile operation means is structured to detect a pressing operated by the fingertip in the predetermined area which is one of the areas individually set.

With this structure, there is no inconvenience of playing sound/voice regarding assigned information only by touching the tactile operation means to confirm the setting state of the tactile operation means. Accordingly, attention can be paid only to confirm a layout. The tactile input/output apparatus is easy to use because operation can be input only by pressing the tactile operation means without moving a finger off.

In the information processing means for the visually impaired as claimed in any one of claims 1 to 17, the invention claimed in claim 18 is that a sequence of setting operation of the plurality of the tactile operation means is changed in accordance with a position of the operated tactile operation means.

With this structure, an unstable state having an effect on the setting operation of the tactile operation means can be avoided by which change of the setting of the operated tactile operation means is postponed.

In the information processing means for the visually impaired as claimed in any one of claims 1 to 18, the invention claimed in claim 19 is that the tactile operation means includes the fingertip detecting means that detects existence of the fingertip in the predetermined area, which is one of the areas individually set, and is provided with auxiliary operation means that detects auxiliary input operation performed out of the predetermined area, and the operation signal selecting means is structured to select and output an operation signal corresponding to a predetermined operation based on the auxiliary input operation via the auxiliary operation means and results of detection by the fingertip detecting means.

With this structure, a detecting device that detects the plurality of the operating patterns is not need every tactile operation means. Accordingly, the information processing apparatus can be simply structured.

In the information processing means for the visually impaired as claimed in any one of claims 1 to 19, the invention claimed in claim 20 further includes updated information input means that receives input of updated information, wherein the information modification means changes the stored content of the information storage means related to the operated tactile operation means based on information input from the updated information input means on the basis of the operated tactile operation means.

With this structure, description can be modified by simply directing a portion desired to be modified.

In the information processing means for the visually impaired as claimed in claim 20, the invention claimed in claim 21 is that the updated information input means includes voice input means that selects text information from a voice signal input from a microphone.

With this structure, information for modification can be input by voice. Accordingly, the information can be input without moving a hand off from the tactile input/output apparatus, so that the tactile input/output apparatus is easy to use.

In the information processing means for the visually impaired as claimed in any one of claims 1 to 21, the invention claimed in claim 22 further includes operating time totaling means that sums operating time information of the information processing apparatus, wherein t operation for directing to perform maintenance of the information processing apparatus is started based on the operating time information.

With this structure, the visually impaired, who can not confirm an appearance of the information processing apparatus by the sense of sight, can perform maintenance, such as cleaning of the information processing apparatus, with appropriate timing.

In the information processing means for the visually impaired as claimed in any one of claims 1 to 22, the invention claimed in claim 23 is that the information setting means includes information input means that receives input of information having a data structure that can be two-dimensionally expanded, grouping means that divides information into a plurality of groups based on a structural descriptor included in the input information, hierarchical structure selecting means that selects a hierarchical structure of the groups when a parent-child relationship is established between the plurality of the groups, group area selecting means that obtains information related to an area which is occupied by information included in the groups at the time when the information is displayed or printed, and mapping means that sets a correspondence between the plurality of the groups and at least one of the tactile operation means to be used in a display state of any level, wherein the information setting means sets the block unit information and the information related to a correspondence with the tactile operation means based on the information included in the groups and the information set by the mapping means.

With this structure, even when information desired to be browsed is not stored in storage means in advance as block unit information, the information is divided into groups based on a structure that can be two-dimensionally expanded, as necessary. The grouped information are assigned to tactile operation means by the mapping means with consideration given to a hierarchical structure and area information of the groups and set with block unit information. Accordingly, information that exists in the outside and has hierarchical structure that can be two-dimensionally expanded can be effectively browsed.

A tactile input/output apparatus claimed in claim 24 that includes a mechanical clutch mechanism disposed at some midpoint in a drive force-transfer path Lo selectively drive a plurality of up-and-down key tops using a single drive motor. The tactile input/output apparatus includes a frame, a motor mounting frame, a plurality of drive motors fixed to the motor mounting frame, a drive motor controller, drive force output units attached to an output shaft of each drive motor, a plurality of key units disposed to the frame at positions with respect to one drive motor that each includes an up-and-down key top having an operation input portion, up-and-down key top moving means that moves the up-and-down key top in up and down directions, and an operation detector that detects pressing operation by a fingertip touching the up-and-down key top, and positioning driving means that respectively drives the frame and the motor mounting frame in a parallel direction without rotation, and connects the drive force output units of the drive motors to the up-and-down key top moving means of arbitrary key units of the plurality of the key units disposed to the frame with respect to the drive motor.

With this structure, the positioning drive means respectively moves the frame and the motor mounting frame. The positioning drive means connects drive force output units to the key top moving means of arbitrary key units of the plurality of the key units corresponding respective drive motors. Therefore, a key top at any position provided in the tactile input/output apparatus can be controlled its up-and-down movement by the drive motors that are small in number than the number of the key tops. Further, an intermediate member, such as a rack, is not needed to transmit the drive force as a conventional apparatus. Accordingly, a parts count is small and the tactile input/output apparatus has a mechanically simple structure and high reliability.

Further, the positioning drive means is effectuated with only a mechanism that relatively moves the motor mounting frame with respective to the frame. However, the tactile input/output apparatus does not need the clutch mechanism at every rows, as the conventional apparatus. Therefore, the parts count is small and the tactile input/output apparatus has a mechanically simple structure and high reliability.

Furthermore, the frame and the motor mounting frame are relatively driven in a parallel direction without any rotation. If the drive motors are fixed to the motor mounting frame at an appropriated positions, a connecting operation in the drive motors can be properly and simultaneously performed.

In the tactile input/output apparatus as claimed in claim 24, the invention claimed in claim 25 is that the key units are disposed at corners of a rectangular formed by which the drive force output unit of the corresponding drive motor is as its center.

With this structure, the drive output units can directly transmit the rotational drive force to the key top moving means by the action of the positioning drive means. Accordingly, means that transmits the rotational drive force in a row direction, such as a rack, is unnecessary as the conventional apparatus.

Further, one drive motor is needed for every four key units. The drive motors can be disposed with a pitch which is twice as much as an arrangement pitch of the key units. Therefore, even if a drive motor having a some large diameter is used, the key units can be disposed with a small pitch. In particular, when the key units are disposed at the corners of a square by which a vertical pitch is made to become equal to a horizontal pitch, the drive motor is disposed at a center of the square. Because the drive motor has a circular shape, by doing so, front/rear and right/left clearance is evened out and the drive motors can be effectively disposed.

In the tactile input/output apparatus as claimed in claim 24 or 25, the invention claimed in claim 26 that is the drive motors are pulse motors, the drive force output units are drive gears fixedly attached to a rotation output shaft of each drive motor, the up-and-down key top moving means is structured with a driven gear that is rotated by engaging the drive gear, and the key units are structured so as to take a first mounting position that the drive gear normally engages the driven gear and a second mounting position that the key unit is displaced to absorb an abutment of teeth of the drive gear and the driven gear and is structured to return to the first mounting position from the second mounting position by a urging force from an elastic member.

With this structure, the drive force can be synchronistically transmitted. Even when the driven gear moves itself for some reasons while the drive gear and the driven gear are not engaged, the key units are evacuated to the second attaching position. When the drive gears and the driven gears become a state where their teeth are not contacted with each other, the driven gears are returned to the first mounting position. Therefore, the teeth are not damaged and the synchronistical transmission of the gears can be maintained.

In the tactile input/output apparatus as claimed in claim 26, the invention claimed in claim 27 that is an upper portion of the up-and-down key tops is slidably guided in the up-and-down direction along a guide hole formed in the frame, a lower portion of the up-and-down key tops is connected to the up-and-down key top moving means, and the up-and-down key tops swing about a portion guided by the guide holes with evacuation of the driven gear in a horizontal direction.

With this structure, the structure of the up-and-down key tops can be simplified because the up-and-down key tops slightly swing about its upper portion to effectuate the structure of claim 26 even when the driven gears move to evacuate with respect to the frame.

In the tactile input/output apparatus as claimed in any one of claims 25 to 27, the invention claimed in claim 28 that is the up-and-down key tops are formed with a portion input pressing operation at their upper portion, the up-and-down key tops and the up-and-down moving means are connected each other by screws or cams and are structured so that the up-and-down key tops move up and down with respect to the up-and-down key top moving means with rotation of the up-and-down key top moving means, some of the up-and-down moving means contact the operation detecting means and are supported by operation detecting means from a bottom, and the some of the up-and-down moving means are structured so that pressing operation input to the up-and-down key top is detected by the operation detecting means via the up-and-down key top moving means.

With this structure, the operation detecting means provides a standard position in the protrusion amount of the up-and-down key top and a function that detects pressing operation input to the up-and-down key top.

In the tactile input/output apparatus as claimed in claim 28, the invention claimed in claim 29 that is the key top moving means is regulated its upward movement with respect to the frame, the up-and-down key tops and the key top moving means are structured so that origin pressing means, that presses the operation detecting means at a portion where the up-and-down key top moving means contacts the operation detecting means under the up-and-down key top moving means, protrudes as the up-and-down key top reaches a standard position with respect to the up-and-down key top moving means of the up-and-down key top by descending and to detect the standard position with respect to the up-and-down key top moving means by detecting a pressing of the operation detecting means by the origin pressing means.

With this structure, the operation detecting means also serves as means that detects the standard position that is required for operation of the up-and-down key top moving means. Accordingly, the parts count decreases and the tactile input/output apparatus can be downsized.

In the information processing means for the visually impaired as claimed in any one of claims 1 to 23, the invention claimed in claim 30 further includes state information storing means that stores state information, that includes at least correspondence information included in the information storage means and can reproduce a state of the information processing apparatus that reflects a history of the operation performed by the user, into nonvolatile information storage means, and
state information reading means that reproduces a state of the information processing apparatus by reading the stored state information.

With this structure, a state of the tactile input/output apparatus, that is changed based on the operation performed by the user to browse the information, can be easily reproduced.

### BRIEF DESCRIPTION OF DRAWINGS

FIG. 1 is a diagram showing a structure of claim of the invention.

FIG. 2 is a block diagram showing a structure of an information browsing apparatus for the visually impaired of the invention.

FIG. 3 is a diagram showing data in which a hierarchical control structure of a document to be read is recorded.

FIG. 4 shows an example of document data.

FIG. 5 shows data of a “snap.”

FIG. 6 shows pictorial data of the “snap.”

FIG. 7 shows data of an “experimental result table.”

FIG. 8 is an explanation of definitions of tags.

FIG. 9 is an explanation of definitions of tags.

FIG. 10 shows a hierarchical structure of directories of a “TOKKYO KUN's bookshelf.”

FIG. 11 shows a hierarchical structure of fields of a “letter.”

FIG. 12 shows a correspondence between contents and the hierarchical structure of the fields of the “letter.”

FIG. 13 shows a data structure of a storage area established in a memory.

FIG. 14 is a flowchart (first half) of a main routine.

FIG. 15 is a flowchart of a subroutine “DispIndex.”

FIG. 16 is a flowchart (latter half) of the main routine.

FIG. 17 is an operation correspondence table.

FIG. 18 shows a sound pattern of display of attribute.

FIG. 19 is a flowchart of a subroutine “Cleaning.”

FIG. 20 is a flowchart of a subroutine “NewIndex.”

FIG. 21 is a flowchart of a subroutine “Calibraton.”

FIG. 22 is a flowchart of a subroutine “BlockData.”

FIG. 23 shows a setting state of key tops when browsing the “TOKKO KUN's bookshelf.”

FIG. 24 shows a setting state of the key tops when browsing “research and development.”

FIG. 25 shows a setting state of the key tops when browsing “communication record.”

FIG. 26 shows a setting state of the key tops when browsing the “letter.”

FIG. 27 shows a setting state of key tops when browsing a “body” in a tactile input/output apparatus having key tops of an array with 16 rows and 16 columns.

FIG. 28 shows a setting state of the key tops when browsing the “body”.

FIG. 29 shows a setting state of the key tops when browsing the “body” in the tactile input/output apparatus having of key tops of an array with 16 rows and 16 columns.

FIG. 30 shows a setting state of the key tops when browsing the “experimental result table.”

FIG. 31 shows a setting state of the key tops when browsing the “experimental result table” in the tactile input/output apparatus having key tops of an array with 16 rows and 16 columns.

FIG. 32 shows a setting state of the key tops when browsing a “postscript”.

FIG. 33 shows a setting state of the key tops when browsing the “snap”.

FIG. 34 shows a setting state of key tops when browsing the “letter” after inputting a “date”.

FIG. 35 is an explanatory diagram of a scrolling display.

FIG. 36 is a top view of the tactile input/output apparatus.

FIG. 37 is a sectional view of the tactile input/output apparatus taken along line A-A of FIG. 36.

FIG. 38 is a diagram showing four key groups as seen from the above of a section A-A of FIG. 37.

FIG. 39 is a diagram showing the four key groups as seen from the bottom of a section B-B of FIG. 37.

FIG. 40 is a diagram showing a portion corresponding to the four key groups on an electronic substrate as seen from the above of a section C-C of FIG. 37.

FIG. 41 is a diagram showing a positional relationship between up-and-down gears and pinion gears in the four key groups as seen from the bottom of a section D-D of FIG. 37.

FIG. 42 is a diagram showing a mechanism of positioning drive means.

FIG. 43 is a diagram showing various protrusion height of up-and-down pins as seen from the section A-A of FIG. 36.

FIGS. 44 to 48 are diagrams showing a positional relationship among the up-and-down gears, the pinion gears and the mechanism of the positioning drive means in the four groups when a motor mounting frame is positioned at a standard position, at an upper left position, at a lower left position, at an upper right position, and at a lower right position, respectively, as seen from the section D-D of FIG. 37.

FIG. 49 is a diagram showing various protrusion height of the up-and-down pins in the operating panel and the up-and-down pin of a second embodiment as seen from the section A-A of FIG. 36.

FIG. 50 is a diagram showing a structure of a tactile input/output apparatus of the second embodiment.

FIG. 51 is a flowchart of a program stored in a one-chip microcomputer of the tactile input/output apparatus of the second embodiment.

FIG. 52 is a diagram showing a structure of a tactile input/output apparatus of a third embodiment.

FIG. 53 is a sectional view showing a structure of a vibration pin.

FIG. 54 is a flowchart of a program stored in a one-chip microcomputer.

FIG. 55 is a diagram showing a hierarchical structure of functions of a personal computer.

FIG. 56 is a diagram showing an example of use of the key tops of the tactile input/output apparatus that is a user interface applicable to access the functions of the personal computer of FIG. 55.

FIG. 57 is an example of displaying a hierarchical structure of the functions of the personal computer shown in FIG. 55.

FIG. 58 is a diagram showing a setting state of the key tops when browsing a homepage.

FIG. 59 is a diagram showing a setting of the key tops after double-clicking a key top in a task bar in FIG. 58.

FIG. 60 is a diagram showing a worksheet of arithmetic.

FIG. 61 is a diagram showing a display condition of the key tops corresponding to FIG. 60.

FIG. 62 is a diagram showing a display condition of the key tops of a next step of FIG. 61.

FIG. 63 is a diagram showing data of the functions of the personal computer shown in FIG. 55.

### BEST MODE FOR CARRYING OUT THE INVENTION

The invention will be described with reference to the accompanying drawings to provide a detailed explanation.

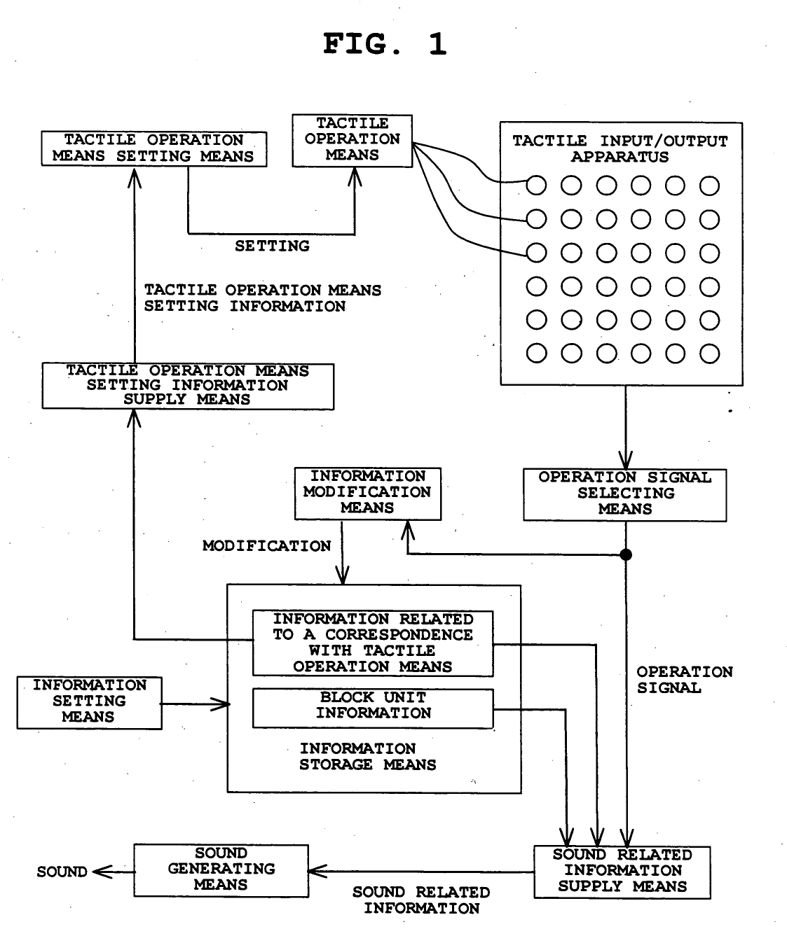

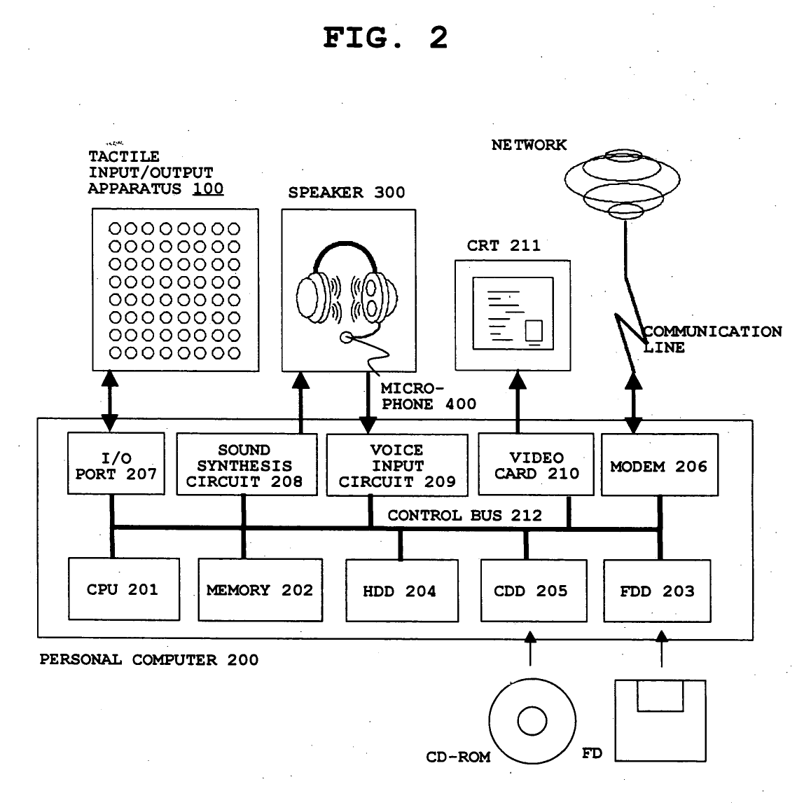

FIG. 1 is a diagram showing a structure of claim of the invention. FIG. 2 is a block diagram showing a structure of an information processing apparatus for the visually impaired of the invention.

In FIG. 2, a tactile input/output apparatus 100 is used to read a layout of information and perform input operation by a visually impaired person using his/her tactile sense. The tactile input/output apparatus 100 is connected to a personal computer 200 via a signal cable 1a. The personal computer 200 is structured so as to operate based on a stored control program, input data of sentences, tables and the like made by a word processor from a floppy disk (hereinafter referred to as an FD), as a replaceable recording medium, and perform predetermined processing according to operations described later. Information may be input from a server of the Internet using a modem 206.

A sound synthesis circuit 208 synthesizes sound and outputs sound/voice to a headphones-type speaker 300. The speaker 300 has four channels and is outstanding for expressing a sound field. A left front speaker 300a and a left rear speaker 300b are disposed on a left ear and a right front speaker 300c and a right rear speaker 300d are disposed on a right ear of a user. A microphone 400 is attached to the speaker 300 and is connected to a voice input circuit 209 with a signal line.

Next, before describing a first embodiment of the tactile input/output apparatus, features and problems of a tactile input/output apparatus (hereinafter referred to as prior art) disclosed in Japanese Patent Application No. 10-268805 (that is one of an application according to claim for priority of this application) that was applied to the Japanese Patent Office on Sep. 22, 1998 by the applicant of this invention will be briefly described.

As is obvious from the description in the aforementioned specification, a feature of the prior art is that a plurality of key tops are arranged along a rack which is straightly driven in a column direction by a single pulse motor, and the plurality of the key tops can be driven in a direction of height of the key top by the pulse motor by permitting engagement of a clutch gear of arbitrary key top with the rack. Further, engagement of the clutch gears with the rack is implemented by a switch mechanism including a clutch plate and a solenoid.

Further, a plurality of pulse motors and racks are provided in a row direction and the clutch plate is provided so that the switch mechanism operates the key tops included in the same row at the same time. Therefore, up-and-down type key tops with an array of M rows and N columns can be individually driven and controlled in cooperation of N pieces of the pulse motors and M pieces of the solenoids.

Unfortunately, however, in the prior art, a rack for transmitting a drive force is needed every row. In addition to this, a mechanism for switching the drive force of the pulse motor is needed as many as the number of columns. As a result, a parts count increases and costs of the tactile input/output apparatus becomes high.

Further, in the prior art, an arrangement pitch of key units is determined based on a total dimension of a width of the rack, a diameter of the clutch gear, and an amount of clearance for clutching. In order to dispose the key units with a small pitch, it is necessary to reduce the diameter of the clutch gear and the width of the rack. However, in a case where the diameter of the clutch gear is reduced, torque required for the drive motor increases, so that the drive motor becomes large in size. Further, in a case where the width of the rack is reduced, it is difficult to maintain a straightness of the rack extending in the column direction.

In order to surely implement clutching operation, the rack and the clutch gear should be positioned where the rack and the clutch gear are precisely engaged with each other. However, in the prior art, a plurality of racks and clutch gears and a clutch plate are needed to be guided by precisely positioning them and also high parts tolerance and assembling accuracy need to be ensured, so that cost increases. The feature of the prior art is that drive motors with respect to the key tops decrease in number with increasing the key tops in number. However, when there are relatively few key tops, the aforementioned disadvantages become more pronounced than the advantages.

Therefore, the inventor made an effort to solve the problems of the prior art described below.

1. A problem that the parts count increases resulting in increased costs.

2. A problem that a reliability of the apparatus is low and a possibility of occurrence of mechanical troubles is high, because a structure of a guiding mechanism is complicated because there are numbers of members which are independently driven and guided.

3. A problem that it is difficult to narrow an arrangement pitch of up-and-down key tops.

4. A problem that high tolerance parts and high assembling accuracy are required.

As a result, a tactile input/output apparatus described below was invented. Next, referring to the drawings, a first embodiment of the tactile input/output apparatus will be described.

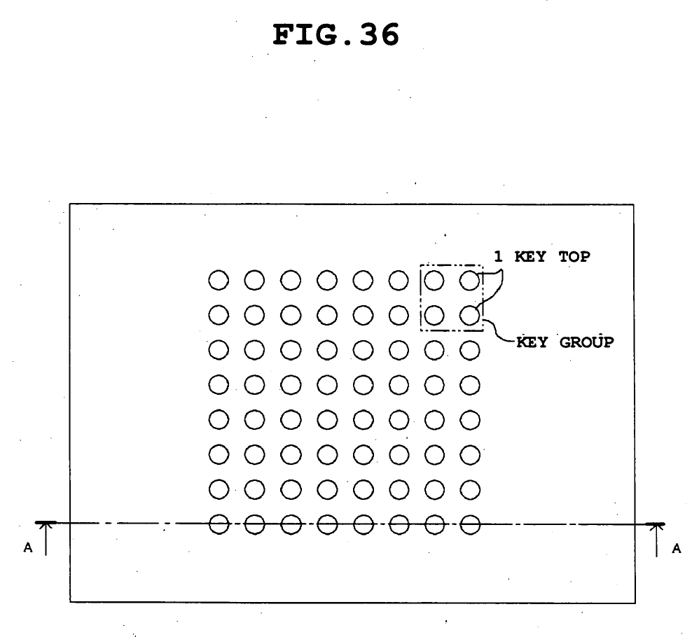

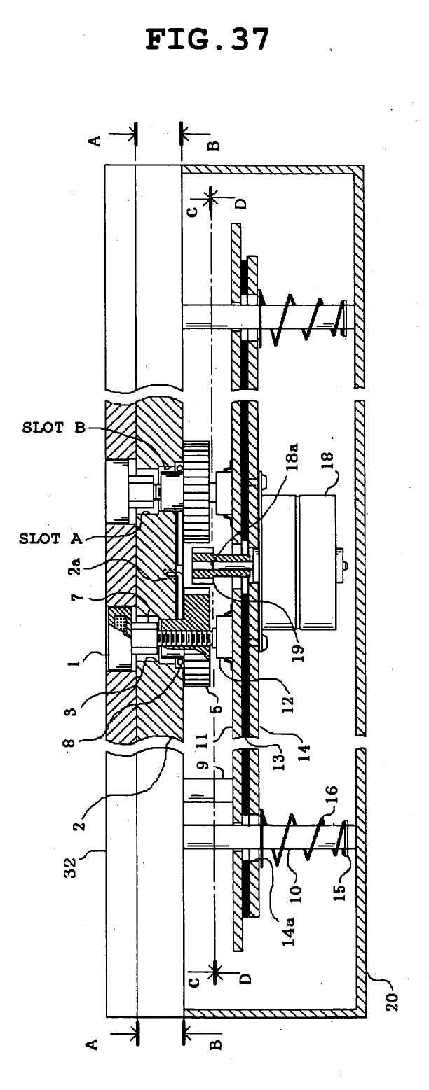

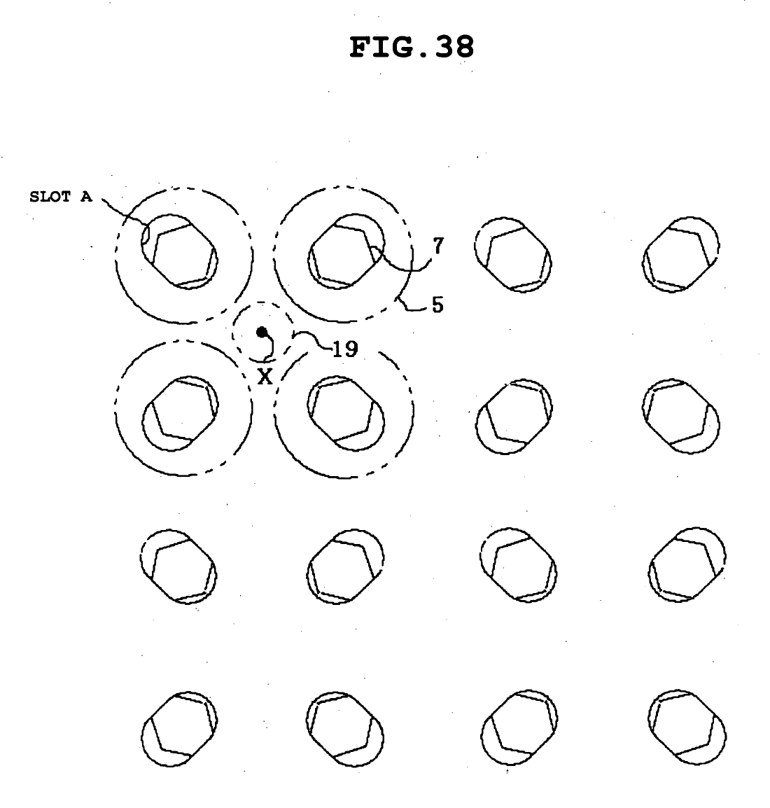

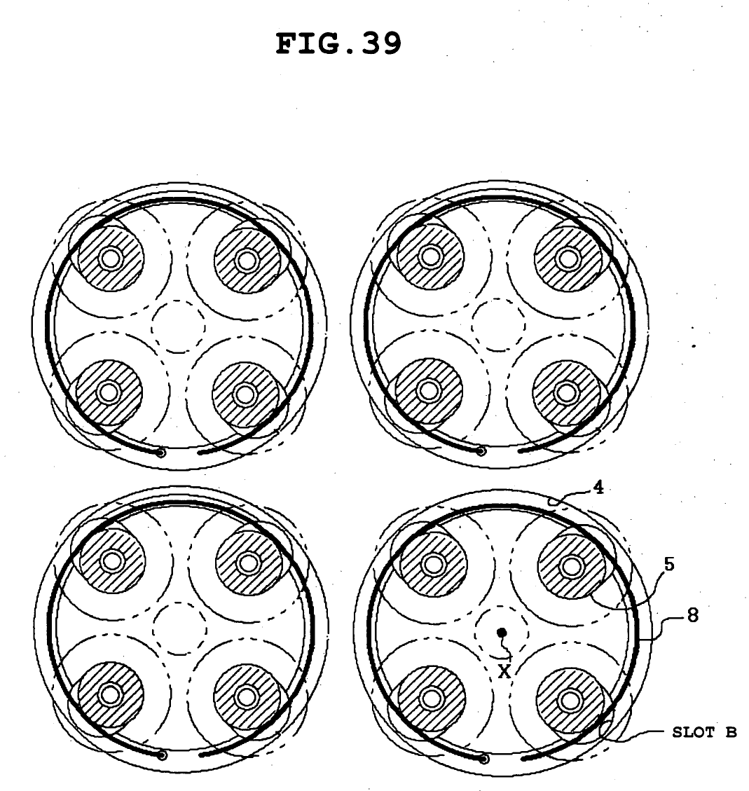

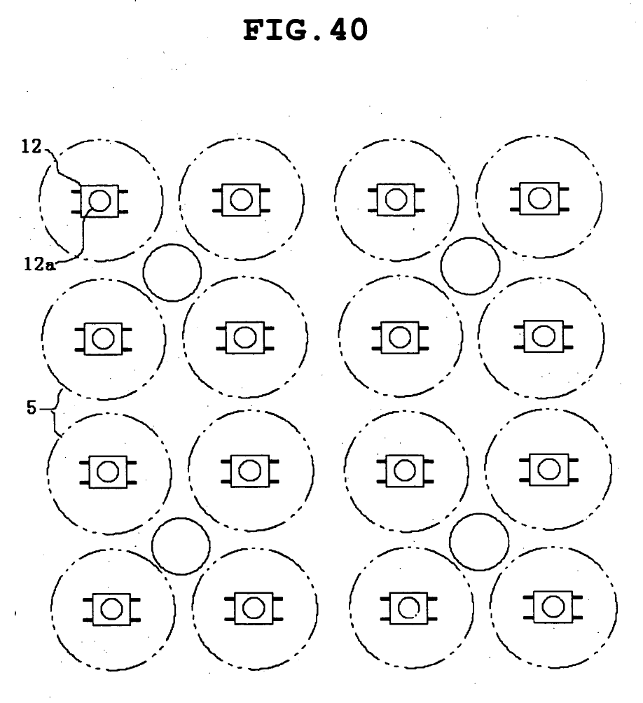

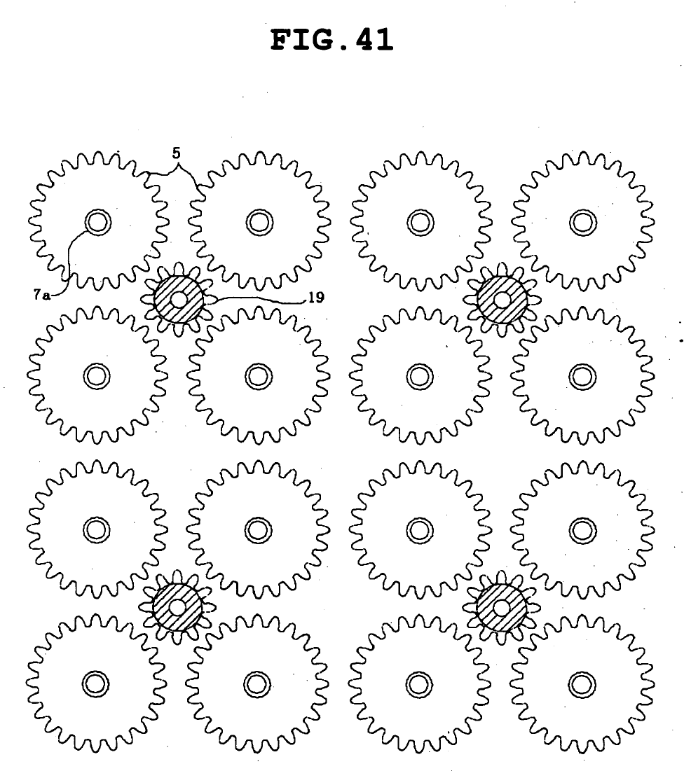

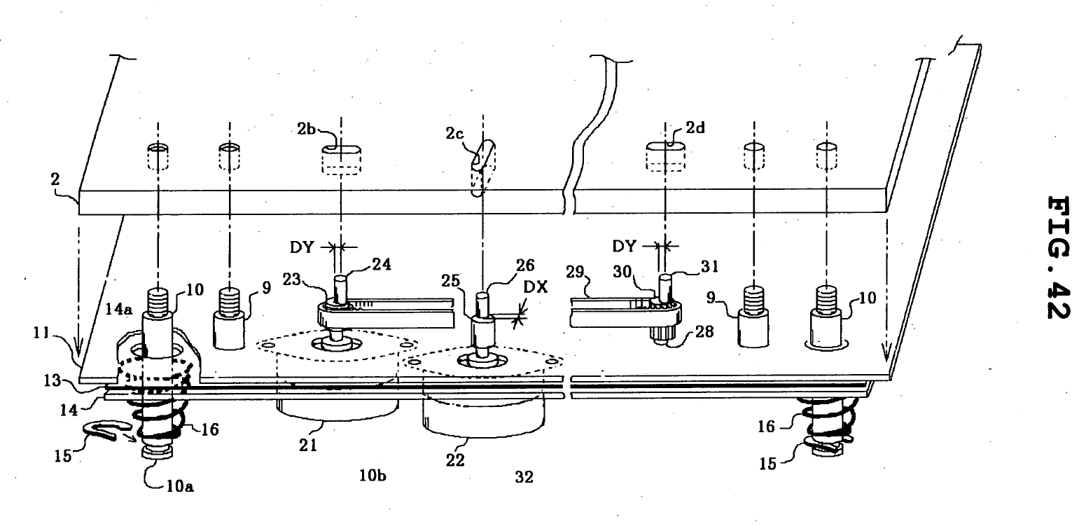

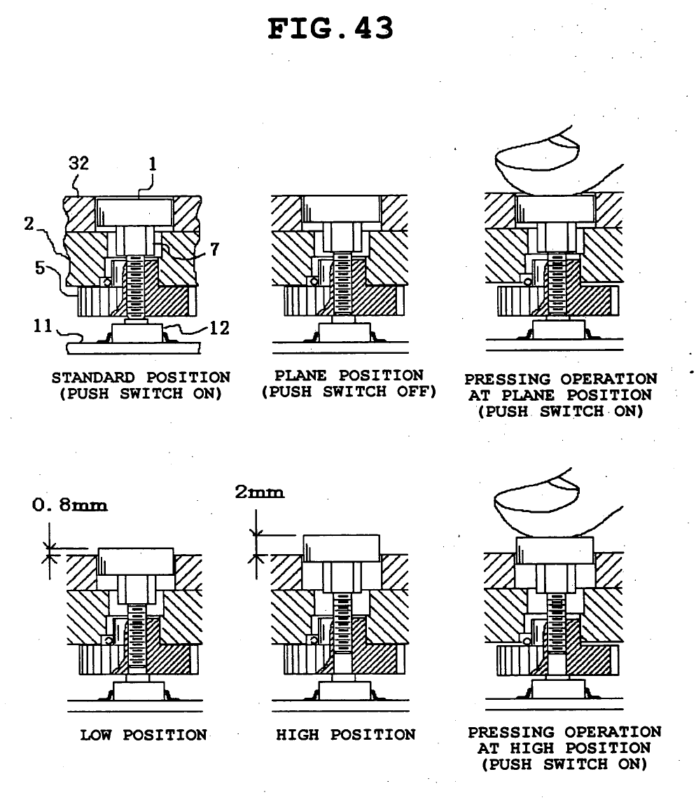

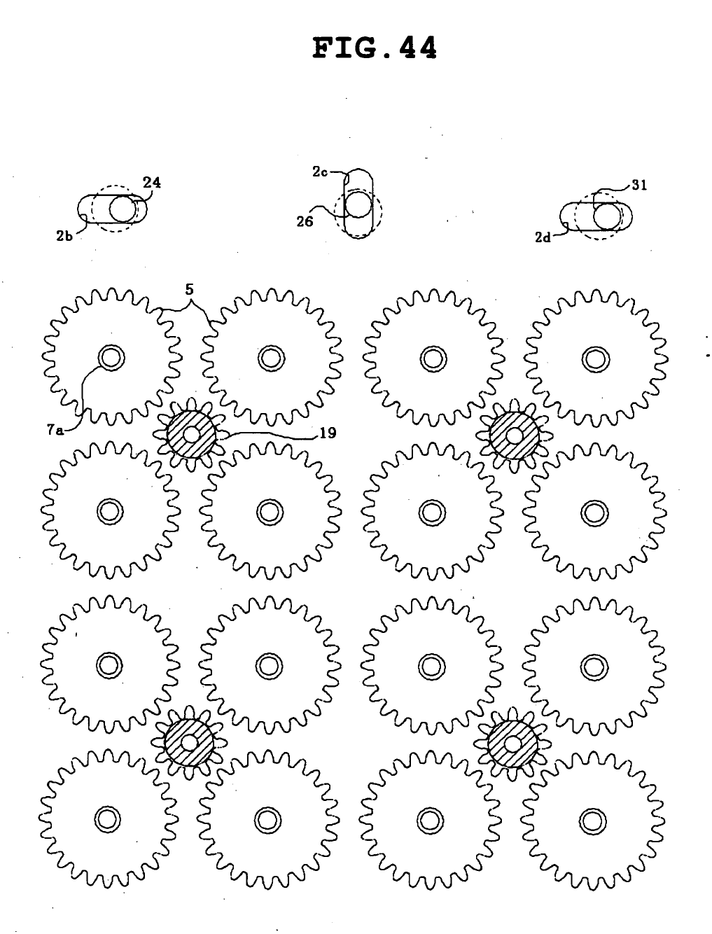

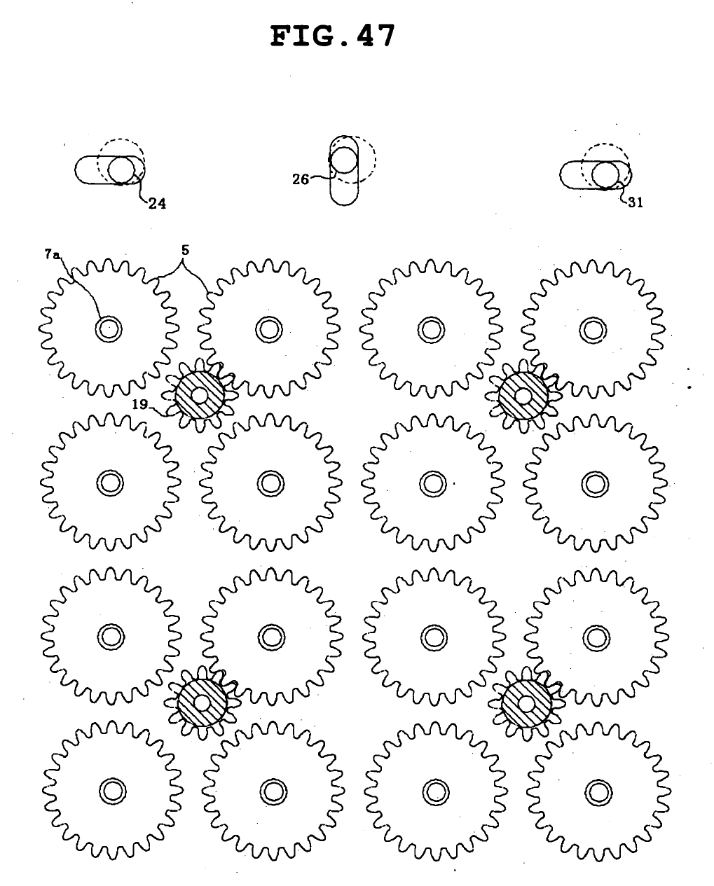

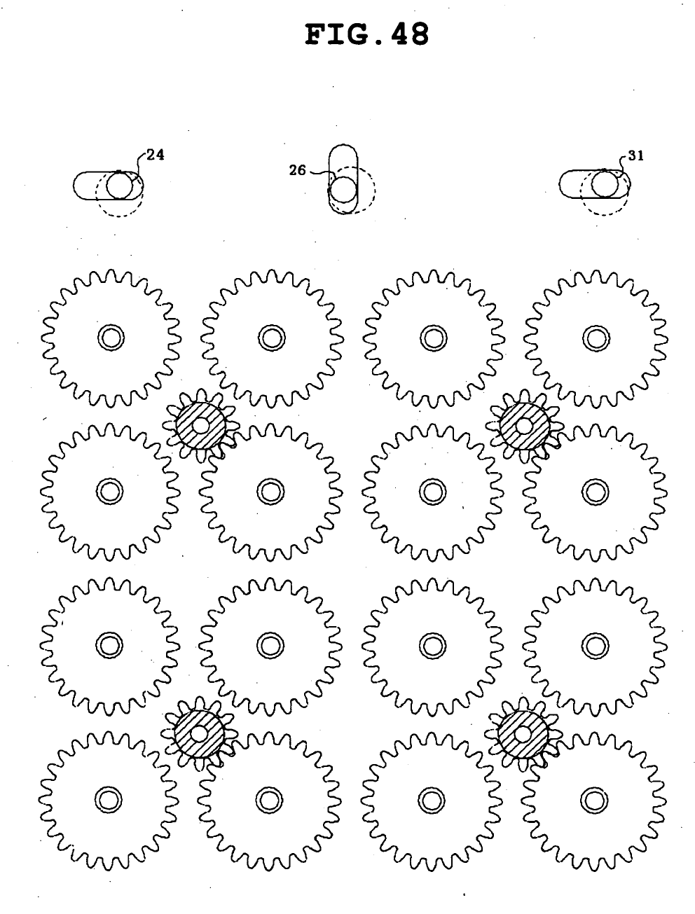

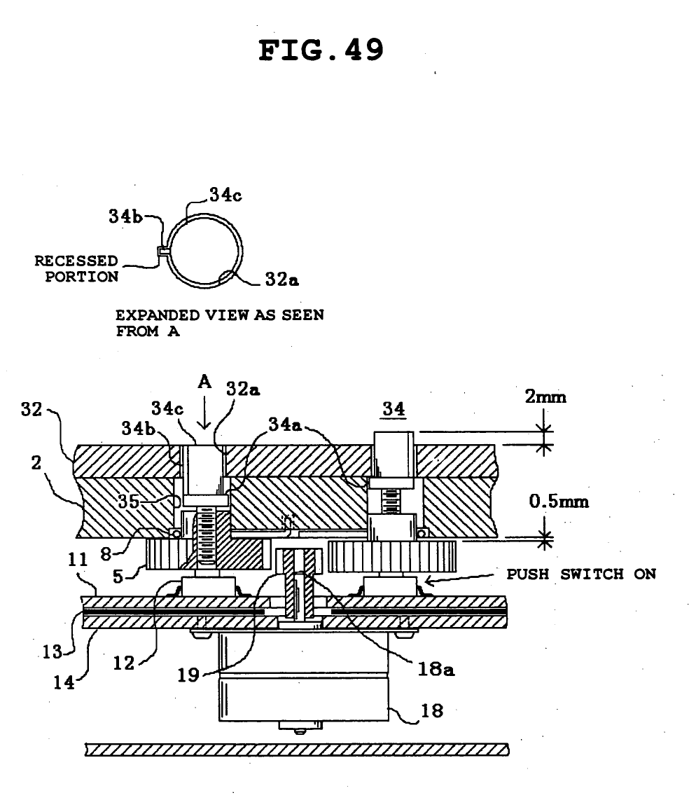

FIG. 36 is a top view of the tactile input/output apparatus. FIG. 37 is a sectional view of the tactile input/output apparatus of FIG. 36 taken along line A-A of FIG. 36. FIG. 38 is a diagram showing four key groups as seen from the above of a section A-A of FIG. 37. FIG. 39 is a diagram showing the four key groups as seen from the bottom of a section B-B of FIG. 37. FIG. 40 is a diagram showing a portion corresponding to the four key groups on an electronic substrate as seen from the above of a section C-C of FIG. 37. FIG. 41 is a diagram showing a positional relationship between up-and-down gears and pinion gears in the four key groups as seen from the bottom of a section D-D of FIG. 37. FIG. 42 is a diagram showing a mechanism of positioning drive means. FIG. 43 is diagrams showing various protrusion height of up-and-down pins as seen from the section A-A of FIG. 36. FIGS. 44 to 48 are diagrams showing a positional relationship among the up-and-down gears, the pinion gears in the four groups and the mechanism of positioning drive means when a motor mounting frame is positioned at a standard position, at an upper left position, at a lower left position, at an upper right position, and at a lower right position, respectively, as seen from the section D-D of FIG. 37. FIG. 49 is a diagram showing various protrusion height of the up-and-down pins in the operating panel and the up-and-down pin of a second embodiment as seen from the section A-A of FIG. 36.

In the embodiment, as shown in FIG. 36, sixty-four key tops are arranged in a matrix with 8 rows and 8 columns with 15 mm pitches. The key tops are grouped into: a plurality of key groups. A key group includes four key tops which constitute a minimum-sized square in a matrix. In the embodiment, the tactile input/output apparatus is structured with a matrix of four groups in the column direction and four groups in the row direction, that is, a total of sixteen key groups.

A frame 2 is a substantially flat plate-shaped member as a base of the tactile input/output apparatus. The frame 2 is made of a non-magnetic material, such as resin, aluminum, and brass. As shown in FIG. 37, each guide hole 3 penetrates from an upper surface to a lower surface of the frame 2 at a position each corresponding to a position where the key top is provided. As shown in FIG. 38, in each guide hole 3, a slot A having a width w1, a length t1, a radius r1=w1/2, and a depth D1 is formed from the upper surface of the frame 2 to a midpoint position in thickness of the frame 2. As shown in FIG. 39, a slot B having a width w2, a length t2, a radius r2=w2/2, and a depth D2 is formed from the midpoint position to the lower surface of the frame 2 in the thickness of the frame 2 in each guide hole 3. The guide hole 3 penetrating the frame from the upper surface to the lower surface is formed with the slot A and the slot B. An up-and-down gear 5 and an up-and-down pin 7, which are described later, are inserted into the guide hole 3.

A longitudinal direction of the slots A and the slots B of the guide holes is determined such that the slots A and the slots B of the guide holes ray with a center of the square (an X-point in FIGS. 38 and 39) in the key group to which the guide hole belongs as its center. As shown in FIG. 39, an annular groove 4 having a depth of 1 mm is formed in a position intersecting each slot B belonging to the key group. The groove 4 is circularized with the X-point as its center.

The up-and-down gear is a spur gear having a boss. The boss of the up-and-down gear is inserted into the slit B of the guide hole. The spur gear in the embodiment has a module 0.5 mm and twenty-four teeth. A screw hole 6 is formed in a center of the up-and-down gear. As shown in FIG. 37, a threaded portion of the up-and-down pin made of a magnetic material, such as a metal, is screwed from the above. A length of the threaded portion of the up-and-down pin is 1 mm longer than a distance from an upper surface to a lower surface of the boss of the up-and-down pin. When the up-and-down pin is screwed to the limit, a tip 7a of the threaded portion of the up-and-down pin protrudes 1 mm from the lower surface of the up-and-down gear. A head 7b of the up-and-down pin is hexagon whose subtense width is t1. As shown in FIG. 38, the head 7b of the up-and-down pin engages the slot A of the guide hole in the width t1, so that the up-and-down pin is regulated its rotation. The up-and-down gear corresponds with “up-and-down key top moving means” claimed in claim 24. The key top and the up-and-down pin correspond with an “up-and-down key top.”

In a clearance between an inside of the annular groove 4 and the upper surface of the teeth of the up-and-down gear, an annular spring 8 is provided. The spring 8 is hooked on the boss of the four up-and-down gears belonging to the key group so as to press the boss to one side (in a direction toward the X-point) of the slot B with a predetermined force.

Under the frame, an electronic substrate 11 is attached in parallel with the frame with studs 9. As shown in FIG. 40, on the upper surface of the electronic substrate, a plurality of push switches are soldered to a predetermined printed wiring pattern at a position where a center of a press input portion of each push switch coincides with a center of the up-and-down gear. As shown in FIG. 37, a height of the stud is set so that the upper surface of the press input portion at the time when the push switch is not operated contacts the lower surface of the up-and-down gear. In the embodiment, a pressing distance that the push switch is to be turned on is 0.5 mm.

The up-and-down gear is regulated its upward movement at the lower surface of the frame. Therefore, the push switch is pressed and operated at the position where the up-and-down pin protrudes 0.5 mm when the up-and-down pin is screwed into the up-and-down gear and protrudes from the lower surface of the up-and-down gear. Hereinafter, this state is referred to as an origin position of the up-and-down gear, and a height of the up-and-down pin in this state is referred to as a standard position of the up-and-down pin.

On the electronic substrate 11, the predetermined printed wiring pattern is formed and electronic components for driving pulse motors are mounted. The pulse motors are driven by a control of the personal computer 200. The electronic components function with an external controller and constitutes a “drive motor controller” claimed in claim 24.

Under the electronic substrate 11, a motor mounting frame 14 is provided in parallel with the electronic substrate while sandwiching an insulation sheet 13 therebtween. In the motor mounting frame 14, holes 14a are formed. Each motor mounting frame support shaft 10 is attached to the frame by extending through the hole and is attached an E-shaped snap ring 15 at its end. Between the E-shaped snap ring 15 and the lower surface of the motor mounting frame, a conical compression spring 16 is attached. A force of the conical spring 16 is set to a predetermined force so that the conical compression spring 16 supports and presses the motor mounting frame 14 from below toward the insulation sheet with a slight force.

A lower cover 20 which has a box shape and no upper surface is fixed to a lower end of the motor mounting frame support shafts 10 with screws. The lower cover 20 provides the box-shaped tactile input/output apparatus with the frame.

Under the motor mounting frame 14, pulse motors 18 are provided in a matrix with 4 rows and 4 columns with 30 mm pitches, that is, a total of sixteen pulse motors are provided. A rotation output shaft 18a of each pulse motors protrudes from the upper surface of the electronic substrate 11 while passing release hole in the motor mounting frame 14 and the electronic substrate 11. The pinion gear 19 is fixed at the end of the rotation output shaft 18a. In the embodiment, the gear having a module 0.5 mm and twelve teeth is used. The pinion gear preferably stops in the same gear phase when the pulse motor is excited with a predetermined exciting pattern. A pulse motor which runs 24 pulses per rotation and a pinion gear having twelve teeth are preferably used. When such the pulse motor and the pinion gear are used, the pinion gear always stops in the same gear phase at a standard exciting position (there are six stop phases of a rotor in circumference of the gear) where a coil of the pulse motor is excited in a forward direction.

The pulse motor 18 corresponds with a “drive motor” claimed in claim 24. The pinion gear 19 corresponds with a “drive force output unit.”

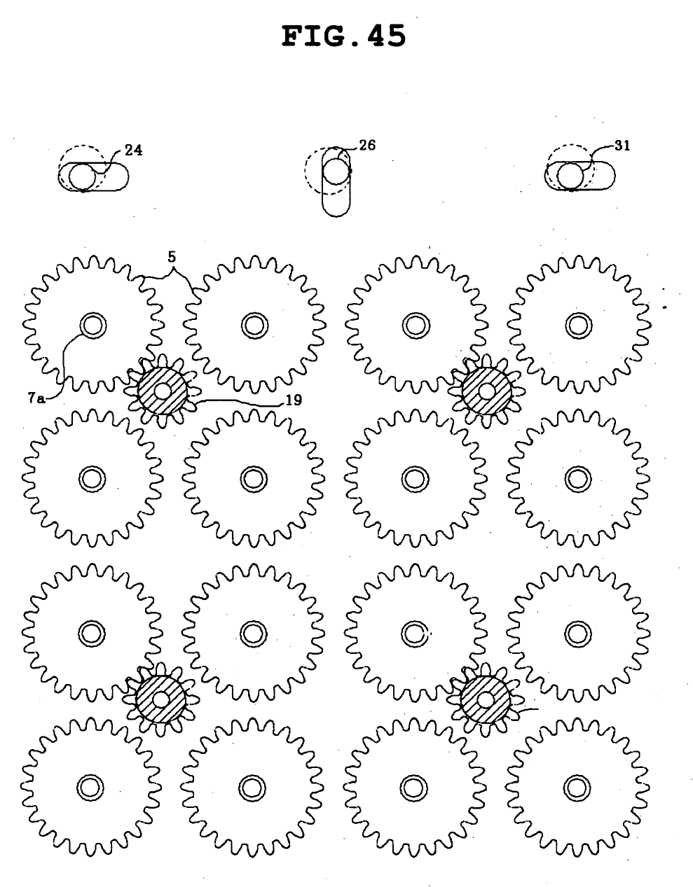

As shown in FIG. 41, when the motor mounting frame 14 is positioned at the standard position, the pulse motor 18 is attached so that the center of the square, in which four up-and-down gears are positioned at corners of the square, coincides with the center of pinion gear 19 and a predetermined clearance is provided between the up-and-down gear and the pinion gear. When the motor mounting frame 14 is moved back/forth or right/left, as shown in FIGS. 45 to 48, the pinion gear engages one of the four up-and-down gears.

Next, the positioning drive mechanism that relatively drives and moves the frame 2 and the motor mounting frame 14.

As shown in FIG. 42, a pulse motor for back-and-forth driving 21 and a pulse motor for right-and-left driving 22 are attached to the motor mounting frame 14. A timing pulley 23 is fixed to a rotation output shaft of the pulse motor for back-and-forth driving 21. The upper end of the rotation output shaft is formed with a back-and-forth drive shaft 24 at a position eccentric to DY from the rotation shaft. The rotation output shaft engages an oblong back-and-forth drive groove 2b formed in the lower surface of the frame.

A right-and-left drive pulley 25 is fixed to a rotation output shaft of the pulse motor for right-and-left driving 22. The upper end of the rotation output shaft is formed with a right-and-left drive shaft 26 at a position eccentric to DX from the rotation shaft. The rotation output shaft engages an oblong right-and-left drive groove 2c formed in the lower surface of the frame.

A second pulley 30 is rotatably attached to a pulley shaft 28 standing from the motor mounting frame 14. A timing belt 29 is looped between the timing pulley 23 and the second timing pulley 30.

The upper end of the second timing pulley 30 is formed with a second right-and-left drive shaft 31 at a position eccentric to DX from the rotation shaft. The rotation output shaft engages an oblong right-and-left drive groove 2d formed in the lower surface of the frame.

A timing belt 29 is disposed under tension while its phase is adjusted so that a back and forth movement occurring by the back-and-forth drive shafts 24 and 31 occurs in synchronization with rotation of the timing pulley 23 and the second timing pulley 30. The timing pulley 23 and the right-and-left drive pulley 25 are attached so that the back-and-forth drive shaft 24 and the right-and-left drive shaft 26 are position at a rotation position shown in FIG. 44 when the second timing pulley 30 is positioned at the origin position based on an origin point detecting sensor, which is not illustrated.

As described above, the back-and-forth drive groove 2b and the second back-and-forth drive groove 2d are long sideways, and their directions guiding the motor mounting frame 14 are parallel each other so that the motor mounting frame 14 is guided in parallel without rotational movement in the right and left direction and is regulated a back and forth movement. Further, the right-and-left drive groove 2c is long longways, so that the right-and-left drive groove 2c regulates the motor mounting frame 14 to move in the right and left direction while allowing the movement in the back and forth direction.

Therefore, when the pulse motor for back and forth driving 21 and the pulse motor for right and left driving 22 are arbitrary driven, the motor mounting frame 14 can be moved in parallel without rotational movement with respect to the frame 2.

Here, if DX and DY are set to a dimension necessary to engage the pinion gear 19 with the up-and-down gear 5, the pinion gears 19 of the plurality of pulse motors 18 can be selectively engaged with the up-and-down gear 5 of the four key units belonging to the key group.

As described above, the motor mounting frame 14 is driven and moved back/forth and right/left in parallel without the rotational movement with respect to the frame 2. Therefore, the engagement of pinion gear 19 of each pulse motor 18 and each up-and-down gear 5 can be precisely performed at the same time. Accordingly, a plurality of guiding mechanisms becomes unnecessary as a conventional apparatus, the parts counts is low and the apparatus can be provided at low cost.

Further, even when the pinion gear 19 interferes with a tooth tip of the up-and-down gear 5, the tooth tip of the up-and-down gear 5 can be hardly damaged because the boss of the up-and-down gear 5 evacuates along the slot B against the annular spring 8. The interference of the tooth tip is released with rotation of the pinion gear 19 and the up-and-down gear 5 is returned to its position by the action of the spring 8 when the tip can be engaged. Accordingly, the engagement can be always achieved.

Next, an operating panel 32 will be described. The operating panel 32 is made of a non-magnetic material, such as resin, aluminum, and brass. The operating panel 32 is a flat panel member and is detachably attached to the upper surface of the frame 2. A plurality of through holes 32a are formed in the surface of the operating panel 32 at positions corresponding to positions where the key units are disposed. Key tops 1 are inserted into respective through holes 32a.

A magnet 33 is embedded inside of each key top 1. The up-and-down pin 7 is made of metal. Therefore, the key tops 1 are not fell off or littered due to magnetism of the magnet 33 even when the user turns the tactile input/output apparatus upside down by accident.

On the upper surface of the operating panel 32, a dirt preventive sheet, such as a paper, is adhered. The dirt preventive sheet can be replaced if it becomes dirty. Therefore, the surface of the operating panel 32 is smooth to the feel, so that a feel of the operating panel 32 is improved.

Next, initialization of the tactile input/output apparatus structured as described above will be described.

First, when the pulse motor for back and forth driving 21 and the pulse motor for right and left driving 22 are driven to the origin position, the motor mounting frame 14 is positioned at the standard position shown in FIG. 44 with respect to the frame 2. Next, the pulse motor for back and forth driving 21 and the pulse motor for right and left driving 22 are run so that the pinion gear 19 is in a state shown in FIG. 45. By doing so, the pinion gear 10 of each pulse motor 18 engages the upper left up-and-down gear 5 in FIG. 45 in each key group.

Next, the up-and-down gears 5 are rotated by driving the pulse motors 18. After the standard position is detected by which the up-and-down pin 7 comes down and operates the push switch 12, the pulse motors 18 are driven at a predetermined angle in a reverse direction so that the up-and-down pins 7 are at a plane position shown in FIG. 43.

This operation is performed at an engagement position shown in FIGS. 45 to 48 in the same manner, so that all the key units are positioned at the plane position. When the key tops 1 are perceived that the key top 1 is not positioned at the same height as the upper surface of the operating panel 2 due to dimension error of parts or differences of feeling by the user, a predetermined correction value is set and recorded using a control program described later and the key tops 1 are driven to a correct position according to the value.

Next, operation for protruding the key tops 1 of the key unit will be described.

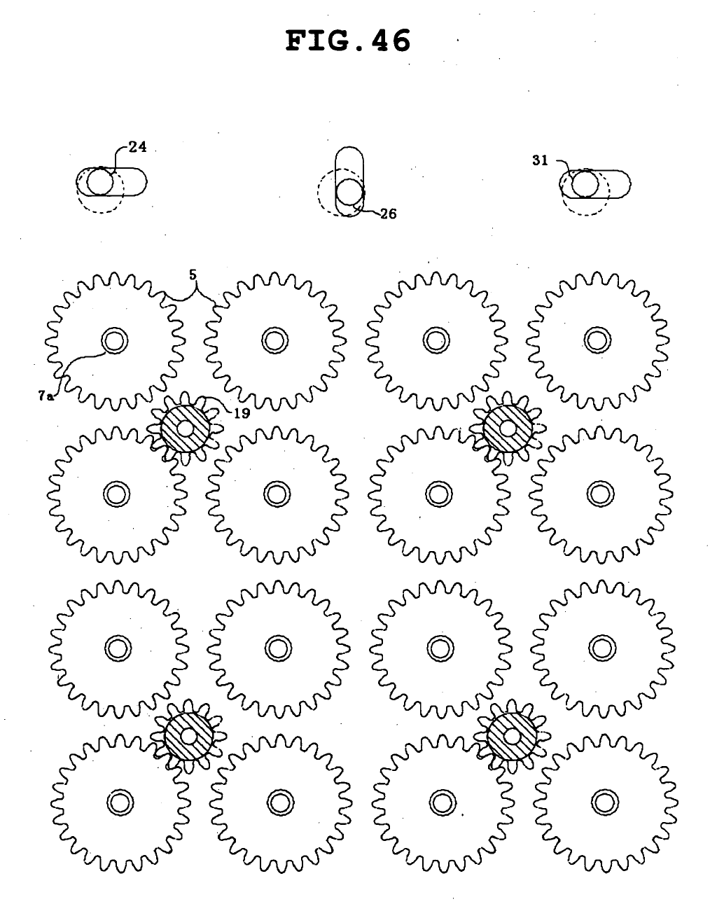

First, as is the same as the initialization, the motor mounting frame 14 is positioned to the position shown in FIG. 45. Then, the key tops 1 of the key units engaging with the pulse motors 18 are protruded to a predetermined height. This operation is performed at the positions shown in FIGS. 46 to 48.

As described above, all the key units can be set to arbitrary position by which operation for switching the rotation drive force of the pulse motors 18 is performed only four times.

At this time, it is preferred that the up-and-down pins are moved to the standard position once in several times so that displacement of the teeth at the time of engagement is resolved in order to not accumulate the displacement of the teeth.

When the all the key tops 1 are set to the predetermined height, key operation can be performed by the user. When the user presses the upper surface of the key top 1 while recognizing protruding state of the key top 1 by tactile sense, the push switch 12 is operated via the up-and-down gear 5, so that the key operation can be input.

Next, a second embodiment of the operating panel and the up-and-down pins of the invention will be described with reference to FIG. 49. In the frame 2, slots 35 having a width w1, a length t1, and a radius r1=w1/2 are formed. The slots 35 penetrates the frame. An up-and-down pin 34 has a threaded portion to be coupled to a screw hole of the up-and-down gear 5 at its lower portion. The up-and-down pin 34 has a key top portion 34c formed with a collar portion 34a and a vertical rib 34b, at its upper portion.

Each through hole 32a in the operating panel 32 has a recessed portion in which the vertical rib 32b fit so that a little clearance is provided between the through hole 32a and the key top portion 34c. The through hole 32a regulates rotation of the up-and-down pin 34. The key top portion 34c is slidably guided in an up and down direction by the through hole 32a and allows sliding of the up-and-down pin 34 due to evacuating operation of the up-and-down gear 5.

Further, when the up-and-down pin 34 rises with the rotation of the up-and-down gear 5, the collar portion 34a of the up-and-down pin 34 contacts the lower surface of the operating panel 32 and regulates rising of the up-and-down pin 34. Further, when the up-and-down gear 5 is rotated, the up-and-down gear 5 moves downward, so that the lower surface of the up-and-down gear 5 presses the upper surface of the press input portion of the push switch 12. Thereby, the switch is turned on and the standard of height of the up-and-down pin 34 can be detected.

Tactile operation means may be structured with a switch that detects a pressing of the key top protruding from the operating plane without adopting an up-and-down mechanism and may provide a plurality of identification states by outputting sound according to an identification state assigned to a pressed key top based on the pressing of the predetermined key top. In this case, input of operation needs to be given consideration such that an auxiliary input switch is provided. This corresponds with the invention claimed in claim 13.

Next, according to the drawings, a second embodiment of the tactile input/output apparatus corresponding with claims 16 and 19 will be described.

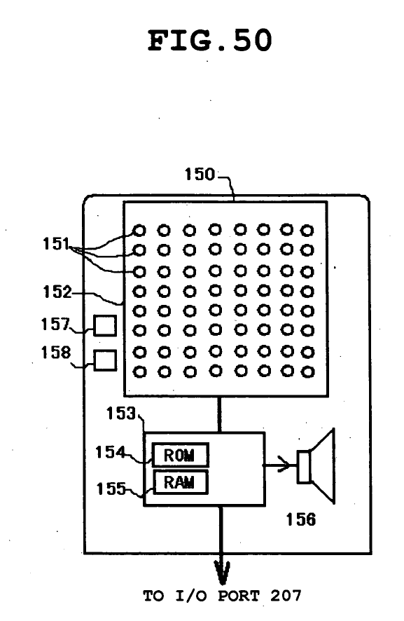

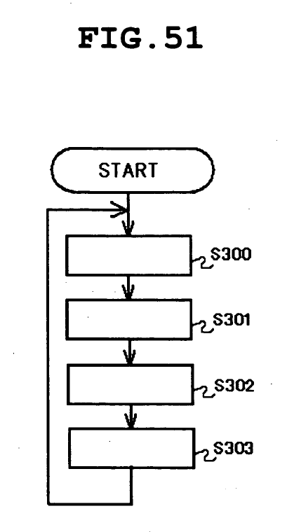

FIG. 50 is a diagram showing a structure of the second embodiment of the tactile input/output apparatus. FIG. 51 is a flowchart of a program stored in a one-chip microcomputer.

The tactile input/output apparatus shown in FIG. 50 includes a touch panel 150 and a one-chip microcomputer 153. A position where a fingertip touches a surface of the touch panel is detected. Then, the pressed position is output to the one-chip microcomputer 153. The touch panel 150 is well-known, so that a detailed explanation will be omitted.

On the surface of the touch panel 150, a plurality of protrusions 151 are formed at predetermined intervals. By touching with a fingertip, a position of the protrusion 151 on the surface of the touch panel 150 can be recognized. The protrusion 151 corresponds with a “tactile portion” claimed in claim 16.

When the user touches the protrusions 151 on the touch panel 150 with his/her fingertip, the position of the fingertip is detected. Thereby, the protrusions which is being touched with the fingertip of the user can be detected. The above-described structure and function correspond with “fingertip detecting means” claimed in claims 16 and 19.

Beside the touch panel 150, a shift switch 157 and a second shit switch 158 are provided which are to be operated at the time when an operation signal is input. The shift switch 157 and the second shift switch 158 correspond with “auxiliary operation means.”

A ROM 154 is stored in the one-chip microcomputer. The ROM 154 stored a control program which runs according to a flowchart shown in FIG. 51.

First, at S300, tactile operation means setting information provided from tactile operation means setting information supply means is input into the one-chip microcomputer via an I/O port of the personal computer and is stored in a RAM 155. Next, at S301, a signal from the fingertip detecting means is input to the one-chip microcomputer, so that a position of the tactile operation means to which the fingertip approaches is determined. At S302, a predetermined sound/voice is output from a buzzer 156 in accordance with the setting information of the tactile operation means.

Next, when a specific protrusion 151 is touched while the shift switch 157 is being pressed or when the shift switch 157 is pressed while the specific protrusion 151 is being touched, at S303, operation indicating a click is detected and an operation signal indicating the click operation is output to the personal computer 200.

On the other hand, when the second shift switch 158 is pressed while the specific protrusion 151 is being touched, at S303, operation indicating a double-click is detected and an operation signal indicating the double-click operation is output to the personal computer. After that, the processing returns to S300.

The tactile input/output apparatus structured as described above does not need the pulse motor and the drive mechanism. Accordingly, the tactile input/output apparatus can be manufactured at low cost.

Next, referring to the drawings, a third embodiment of the tactile input/output apparatus corresponding to claims 14 and 15 will be described.

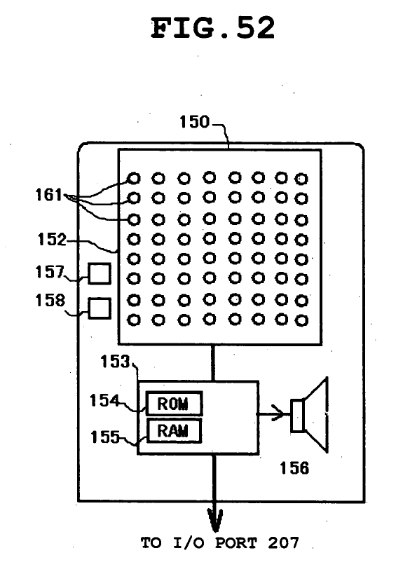

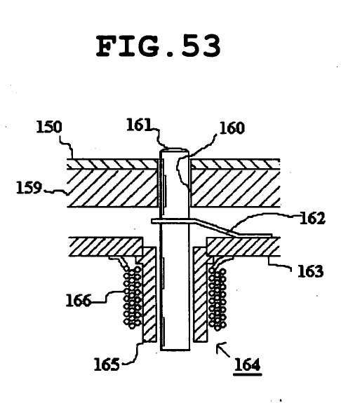

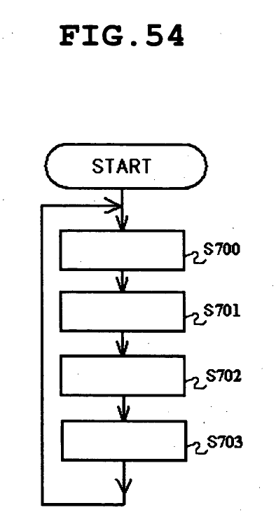

FIG. 52 is a diagram showing a structure of the third embodiment of the tactile input/output apparatus. FIG. 53 is a sectional view showing a structure of a vibration pin 161 constituting the tactile operation means. FIG. 54 is a flowchart of a program stored in an one-chip microcomputer.

As is the case with the second embodiment, this tactile input/output apparatus includes the touch panel 150 and the one-chip microcomputer 153. The touch panel 150 is attached to the upper surface of an operating plane 159.

Further, the shift switch 157 and the second shift switch 158 for inputting an operation signal are provided near the touch panel 150.

A plurality of through holes 160 penetrating the touch panel 150 and the operating plane 159 are formed in a matrix with 8 rows and 8 columns with predetermined pitches. The vibration pins 160 are inserted into respective through holes 160. The vibration pin 161 is a rod-like member formed by plating a magnetic material. A portion which transmits vibration to the fingertip is formed at an upper portion. A body is guided in the up and down direction by the through hole 160. The vibration pin 161 is supported at a predetermined height, with respect to a substrate 163, by a leaf spring 162 fixed at a middle, portion of the body. The lower portion of the body is magnetized so as to be driven by a coil member 164 described later.

The substrate 163 is attached under the operating panel 159 in parallel to each other and the coil member 164 is attached at the position corresponding to the vibration pin 161. The coil member 164 includes a bobbin 165 and windings 166. The magnetized lower portion of the body of the vibration pin 161 is inserted into the bobbin 165. Therefore, the vibration pin 161 is vibrated by which alternating current is passed through the windings.

In the embodiment, the coil member 164 is provided to each vibration pin 161. However, the vibration pins 161 may be vibrated using a vibrator by which several vibration pins 161 are connected under the operating plane 159.

In this case, when the fingertip detecting means determined that the vibration pin 161 being touched with the fingertip is a vibration pin that should be vibrated, the vibrator is vibrated. When the vibration pin 161 need not be vibrated, the vibrator is not vibrated. In such the structure, so long as the fingertip touches a single vibration pin 161, an identification state set to the vibration pin 161 touched with the fingertip can be correctly recognized by the vibration.

When this principle is further applied, the plurality of protrusions 151 may be formed on the surface of the touch panel 150 with predetermined pitches and the whole touch panel 150 may be vibrated using the vibrator. That is, when the fingertip detecting means determined that the protrusion 151 that is touched with the fingertip needs to be identified by vibrations, the vibrator is vibrated. When the protrusion 151 need not be identified, the vibrator is not vibrated. As the whole touch panel 150 is vibrated by the vibrator while the protrusion is being touched, the fingertip can recognize the vibrating state via the protrusion.

All the structures capable of transmitting vibrations to the fingertip described above correspond with “vibration means” claimed in claim 14. Further, the position of the fingertip touching the vibration pin 161 is detected by the touch panel 150, so that the vibration pin 161 which is touched by the user can be detected. This structure and function corresponds with the “fingertip detecting means” claimed in claim 15.

In the ROM 154 stored in the one-chip microcomputer 153, a control program which operates according to a flowchart shown in FIG. 54 is stored.

First, at S700, tactile operation means setting information provided from the tactile operation means setting information supply means is input into the one-chip microcomputer 153 via the I/O port 207 of the personal computer and is stored in the RAM 155 in the one-chip microcomputer 153. Next, at S701, a signal from the fingertip detecting means is detected and then the vibration pin 161 (or the protrusion 151) which the fingertip approaches is determined. At S702, the vibration pin (or the protrusion) is vibrated by which the coil member (or the vibrator) is driven by a drive circuit according to the setting information of the vibration pin (or the protrusion).

When the user presses the shift switch 157 or the second shift switch 158 while touching a specific vibration pin 161 (or a specific protrusion), at S703, operation indicating a single-click or a double-click is detected and operation signal indicating the single-click or the double-click is output to the personal computer 200. Then, the processing returns to S700.

As described above, the tactile input/output apparatus is structured so that only the vibration pin 161 touched with the fingertip is driven according to the setting state of the vibration pin 161, not all the vibration pins 161 provided to the tactile input/output apparatus. Therefore, electricity for driving the vibration pins 161 which are not being touched with the fingertip can be saved and a power supply circuit and the like can be downsized. Further, a noise to be caused by the vibrations of the vibration pins 161 can be restricted to a minimum.

Further, it is needles to say that the tactile input/output apparatus is easy to be used if it is structured such that a touch panel that can individually detect several positions of fingertips on the touch panel is provided and the detected vibration pins 161 on which the fingertips are positioned are individually driven.

Next, the personal computer 200 will be described with reference to the drawings. The personal computer 200 is so-called a personal computer and is now well-known apparatus, so that a detailed explanation will be omitted. The personal computer 200 used in the embodiment includes a CPU 201, a memory 202, an FDD 203, a HDD 204, a CD-ROM drive 205 (hereinafter referred to as a CDD), a modem 206, an I/O port 207, a sound synthesis circuit 208, a voice input circuit 209, and a video card 210, which are electrically connected each other via a control bus 212. A CRT 211 may be provided for displaying a way how to use the apparatus. The CRT 211 is used by an instructor (a light-dependent person) to confirm an operating condition of the apparatus on a screen of the CRT 211 to instruct a visually impaired person, who is unaccustomed to operating the apparatus. Accordingly, the instructor can properly instruct the visually impaired person how to use the apparatus.

Operation of the CPU 201 is defined in a control program stored in the HDD 204. The CPU 201 properly loads the program in the HDD 204 into the memory 202 and executes the program. The CPU 201 reads data from the HDD 204 or the CD-ROM inserted in the CDD or data provided from a data providing server (not shown) of the Internet connected via the modem 206. Then, the CPU 211 performs processing by storing the data in the memory 202, or the HDD 204 if necessary.

Further, when the CPU 201 sets predetermined information, the sound synthesis circuit 208 converts a sound signal into a digital form and generates a predetermined sound/voice from the speaker 300 connected to the sound synthesis circuit 208. The voice input circuit 209 inputs a voice signal, performs a voice analysis and outputs the information included in the voice as text data. The well-known technology is used for the components of the personal computer 200. Detailed explanations of the components of the personal computer 200 will be omitted as the details are not relevant to the essence of the invention.

Here, the sound synthesis circuit 208 has a structure of a circuit for a four-channel stereo. Information relating to sound/voice set by the CPU 201 includes a respective sound/voice set value for the left front speaker, the left rear speaker, the right front speaker, and the right rear speaker. By changing the set values, it can be heard as if a place where the sound generated is being changed.

For the visually impaired, the sense of hearing is a very important faculty that they have. Therefore, the sound synthesis circuit 208 is installed with multiple safety circuits, such as a current limitation circuit, so that sound/voice having sound pressure which is below a predetermined level originates from the speaker. Accordingly, an accident that damages the sense of hearing of the user, such that sound/voice having anomalous high sound pressure is originated due to malfunction of the CPU 201, bugs in a program, data corruption, deterioration of electronic components, will not occur.

Next, a data file to be used in an explanation of the embodiment will be described with reference to the drawings. These data are assigned respective predetermined file names by a function of file system provided an OS of the personal computer 200 and are readably stored in the FD, the HDD 204, and the CD-ROM. These data may be data downloaded from a data server (not shown) existing on a network via the modem 206 connected to a telephone line or may be data representing various operating states generated with the operation of the personal computer.

Generally, there are various formats of data having a structure that can be two-dimensionally expanded, such as pictorial data, table data, word processor data including layout information, HTML format data of a homepage on the Internet and data representing a hierarchical structure. Explaining these data formats one by one is depart from a purpose for explaining an essential of the invention in the embodiment. Therefore, a simple format is specified in terms of necessarily of explaining the essential of the invention of the embodiment and a specific data according to the format will be described hereinafter.

Further, it would be understood that the scope of the invention is not restricted to the application to the information having a structure that can be two-dimensionally expanded according to the format shown in the embodiment. However, if an appropriate algorithm is applied to each format of data widely used as described above, it goes without saying that the effects and the purpose can be achieved by applying the invention. In a fist part of an explanation of the invention, the following situation will be described. Assuming that “TOKKYO HITOSUJI KUN” who is a visually impaired user found that he forgot to input a date in a letter to “GANBA HTSUMEI SENSEI” after he selected the letter from a plurality of document data and read it, so that “TOKKYO HITOSUJI KUN” inputs a date in the letter.

In a latter part, an explanation will be given to a situation where “TOKKYO HITOSUJI KUN” accesses the Internet using the tactile input/output apparatus and browses a homepage of “GANBA SENSEI.”

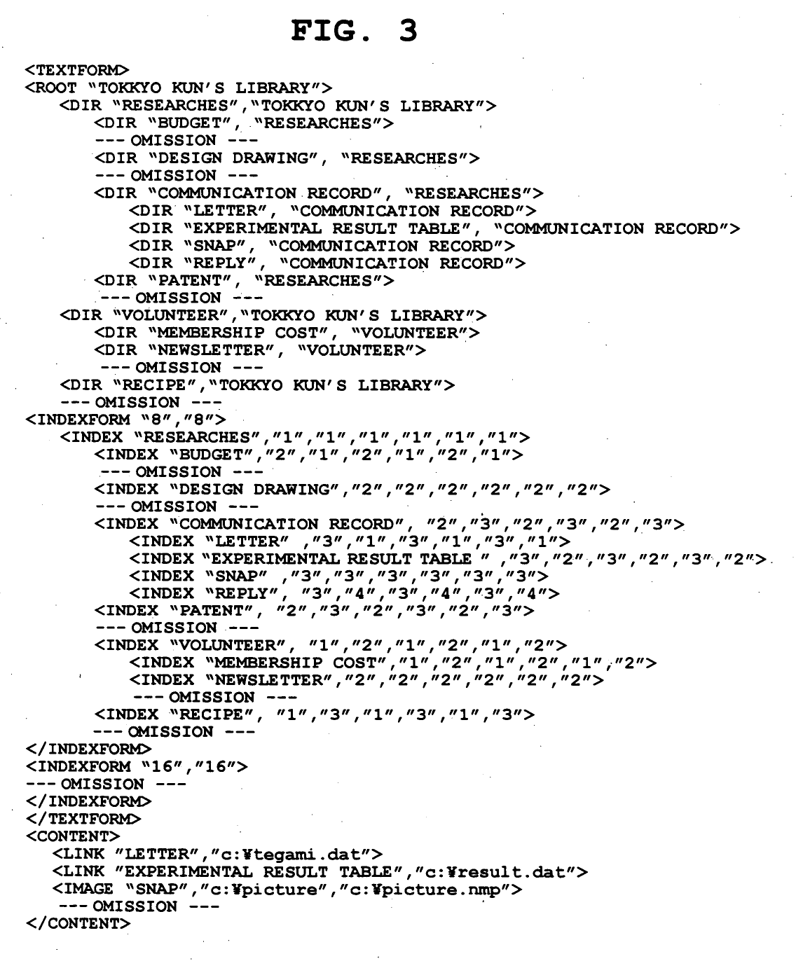

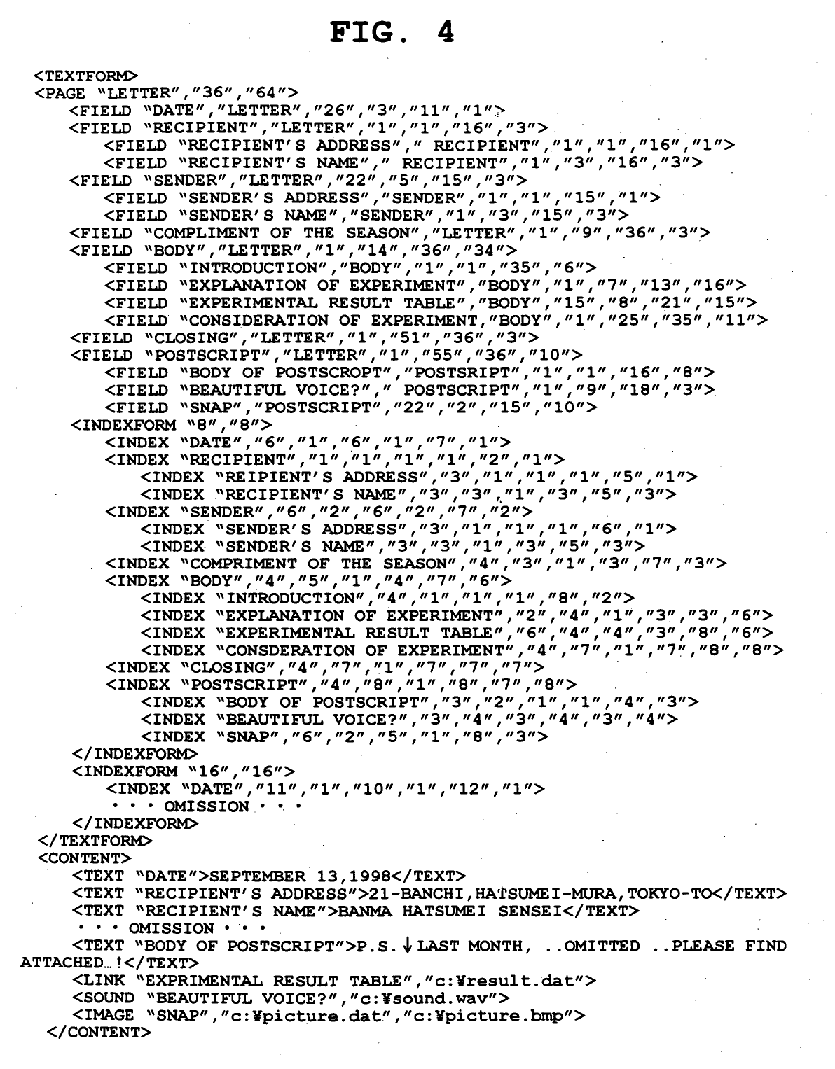

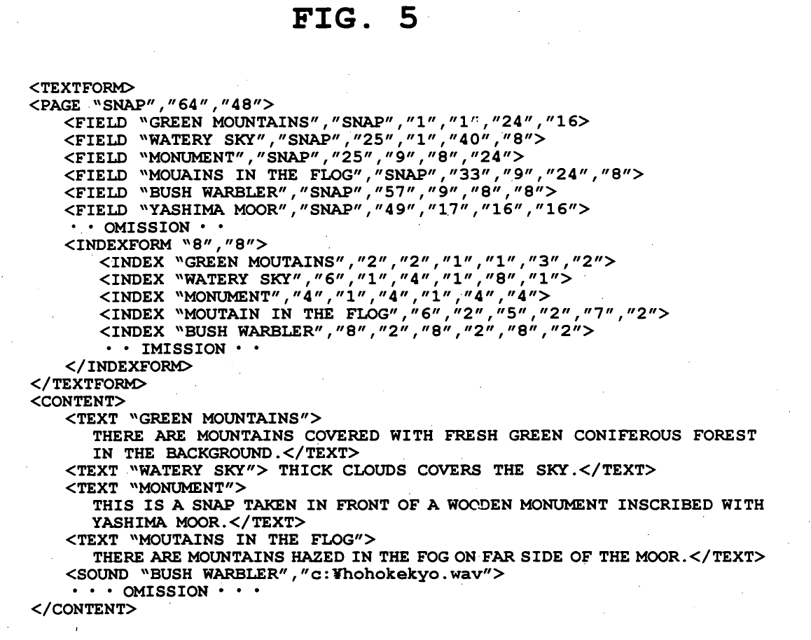

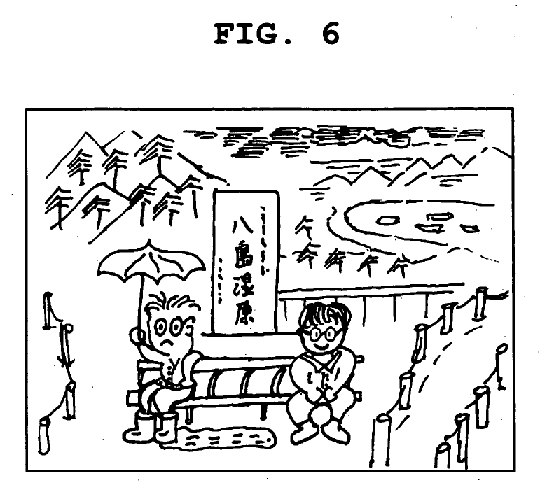

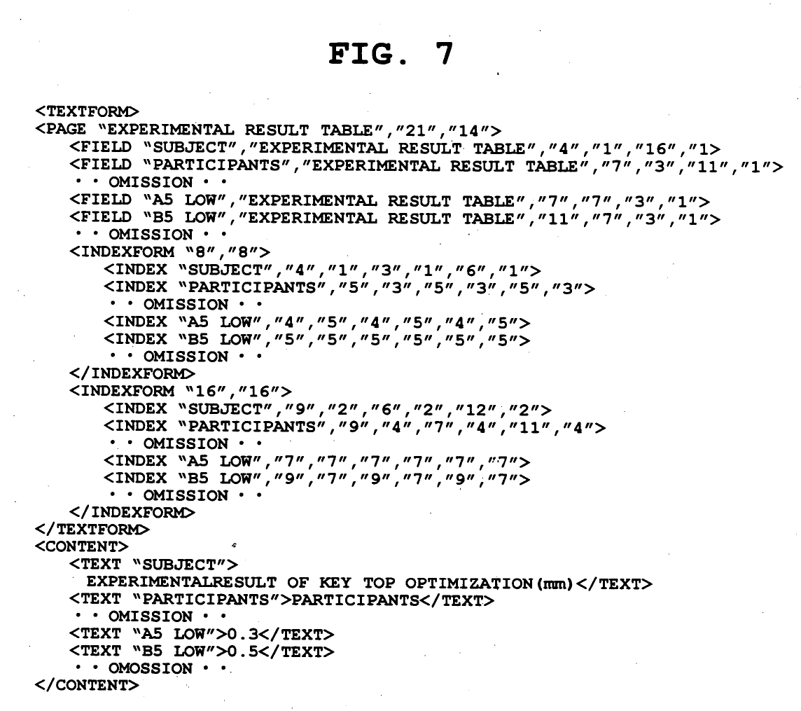

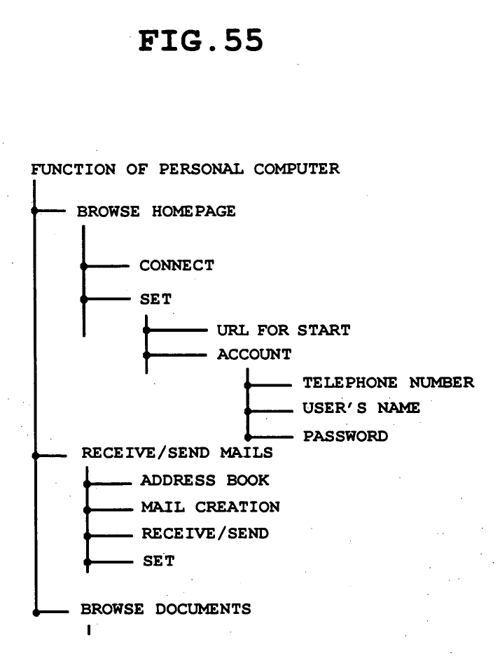

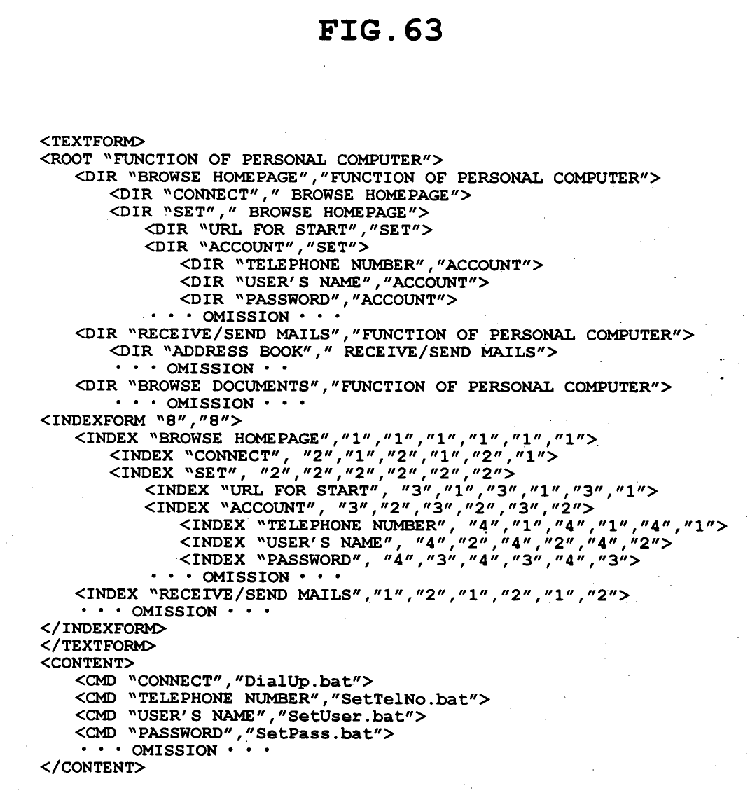

FIGS. 3 to 7 and 63 are diagrams of data structures showing examples of information to be displayed in the embodiment of the invention. In particular, FIG. 3 is a diagram showing data storing a hierarchical control structure of a document to be read (hereinafter referred to as document control data.). FIG. 4 is data which has been edited and is named as a “letter” written in a control data (hereinafter referred to as document data. A physical file name is “c:¥tegami.dat”). FIG. 5 is data named as a “snap” described in the “letter” (likewise, “c:¥picture.dat”). FIG. 6 is a diagram showing pictorial data that is a base of an image data of the “snap” (likewise, “c:¥picture.bmp”). FIG. 7 is a diagram showing data named as an “experimental result table” described in the “letter (likewise, c:¥result.dat”). Further, FIG. 63 is data corresponding to information related to functions of a personal computer shown in FIG. 55 and may be handled as document control data in a program shown below.

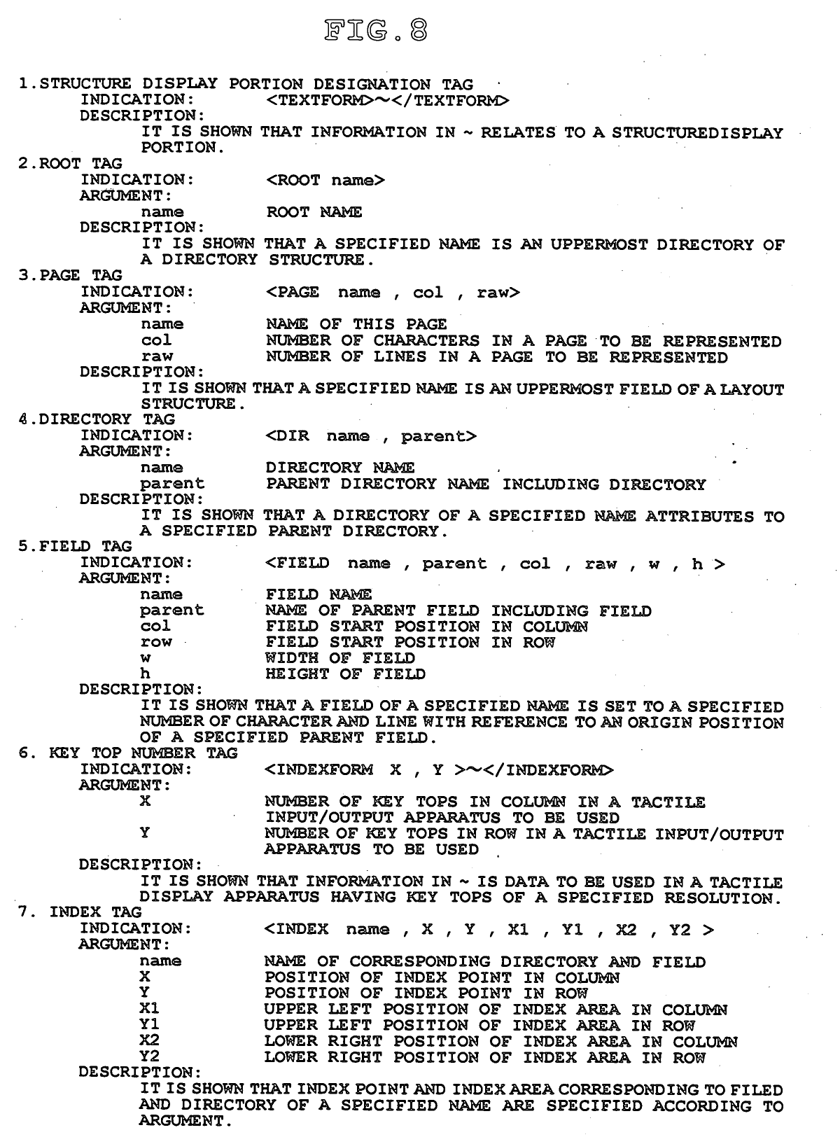

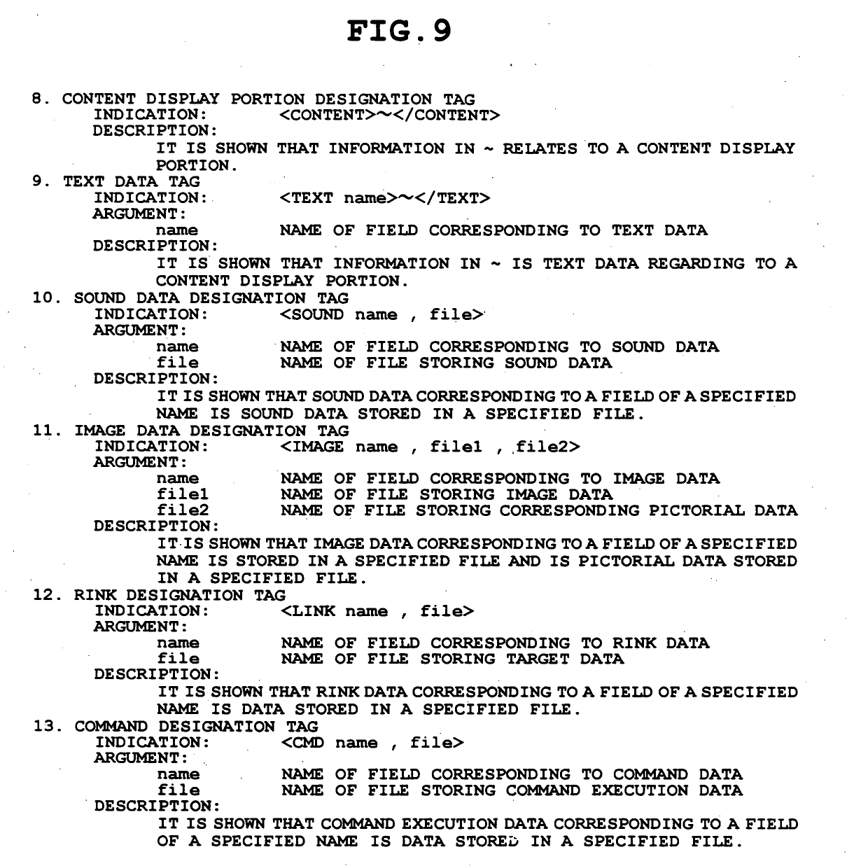

As is seen from the drawings, control data and document data include information called as a “tag” enclosing format descriptor with “< (greater than sign)” and “> (smaller than sign)” and other text data. For reference, definitions of the tags included in data to be explained in the embodiment are shown in FIGS. 8 and 9. Here, there are two kinds of tags. One is a “pair tag” including a pair of a “start descriptor” that is a predetermined format descriptor and an “end descriptor” that is added a “/” character to a front of the format descriptor of the start descriptor. Another is a “single tag” that includes only the start descriptor.

Taking document control data of “TOKKO KUN'S bookshelf” shown in FIG. 3 as an example, information in the 2nd line through the 36th line is designated as a structure display portion with a structure display portion designation tag (<TEXTFORM>˜</TEXTFORM>). Further, with a root tag (<ROOT “TOKKYO KUN's bookshelf”>), it is shown that the document control data has a hierarchical structure with the “TOKKYO KUN's bookshelf” as its root. With directory tags (<DIR name, parent>) shown in the 3rd line trough the 20th line, it is shown that a level of name shown by a “name” is positioned under a level of a name shown by a “parent.”

For example, with tags whose “parent” is the “TOKKYO KUN's bookshelf” (a total of three tags), it is shown that a level immediately below the “TOKKYO KUN's bookshelf” that is an uppermost concept of a control structure is structured with three name directories; 1. Researches, 2. Volunteer, and 3. Recipe. Likewise, a name of parent directory of other directory tags is designated with the “patent”.

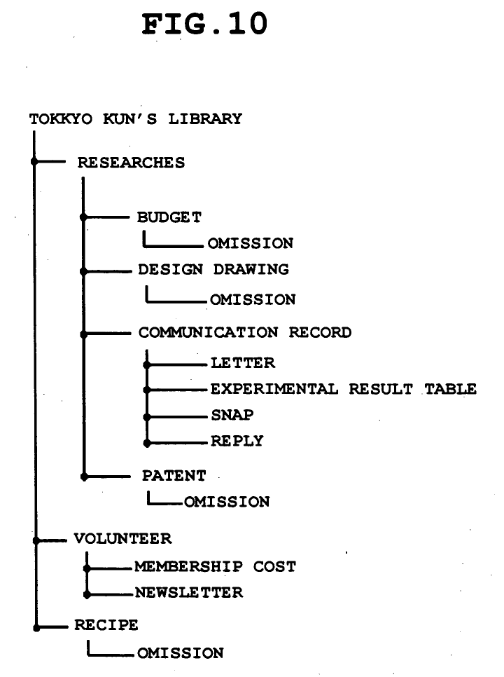

As described above, with the information of the directory tags of the structure display portion, the hierarchical structure of the directories whose root is the “TOKKYO KUN's bookshelf” is expressed and is shown in FIG. 10 in detail.

As to document data, likewise, for example, in document data of the “letter” shown in FIG. 4, with a structure display portion designation tag, information in the 2nd line through the 44th line is designated as a structure display portion of the document data. Likewise, with a page tag (<PAGE “letter”, “36”, “64”>) provided in the 2nd line, it is shown that this document data is a document named as the “letter” formed with 36 characters by 64 lines. With field tags provided in the 3rd line through the 20th line, a character area which is an area where the information of each field occupying in the letter (referred to as a field area) is shown by the character. With a parameter of the “parent” of each field tag, the fields are hierarchically shown by relatively establishing hyponymy with each other. For example, with tags whose “parent” is the “letter” (a total of seven tags), it is shown that fields included in a level immediately below the “letter” that is the uppermost concept of the document. Names of the seven fields are 1. Date 2. Recipient, 3. Sender, 4. Compliments of the season, 5. Body 6. Closing, and 7. Postscript. Likewise, a name of a parent field of other field tags is set to the “parent.” An upper left position of a character area of the field is designated as reference with an origin position in the character area of the parent field.

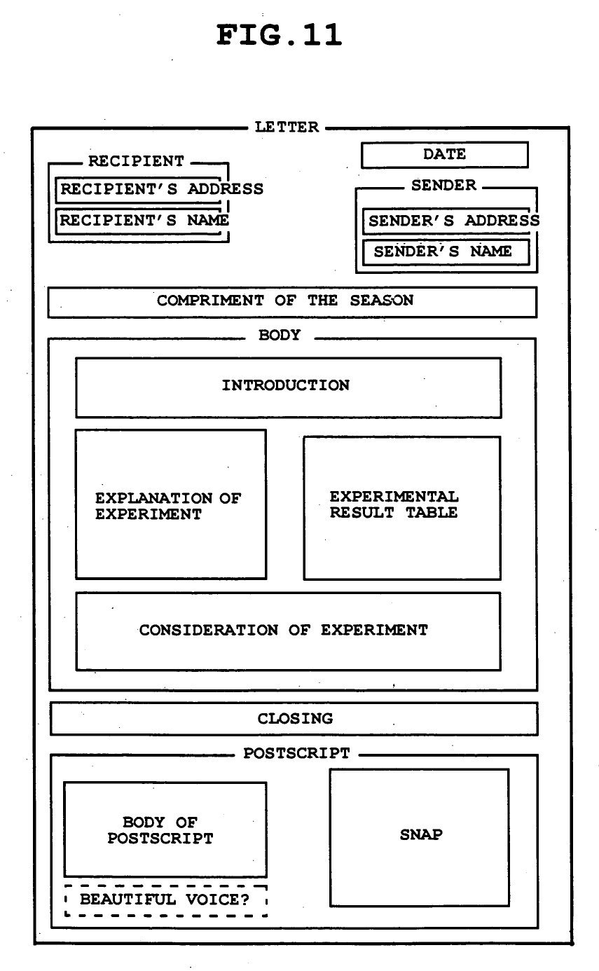

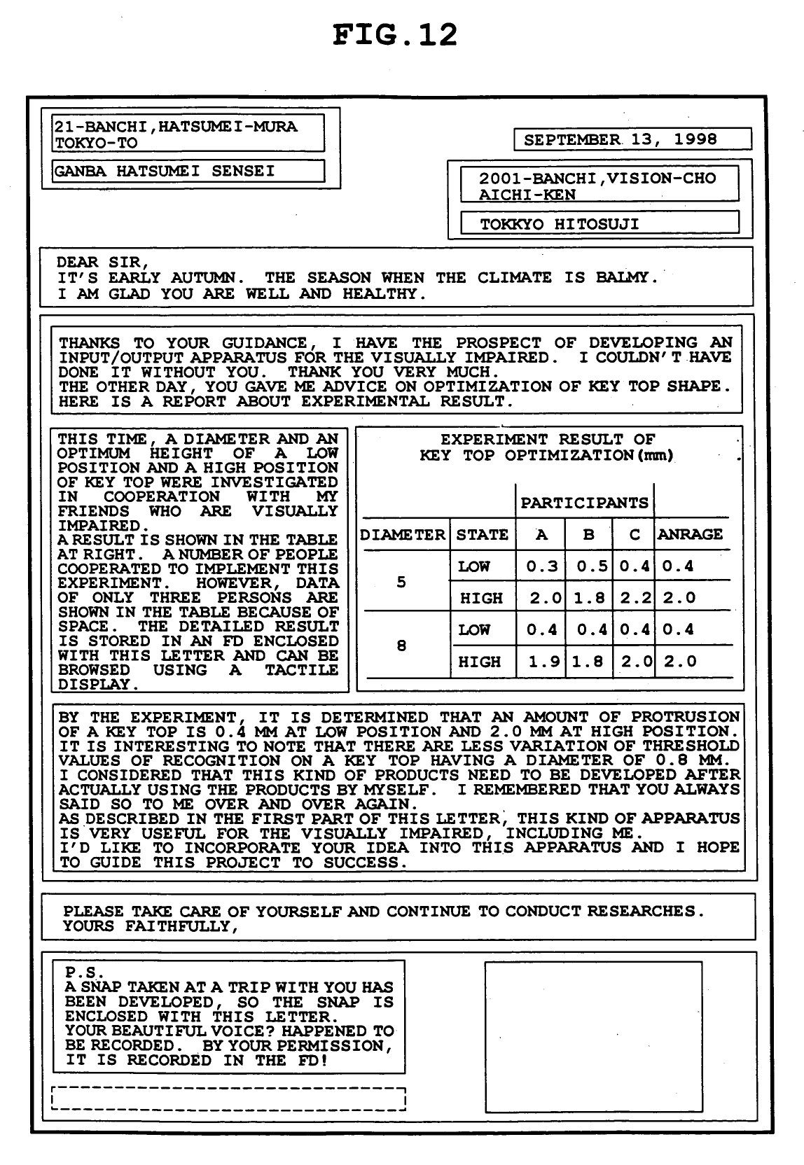

As described above, with the information of the field tags of the structure display portion, a layout and a hierarchical structure of the fields of the letter are expressed. The fields of the “letter” of the embodiment are shown in FIGS. 11 and 12 in detail.

Further, with a key top number tag (<INDEXFORM A, B>˜</INDEXFORM>), it is designated that an index tag between tags (<INDEX name, x, y, x1, y1, x2, y2>) is information for the tactile input/output apparatus having key tops of an array with B rows and A columns. With the index tag, a representative key top position (shown by x and y) corresponding to the fields and directories named as the “name” (hereinafter referred to as an index point) and a rectangular area (shown by x1, x2, y1, y2) (hereinafter referred to as an index area) are designated. In the embodiment, values of a tactile input/output apparatus having key tops of an array with 8 rows and 8 columns and a tactile input/output apparatus having key tops of an array with 16 rows and 16 columns are designated.

Values of X, Y, x1, x2, y1, y2 of the index tag for the field designate the key top positions corresponding to a state where a character area of a field named as a “parent” of the index tag is expanded in a predetermined area of key tops of a tactile input/output apparatus. The values of index tag X, Y, x1, x2, y1, y2 are X=x1=x2 and Y=y1=y1. X shows a depth of the level and Y shows a rank of a direction of lists in the same level.

The information of the index tag of the structure display portion designated as described above is referred by a control program described later and is to be basic information for representing a directory structure and a layout with an arrangement of key tops 1. An explanation will be given later how to express the information with the key tops.

Next, in each data, a content display portion is designated with a content display portion designation tag (<CONTENT>˜</CONTENT>). The contents of the content display portion are designated so as to correspond to the names designated with the “name” of the fields designated in the structure display portion. For example, a content corresponding to a field named as an “address of recipient” of the “letter” is designated with a text tag (<TEXT “address of recipient>˜</TEXT>). To be more specific, text data of “21 Hatsumei-mura, Tokyo-to”, which is to be sound synthesized and is output by a control program, described later, is designated.

Further, for example, a content corresponding to the field of the “experimental result table” in the 14th line of the “letter” is designated with a rink tag (<LINK “experimental result table”, “c:¥result.dat”>). To be more specific, a file name of document data of “c:¥result.dat” to be newly read by the control program described later is designated. Further, for example, a content corresponding to a field of the “snap” in 20th line of the “letter” is designated with an image data tag (<IMAGE “snap”, “c:¥picture.dat”, “c:¥picture.gif”>). To be more specific, a file name of, document data of “c:¥picture.dat” to be newly read and a file name of pictorial data of “c:¥picture.bmp” to be output in an image displaying apparatus for reference by the control program described later are designated.

Further, for example, a content corresponding to a field of “beautiful voice?” in 19th line of the “letter” is designated with a sound data tag (<SOUND “beautiful voice?”, “c:¥sound.wav”). To be more specific, a sound file of “c:¥sound.wav” (data in .wav format is standard sound format data) to be played as sound information by the control program described later is designated. Further, for example, a content corresponding to a directory of a “telephone number” in the 8th line of the “functions of personal computer” is designated with a command tag (<CMD “telephone number”, “SetTelNo.bat”>) in the 33rd line. To be more specific, according to data stored in a designated file, a predetermined unit function (here, a telephone number is set by inputting it using a microphone.) is performed.

The information divided by the field or the directory described above corresponds with “block unit information” claimed in claim 1.

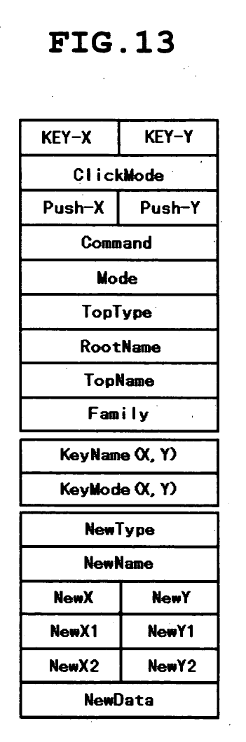

Next, referring to FIG. 13, a storage area set in the memory 202 will be described. “KEY-X” and “KEY-Y” are storage areas for storing the number of rows and columns of key tops 1 of a tactile input/output apparatus to be used, respectively. “Mode” is a storage area for storing a current operating mode. “KeyName (X, Y)” is a storage area for storing a field name assigned to a key top 1 at X row by Y column. “KeyMode (X, Y) is a storage area for storing setting information of a protrusion amount of the key top 1 at X row and Y column. Information to be stored in the “KeyName (X, Y)” and the “KeyMode (X, Y)” corresponds with “information related to a correspondence with the tactile operation means that shows a correspondence between the block unit information and the plurality of the tactile operation means” claimed in claim 1.

Further, “ClickMode” is a storage area for storing an operating state of key tops. “Push-X” and “Push-Y” are storage areas for storing the numbers of a row and a column of a pressed key top. “Command” is a storage area for storing command data input by voice. “TopType” is a storage area for storing a type of data whether data displayed on the tactile input/output apparatus is document control data or document data. “RootName” is a storage area for storing a name of a root of document control data. “TopName” is a storage area for storing a name of presently displayed data. “Family” is a storage area for storing names of directories which have a parent-child relationship with each other in the direction from top to bottom. “NewName”, “NewX”, “NewY”, “NewX1”, “NewY1”, “NewX2”, and “NewY2” are storage areas for storing data to be used in a subroutine “NewIndex” and these will be described later.

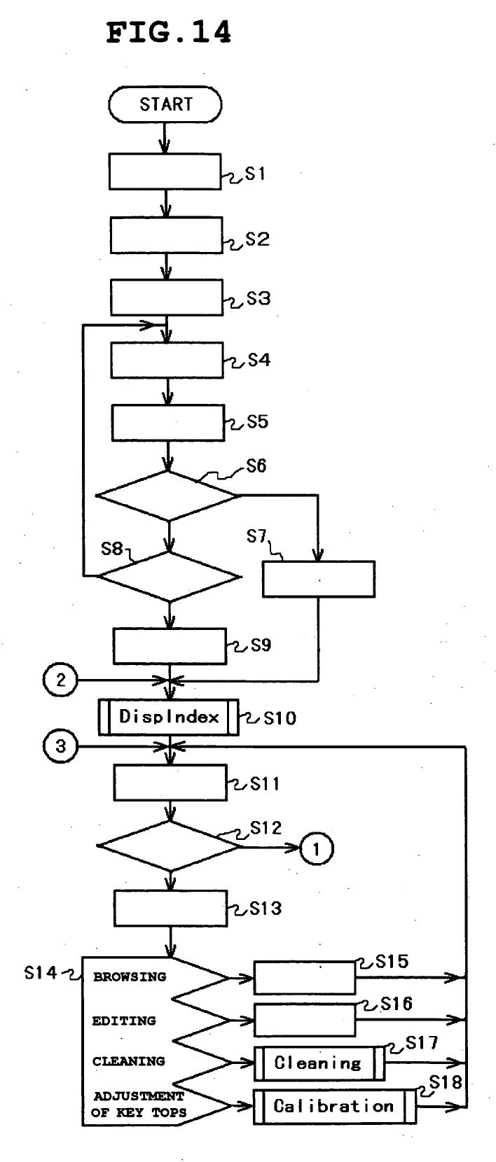

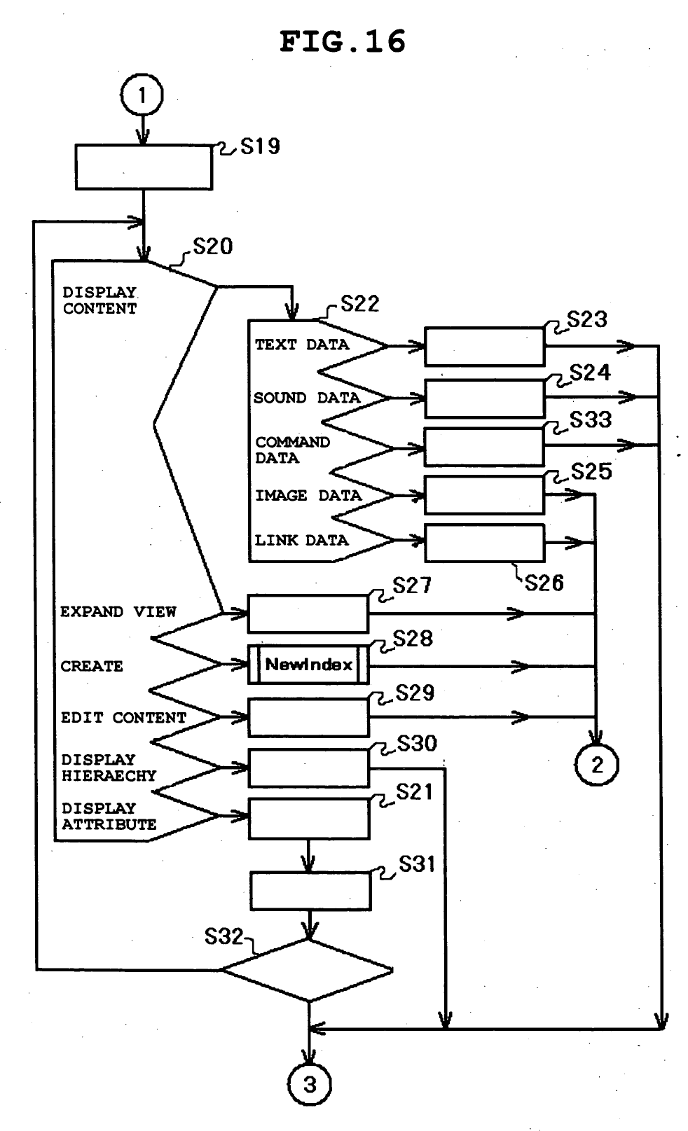

Next, a main routine of the embodiment of the invention will be described with reference to flowcharts in FIGS. 14 and 16. First, at step S1 (hereinafter, a step is referred to such as S1), when power of the personal computer 200 is turned on, predetermined initialization is performed. After that, a control program is loaded into the memory 202 and the control program starts running. First, a setting condition of a DIP switch 106 is read and a specification of a tactile input/output apparatus is determined. Then, the number of key tops 1 in rows and columns are stored in the “KEY-X” and the “KEY-Y”, respectively. In the embodiment, the tactile input/output apparatus having key tops with eight rows by eight columns is used, so that it is set that KEY-X=8 and KEY-Y=8.

At S2, a value of a storage area “CallTimes” (not shown) stored in the HDD 204 is checked whether it is at a certain value or greater. When the value is at the certain value or greater, a subroutine “Cleaning” is called.

At S3, the aforementioned initialization can not be properly performed when the key tops 1 are firmly wedged. Therefore, a voice message to the effect that “please move your hand off from the key tops to perform initialization.” is output to the user. After that all the key tops are driven and amount of protrusion of the key tops 1 are set to 0 mm by performing the initialization of the key tops described above. Further, the Mode is initialized to 0 which is a value indicating a browse mode.

At S4, a voice message to the effect that “please input a file name of desired data into a microphone.” is output via the sound synthesis circuit 208.

At S5, the file name is input via the voice input circuit 209.

At S6, a file having the input file name is opened so that the file can be read thereform and written therein, and a root tag (<ROOT name>) is input. When the root tag can be input, the processing proceeds to S7. When the root tag can not be input, the processing proceeds to S8.

At S7, 0 is set in the TopType and a “name” of the root tag is stored in the RootName. After a value of the “name” is set in the TopName, the processing jumps to S10.

At S8, a page tag is input. When the page tag can be input, the processing proceeds to S9. When, the page tag can not be input, the processing returns to S4.

At S9, 1 is set in the TopType. A value of the “name” is set in the TopName. Then, the processing proceeds to S10.

At S10, a subroutine “DispIndex”, described later, is executed. Each key top is assigned to respective fields or directories. The key tops 1 of the tactile input/output apparatus 100 each are driven and set to a predetermined state.

Here, the functions executed by the predetermined operation in the “DispIndex” at S4 to S10 correspond with “information setting means that sets predetermined information in information storage means” claimed in claim 1.

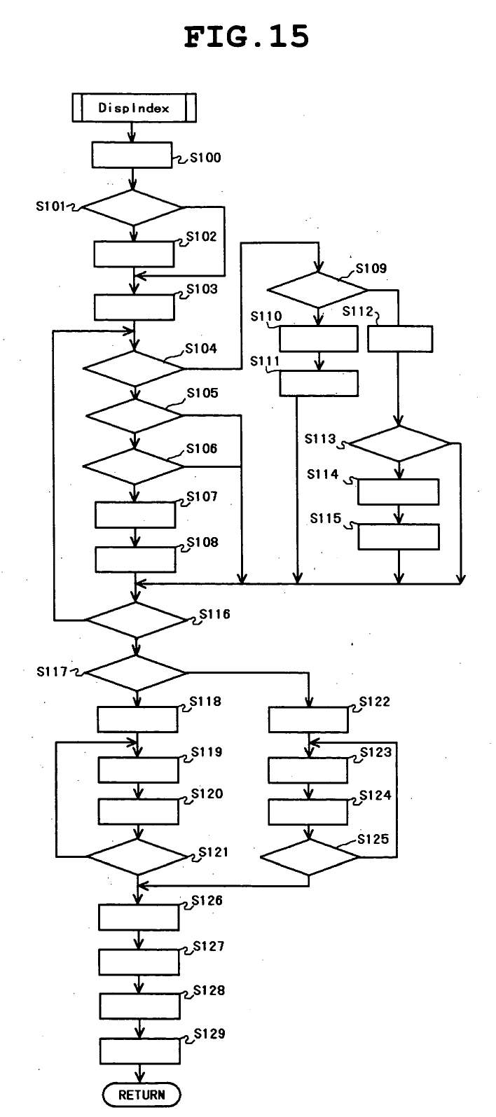

Next, operation of the subroutine “DispIndex” will be described with reference to a flowchart shown in FIG. 15.

First, at S100, a summation stored in the storage area “CallTimes” of the HDD 204 is incremented. Elements of the KeyName ( ) are initialized to be a null character and the elements of the KeyMode ( ) are initialized to 0.

At S101, the TopType is determined. When the TopType is 0, data is document control data, so that the processing proceeds to S102. When the TopType is 1, data is document data, so that the processing jumps to S103.

At S102, directory data is determined. Directory data which is a direct ancestry is retrieved by following roots, such as a parent directory of the TopName, a root of the parent directory, and the RootName. After the directory data is stored in a Family, the processing proceeds to S103. In the example of “TOKKYO KUN's bookshelf” in the embodiment, when RootName=“TOKKYO KUN's bookshelf” and TopName=“letter”, a parent-child relationship such that RootName=“TOKKYO KUN's bookshelf>researches>communication record>letter” is retrieved.

At S103, values of the “KEY-X” and the “KEY-Y” are read. When KEY-X=8 and KEY-Y=8, first index data is read from index data to be displayed between <INDEXFORM “8”, “8”> and </INDEXFORM>. When KEY-X=16 and KEY-Y=16, first index data is read from index data to be displayed between <INDEXFORM “16”, “16”> and </INDEXFORM>. When there is no index data corresponding to the number of the key tops, index data between <INDEXFORM “8”, “8”> and </INDEXFORM> is adopted by default.

At S104, TopType is determined again. When the TopType is 0, the data is document control data, so that the processing proceeds to S109. When the TopType is 1, the data is document data, so that the processing proceeds to S105.

At S105, field data named as the “name” of the read index data is read, and the processing proceeds to S116. When applicable field data can not be read, the processing jumps to S116.

At S106, the name shown in the “parent” of the field data read at S105 is determined. When the name is the same as the TopName, the processing proceeds to S107. When the name is different from the TopName, the processing jumps to S116.

At S107, for each key top 1 specified in an index area (indicated with x1, y1, x2, y2) of the index data, a name which is set in the “name” of the index data is set in the KeyName. In the KeyMode, 1 which indicates an “area” is set.

At S108, for key tops 1 specified in an index point (indicated with X and Y), a name which is set in the “name” of the index data is set in the KeyName (X, Y). In the KeyMode (X, Y), 2 is set. After that, the processing jumps to S116.

At S109, first, it is determined whether the name shown by the “name” of the read index data is included in the Family (that is, whether is it a propositus or a direct ancestry). When the name is included in the Family, the processing proceeds to S110. When the name is not included in the Family, the processing jumps to S112.

At S110, for the key top specified as an index point (indicated with X and Y) of the index data, name shown by the “name” of the index data is set in the KeyName (X, Y). At S111, 3 is set in the KeyMode (X, Y). Then, the processing jumps to S116.

At S112, directory data of the name shown by the “name” of the read index data is read.

At S113, it is determined whether the name of “parent” of the directory data (that is, the parent directory of the directory) is included in the Family. When the name is included in the Family, the processing proceeds to S114. When the name is not included in the Family, the processing jumps to S116.

At S114, for the key top specified as the index point (shown by X, Y) of the read index data, a name shown by the “name” of the index data is set in the KeyName. At S115, 2 is set in the KeyMode (X, Y), and then the processing jumps to S116.

Next, at S116, it is determined whether all index data are processed. When all the index data are yet to be processed, the next index data is read and the processing returns to S104. When all the index data are processed, the processing jumps to S117.

Next, at S117, when the TopType is 1, the processing proceeds to S118. When the TopType is 0, the processing jumps to S122.

At S118, the values of the “KEY-X” and the “KEY-Y” are read again. When KEY-X=8 and KEY-Y=8, first index data is read from the index data between <INDEFORM “8”, “8”> and </INDEXFORM> of the document data to be displayed. When KEY-X=16 and KEY-Y=16, first index data is read from the index data between <INDEFORM “16”, “16”> and </INDEXFORM> of the document data to be displayed.

At S119, field data of a name shown by the “name” of the read index data is read and the name set in the “parent” is selected.

Next, at S120, for all key tops whose names are set in the Key Name, it is set that KeyMode=3.

At S121, it is determined whether all index data are processed. When all the index data are yet to be processed, the next index data is read and the processing returns to S119. When all the index data are processed, the processing proceeds to S126.

On the other hand, at S122, the values of the “KEY-X” and the “KEY-Y” are read again. When KEY-X=8 and KEY-Y=8, first index data is read from the index data between <INDEFORM “8”, “8”> and </INDEXFORM> of the document data to be displayed. When KEY-X=16 and KEY-Y=16, first index data is read from the index data between <INDEFORM “16”, “16”> and </INDEXFORM> of the document data to be displayed.

At S123, directory data of a name shown by the “name” of the read index data is read and the name set in the “parent” is selected.

Next, at S124, for all the key tops whose names are set in the Key Name and the KeyMode are not 3, the KeyMode is set to 4.

At S125, it is determined whether all index data are processed. When all the index data are yet to be processed, the next index data is read and the processing returns to S123. When all the index data are processed, the processing proceeds to S126.

As described above, at the steps from S100 to S125, all the key tops are set their values of the KeyName and the KeyMode.

Next, at 126, in advance of driving and setting of the key tops, a voice massage to the effect that the amount of protrusion of the key tops are being changed is provided by voice so that the user does not perform any key operation.

Next, at S127, a pattern of the key tops 1 of the tactile input/output apparatus being used are displayed on the CRT 211. According to the values set in the KeyMode, key tops are displayed on the CRT 211. When a key top is set to 1, the key top lights with green. When a key top is set 2 or 4, the key top 1 protrudes 0.8 mm and lights with red. When a key top is set to 3, the key top 1 protrudes 2.0 mm and flashes with red.

At S128, information regarding the directory or the field set in the KeyName is displayed on the CRT 211. A form of the display to be displayed on the CRT 211 is, for example, that the entire document is displayed and characters in an area assigned to the key tops are displayed with different colors. Further, a hierarchical structure of the directory data is displayed and icons representing directories assigned to the key tops are displayed with different colors. As described above, a setting state of the key tops and a document being read are displayed on the CRT 211, so that the light-dependent person who instructs the visually impaired person can surely understand the current usage condition and can properly instruct the visually impaired person.

Next, at S129, a voice massage to the effect that setting of the key tops 1 are completed is provided by sound. A buzzer sound may be started sounding at S126 and may be stopped at S129. Any methods can be accepted if the visually impaired can understand that the key tops are being set. Thus, the processing of the subroutine “DispIndex” is completed.

As described above, the functions to be effectuated by the series of the operations of S126 to S129 correspond with “the tactile operation means setting information supply means that receives input of information related to a correspondence with tactile operation means of the information storage means supplies tactile operation means setting information to the tactile operation means setting means” and the “tactile operation means setting means that sets a plurality of the tactile operation means to be in respective predetermined states based on tactile operation means setting information” claimed in claim 1.

Next, when the subroutine “DispIndex” is finished, the processing proceeds to S11. At S11, an operating state of the tactile input/output apparatus is detected such that “no operation”, which shows that any of the key tops 1 are operated, “single click”, which shows that any one of the key tops 1 is explicitly operated, and “double click”, which shows that any one of the key tops 1 is operated twice within a certain time, by an operation signal input to the key tops 1 of the tactile input/output apparatus. Then, a value of any one of “N”, “S”, or “D” is set in “ClickMode”. When any one of the key tops 1 has been pressed, values of the row and the column where the pressed key are positioned is stored in the “Push-Y” and the “Push-X”, respectively. After that, the processing moves to S12.

The specific implementation of the method for inputting operation varies depending on types of the tactile input/output apparatus to be used. It needless to say that a program should be created to conform to the type of the tactile input/output apparatus to be actually used.

The function effectuated by the operation of S11 corresponds with “operation signal selecting means that selects and outputs an operation signal corresponding to a predetermined operation method based on operation performed in a predetermined area” claimed in claim 1.

Next, at S12, the ClickMode is determined. When the ClickMode is N, the processing proceeds to S13. When the ClickMode is S or D, the processing proceeds to S19 in FIG. 16.

At S13, a command vocalized by the user is input via the voice input circuit 209. When an effective command is vocalized, the vocalized command is converted into text data and is set in “Command”.

At S14, the “Command” is determined. When the command is “browsing”, the processing proceeds to S15. When the command is “editting”, the processing proceeds to S16. When the command is “cleaning”, the processing proceeds to S17. When the command is “adjustment of key tops 1”, the processing proceeds to S18.

At S15, 0 which shows a browse mode is set in “Mode”. Then, the processing returns to S11.

At S16, 1 which shows an edit mode is set in the “Mode”. Then, the processing returns to S11.

At S17, a subroutine“Cleaning” is executed. After that, the processing returns to S11.

At S18, a subroutine “Calibration” is executed. After that, the processing returns to S11.

Next, at S19 in FIG. 16, field data or directory data, and content information (text data, sound data, or image data) which have the same name as the name set in the KeyName (X, Y) when X=Push-X and Y=Push-Y are read.

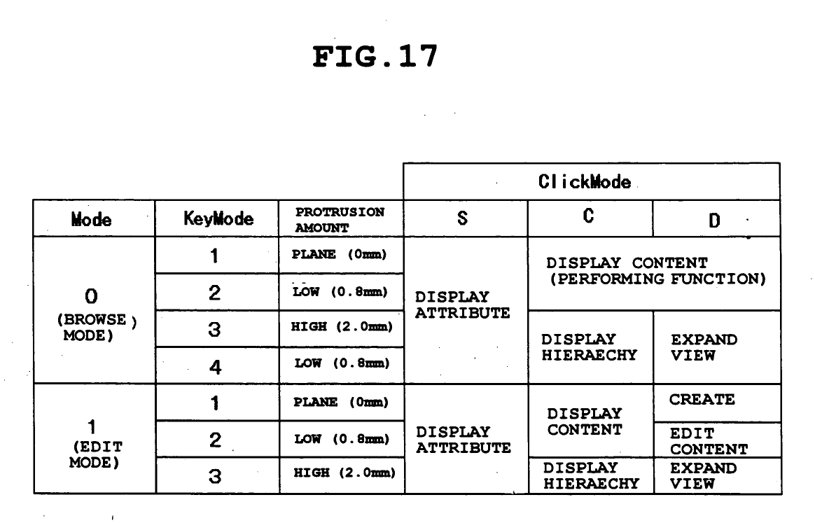

At S20, based on the “Mode”, the “KeyMode (X, Y)” and the “ClickMode”, operation is selected according to an operation correspondence table shown in FIG. 17.

As shown in FIG. 17, there are six types of operations defined such as “display attribute”, “display content”, “display hierarchy”, “create”, “expand the view” and “edit the content”. A predetermined operation is selected according to the current operating mode (browse mode or edit mode), the setting state of the operated key top (a plane state, a low-raised state, or a high-raised state), and the operating mode (single click or double click) and the processing branch to a step shown in the drawing. Next, each operation described above will be described.

When operation selected at S20 is the “display attribute”, the processing branches to S21.

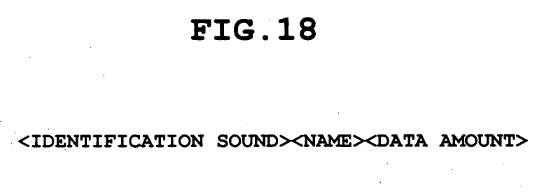

At S21, information regarding the name of the field data read at S9 and information regarding the content display portion are set so that the information are to be output via the sound synthesis circuit 208 by sound/voice with a sound/voice pattern shown in FIG. 18. After that, the processing proceeds to S31. Sound/voice is asynchronously played by a sound generating circuit. When other information is read while sound/voice is being played, the sound/voice is stopped outputting and new sound/voice is output.

In the sound/voice pattern, an “area identification sound” is a specific sound to be assigned to distinguish between an area of a field to which the operated key top attributes and other areas adjacent to the area. For example, as a question of coloring a map with four colors, four different area identification sounds are prepared and the areas of the fields may be classified by an algorithm of coloring with four colors, which is not described, in the tactile input/output apparatus. The “area identification sound” is preferably short sound and easy to identify. In the sound/voice pattern, a “name” is a value of KeyName of the key top, that is, a sound/voice reading out the field name to which the data attributes. Further, in the sound/voice pattern, “data amount” is sound/voice reading out the number of characters when information of a content display portion is text data, reading out an image size when it is image data, and reading out replay time when it is sound data. When it is rink data, no sound is generated. When the KeyMode of the key top is 3 or 4, there is a field of a so-called “child” in which the field name is specified in “parent”. In this case, the “data amount” is sound/voice reading out the number of fields of “child” after the number of fields of the “child” is counted.

As can be seen from the drawings, unless the KeyMode of the key top is “undefined”, attribute is displayed by a single-click. Therefore, attribute information of information assigned to the key top can be confirmed by sound/voice with simple operation before browsing the information of the content display portion. In particular, first, an area identification sound is shortly generated, so that an occupied area in a matrix of the key tops of the tactile input/output apparatus can be easily recognized by operating the key top in a plane state. Further, the field name assigned to the key top is simply represented, so that an outline of the information can be understand before detailed contents are browsed. Furthermore, the number of characters included in the field to which the key top attributes is simply represented, so that a time required to browse the contents can be understand in advance. When the key top is assigned with a field which is a “parent”, the number of “child” fields included in the “parent” field is simply represented. Therefore, how much information is classified and included in a subordinate level of the key top can be confirmed in advance. Accordingly, information can be effectively browsed.

The attribute information is not restricted to the example described above. For example, a type of an input/output part of a graphical user interface may be expressed by a simple sound/voice.

When operation selected at S20 is the “display content”, the processing branches to S22.

At S22, the information of the content display portion read at S19 is determined. When the information is text data, the processing proceeds to S23. When the information is sound data, the processing proceeds to S24. When the information is image data, the processing proceeds to S25. When the information is rink data, the processing proceeds to S26. When the information is command data, the processing proceeds to S33.

At S23, sound/voice representing the information of the content display portion is output. Then, the processing returns to S11.

At S24, sound data specified in the content display portion is read and is played by sound/voice. Then, the processing returns to S11.

At S25, an image data file specified in the content display portion is specified in TopName as data to be newly read. Then, the processing returns to S10.

At S26, a rink file specified is specified in TopName as data to be newly read. Then, the processing returns to S10.

At S33, a specified command specifying file is read, and a function of the apparatus which is separately determined is performed. Then, the processing returns to S11.

When operation selected at S20 is “expand the view”, the processing branches to S27.

At S27, field data or directory data read at S19 is set in the TopName as data to be newly read. Then, the processing returns to S10.

When operation selected at S20 is “create”, the processing branches to S28.

At S28, a creation subroutine “NewIndex” is executed. Then, the processing returns to S10.

When operation selected at S20 is “edit content”, the processing branches to S29.

At S29, a sentence for edit input by the user via the microphone 400 is input via the voice input circuit 209. Text data of information of a content display portion corresponding to a portion to be edited is converted into input character data. Then, the processing returns to S10.

When operation selected at S20 is “display hierarchy” the processing branches to S30.

At S30, sound/voice representing field names of a “child” in order is output. Then, the processing returns to S11.

Next, at S31, an operating state of the key tops 1 of the tactile input/output apparatus is input again. Then, at S32, it is determined whether the operation state is in the same state as the state input at S19. When the same key top is still being operated, it is set that ClickMode=C. Then, the processing returns to S20. When the same key top is not operated, the processing returns to S11.

The functions effectuated at a series of steps, S21 and S22, S23 and S24, and S30 and S31, include a function corresponding with “sound related information supply means that is input an operation signal therein, selects sound related information by reading block unit information corresponding to an operated tactile operation means from the information storage means, and supplies the sound related information to sound generating means” claimed in claim 1. The function effectuated by performing the “DispIndex” at S10 after performing any one of steps S25, S26, S27, S28, or S29 includes a function corresponding with “information modification means that is input an operation signal therein and modifies contents of the information storage means based of an operated tactile operation means” claimed in claim 1.

As described above, when sound/voice is generated based on the operation, sound/voice is heard from a predetermined sound source position in correspondence with a position of operated tactile operation means, by effect of the four channel stereo of the sound circuit. Therefore, a position of information to be read can be understand not only by tactile operation but also auditory sense.

A “page tag” and a “field tag” included in document data are a super set tag including information corresponding to a “root tag” and a “directory tag” included in document control data. A “page tag” included in document data and a “field tag” may be handled as a “root tag” and a “directory tag”, respectively. As a result, as in the case of the processing in the document control data (the processing performed as TopType=0), document data can be displayed by which a direction of a depth of a hierarchical structure of fields included in document data is assigned to a column direction of the key tops of the tactile input/output apparatus and a direction of list of fields included in the same level is assigned to a row direction of the key tops. At a step not shown, a value of the TopType is changed from 1 to 0. By doing so, a display pattern of a document can be switched between a display applicable to confirm a layout and a display applicable to confirm a hierarchical structure when the document is read.

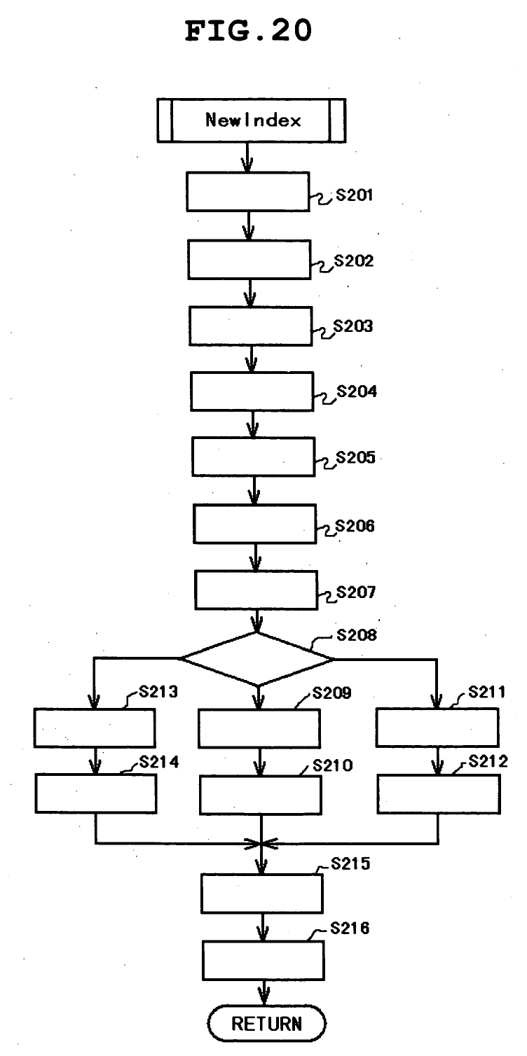

Next, operation of the creation subroutine “NewIndex” will be described with reference to FIG. 20.

First, at S201, a row number and a column number of a pressed key top are stored in NewY and NewX, respectively. Then, a voice message to the effect that “please input a name of a new area via the microphone” is output from the sound output circuit. At S202, the name vocalized by the user is input via the voice input circuit 209 and is stored in NewName.

Next, at S203, a voice message to the effect that “please click the key top that is an upper left point in the new area” is output. At S204, a state of the push switch 21 is input, and a row number and a column number of the clicked key top are stored in NewY1 and NewX1, respectively.

At S205, a voice message to the effect that “please click the key top that is an lower right point in the new area” is output from the sound output circuit. At S206, a state of the push switch 21 is input, and a row number and a column number of the clicked key top are stored in NewY2 and NewX2, respectively.

Next, at S206, a voice message to the effect that “please input a type of data via the microphone” is output from the sound output circuit. At S207, the type of data vocalized by the user is input via the voice input circuit 209 and is stored in NewType.

At S208, the NewType is determined. When the content is a “document”, the processing proceeds to S209. When it is a “sound”, the processing proceeds to S211. When it is an “image”, the processing proceeds to S213.

Next, at S209, the number of characters N in a text corresponding to a key top area specified at S204 and S206 is calculated. After that, a voice message to the effect that “please input a sentence having characters as many as the number of characters N via the microphone after a beeping sound “PI” is produced. PI.” is output. At S210, the sentence vocalized by the user is input via the voice input circuit 209 and is stored in NewData. After that, the processing proceeds to S 215.

At S211, a voice message to the effect that “please input a name of a file storing sound data to be added via the microphone” is output from the sound output circuit. At S212, the file name of the sound data vocalized by the user is input via the voice input circuit 209 and is stored in the NewData. Then, the processing proceeds to S215.

At S213, a voice message to the effect that “please input a name of a file storing image data to be added via the microphone” is output from the sound output circuit. At S214, the file name of the image data vocalized by the user is input via the voice input circuit 209 and is stored in the NewData. Then, the processing proceeds to S215.

Next, at S215, between tags of index forms corresponding to the current “Key-X” and “Key-Y” in a structure display portion of document data, a new index tag is added. At that time, parameters of the index tag set are set as follows.
name=NewName
X=NewX, Y=NewY
X1=NewX1, Y=NewY1
X2=NewX2, Y2=NewY

Next, at S216, a tag corresponding to the NewType is added to the content display portion of the document data. That is, when the NewType is a “document”, text data whose name is the NewName is added and the NewData is set in a portion between a pair tag. When the NewType is a “sound”, sound data whose name is the NewName is added and the NewData is set in a portion of a file name. When the NewType is an “image”, image data whose name is the NewName is added and the NewData is set in a portion of a file name. Thus, the operation of NewIndex is finished.

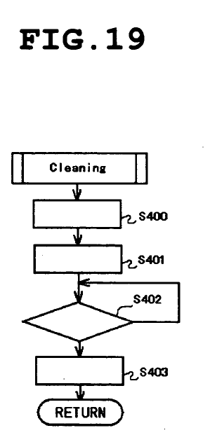

Next, operation of a subroutine for cleaning preparation “Cleaning”, which is preferably applied to the first embodiment of the tactile input/output apparatus, will be described with reference to FIG. 19.

At S400, all the key tops of the tactile input/output apparatus are set to the highest position.

At S401, a voice message to the effect that “please clean the apparatus. Remove the operation cover and clean the cover and the key tops. Then, attach the cover to the apparatus, and please say “finished”.” is output. After that, the processing proceeds to S402.

At S402, when voice input is confirmed. When a word “finished” is input, the processing proceeds to S403.

At S403, all the key tops are set to the plane state, and the operation of the subroutine is finished.

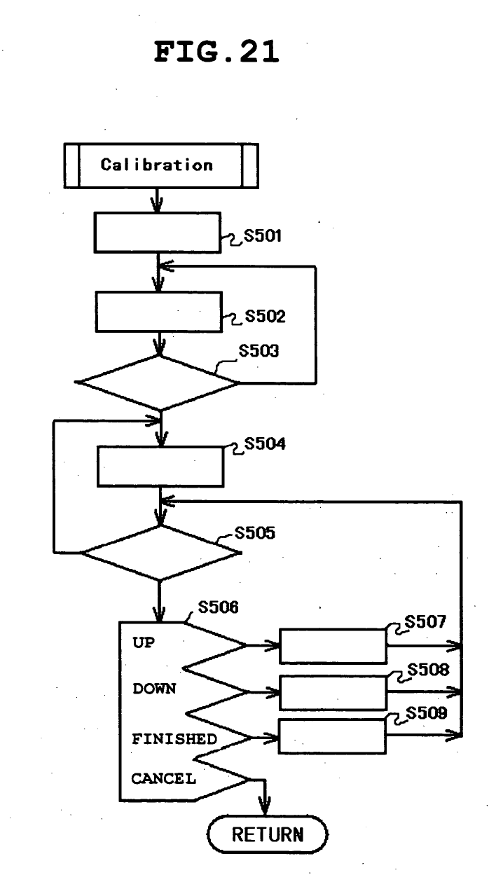

Next, operation of a height adjustment subroutine “Calibration”, which is preferably applied to the first embodiment of the tactile input/output apparatus, will be described with reference to FIG. 21.

At S501, a voice message to the effect that “please click a key top desired to be adjusted its height. When you desire to finish the operation, please say “finished”.” is output.

Next, at S502, an operating state of the push switch 21 is input.

Next, at S503, the key top on which click operation is performed is detected. After the key top is detected, the processing proceeds to S504. When the key top is not detected, the processing returns to S502.

At S504, a voice message to the effect that “now the height of the key top will be adjusted. Please instruct with words “up”, “down”, “finished”, and “cancel”.” is output.

At S505, a voice input via the microphone 400 is processed at the voice input circuit 209 and is output as text data, and the text data is input. Then, the processing proceeds to S506. When voice input is not performed within a certain time at S505, the processing returns to S504.

Next, at S506, the input data is determined. When the data is “up”, the processing proceeds to S507. When the data is “down”, the processing proceeds to S508. When the data is “finished”, the processing proceeds to S509. When the data is “cancel”, the operation of the subroutine is finished.

At S507, the key top is slightly driven to correct the position in a protruding direction and a history of correction is stored. After that, the processing returns to S506. At S508, the key top is slightly driven to correct the position in a recessing direction and a history of correction is stored. After that, the processing returns to S506. At S509, correction values stored in the correction history are stored in a nonvolatile recording medium, such as the HDD 204. Then, correction history is cleared and the processing returns to S505.

As described above, by the operations at S504 to S509, correction values of a key top is stored in a nonvolatile recording medium, such as the HDD 204. The correction values are reflected to subsequent processing so that the key tops can be positioned at the plane position. Accordingly, variations in parts in manufacturing can be accommodated and the apparatus can be manufactured at low cost. Further, variations of tactile sense among users can be accommodated.

In the embodiment, information having a data structure that can be expanded into a two-dimensional plane is divided into pieces of block unit information in advance and is stored in the storage means. However, information that the visually impaired person desires to read is not always stored in the storage area in the apparatus. As described below, it is practical to be able to read the existing document data by which information to be read is divided into block unit of a predetermined size and selected by the information setting means and is stored in the storage means.

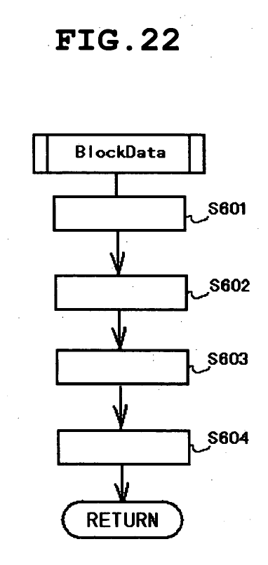

FIG. 22 is a flowchart of a subroutine “BlockData” showing operation of the information setting means. This operation is called as a subroutine from a “main routine” described later after the “main routine” is corrected.

First, at S601, a document created using such as a word processor or the like is input via information input means such as an external recording medium. A homepage formed in HTML or XML may be read from a server by accessing the Internet using a modem. The function performed at S601 corresponds with “information input means” claimed in claim 23.

The information maybe a document to be actually displayed on the screen as the “letter” in the embodiment, may be information having a hierarchical structure of the information as the “TOKKYO KUN's bookshelf” in the embodiment, or may be information in which the unit functions of the apparatus is hierarchically structured as the “functions of personal computer” in the embodiment. Further, depending on the specification of the program, the aforementioned information may be combined.

The information is described with a structural descriptor so that the structure of the information can be electronically identified. The structures are a page structure to be divided by the page break code, a paragraph structure to be divided by the line feed code, an outline structure (also called as a hierarchical structure) between paragraphs to be specified by the outline data, a layout structure including layout frames, a data structure structured with object data (image data, tables, sound data, or the like) inserted in a document by specifying an inserting position, a list structure to be listed and displayed using a list code, and a table structure to be specified by the table code. The information is divided into a plurality of groups by focusing on the structural descriptor. This function corresponds with “grouping means” claimed in claim 23.

In the process of analyzing the structural descriptor or dividing information into groups, when information regarding a hierarchical structure, such as a parent-child relationship between groups is obtained, the obtained information is stored. This function corresponds with “hierarchical structure selecting means” claimed in claim 23.

Information is divided into groups based on structural descriptors because the information has been divided using the structural descriptors according to attributes when a user created a document. That is, the information grouped by the structural descriptors each attributes to the same group under a concept, such as a content, a type of information, a format, an area to be displayed, and a hierarchical relation of a group. Information may be divided into groups based on a structural descriptor other than the descriptors described above. When information is structurally stored in other rule, the results may be used to divide the information into groups.

Next, at S602, as to information having a concept of “area” when the information is displayed, information regarding an area that the group occupies in the document is obtained. This is information of a concept that corresponds with a “character area” in a field in the embodiment.

To be more specific, when an area occupied by the information of the group is specified in a structural descriptor, information regarding an area is obtained based on the information of the structural descriptor. In another way, the information regarding the area is obtained based on a result of calculation of an area occupying in the document when the document is represented in a form that a human being can recognize the document in reality.

At the time, characters may occupy a small area in a layout in consideration of size and style of fonts. When there are characters and a photograph in the same group, an area where the information in the group is represented needs to be obtained with consideration given to both the characters and the photograph. For a structural descriptor defined so that a display area is dynamically changed in accordance with an aspect ratio of a screen to be displayed, like a homepage, an area which is displayed on the tactile input/output apparatus may be obtained according to an aspect ratio of the number of the rows and the columns of the tactile input/output apparatus to be actually used. The function performed at S602 corresponds with a function of “group area selecting means” claimed in claim 23.

Next, at S603, a correspondence between each key top 1 and each group. The key tops 1 are provided to the tactile input/output apparatus to be used and are arranged in a two-dimensional matrix in which the key tops 1 are divided into individuals by the number of columns X and the number of rows Y. A determination of an “index point” in index data in the embodiment corresponds with this step. At this time, the index point is determined according to the setting information of the DIP switch 106 in consideration of a specification, such as the number of rows and columns of the key tops of the tactile input/output apparatus to be used. Therefore, it goes without saying that grouping processing may provide different results depending on a specification.

To be more specific, the user can selectively access the grouped information via the key tops 1. One group is assigned to at least one or more key tops. The following processing is appropriately performed so that one key top is assigned with not more than one group.

1. A plurality of groups adjacent to each other are grouped into one and the unified group is assigned to one-key top. As a result, an information block that can be accessed by the user by operation of the key top becomes unified information. (unification of groups)

2. When information has a hierarchical structure, a block of a common higher level of a gathering of groups which need to be assigned to a plurality of key tops is reassigned to one key top. (an assignment of a block of a common higher level)

3. A group assigned to a key top is reassigned to an unassigned key top adjacent to the key top assigned with the group, and the key top which newly becomes an unassigned key top is assigned with an unassigned group. (a displacement of assignment position)

However, when a group is displaced, it is unpreferred that an assignment position is moved to a key top which is far from a position where information is actually represented in an original. In this case, either of the “unification of groups” or the “assignment of a block of a common higher level” is performed so that the number of key tops required to assign groups is reduced and information can be displayed at a position where the information is represented in the original. There may be a case where groups are unnecessarily moved.

On the other hand, even when there are still unassigned key tops so that groups can be assigned to the key tops individually, a lower group may not consciously be assigned to the unassigned key top. This is because levels to be simultaneously displayed are clearly specified with a structural descriptor or consideration is given to proportions of a level of sentences in the group assigned to other key top.

The “body” of the “letter” in the embodiment corresponds to this case. The field having a concept of “body” (which is an implementation form of the “group”) is easy to understand when the field having a concept of “body” is recognized in the same display pattern as the field, such as an “address”, “compliments of the season” and a “closing”, which are generally easy to understand as a structure of a letter. Therefore, even when unassigned key tops exist near a key top to which the “body” is assigned, the field having a concept of “body” is preferably assigned to a single key top. When a homepage, on which a hierarchical structure of information is described, on the Internet is displayed using a structure description language, such as HTML and XML, consideration must be given to the assignment of groups to key tops.

Further, when a plurality of unassigned key tops exist, the same group is assigned to several key tops according to the occupied area of the group obtained at S602 and identification data is calculated so that adjacent groups can be easily discriminated from each other. Therefore, the user can understand by hearing an area identification sound that the group of the information occupies which area on the two-dimensional matrix of the key tops. This corresponds to a concept of “index area” in the embodiment.

Further, when a group has a hierarchical structure, not only groups included in a predetermined level, but also subordinate groups are assigned to key tops. That is, a plurality of subordinate groups are assigned to key tops which can be newly assigned by expanding operation. All the key tops are targeted to be assigned with groups when an entire display is used. However, in a case where information in a lower level is expanded into another key top area while information in an higher level is displayed on the key tops, like the “TOKKYO KUN's bookshelf” and the “functions of a personal computer”, the groups of the information in the lower level are assigned using key top areas other than the key tops to which the information in the higher level is assigned.

At the time, as the “TOKKYO KUN's bookshelf”, the depth of the hierarchy is adopted as an X (or Y) direction and the subordinate group is assigned to key tops in a Y (or X) direction perpendicular to the X (or Y) direction. As a result, information can be expanded into eight levels each including eight blocks on a tactile display with a matrix with eight rows by eight columns. Further, a display pattern of a parent-child/relative relationship of the information that is being expanded and displayed is maintained. Accordingly, a position of the block to be currently selected on the hierarchical structure can be easy to understand.

These processing are recursively performed. These processing are repeated until all groups are assigned to one or more key tops on any expanded display.

The function performed at S603 corresponds with a function of “mapping means” claimed in claim 23.

Next, at S604, information included in the “group” assigned to the key top is stored as block unit information in a predetermined format, such as a “field tag” and a “text tag” shown in the embodiment. Correspondence information between the group and the key tops determined in mapping processing is stored in a predetermined storage area in a predetermined format, such as an “index tag” shown in the embodiment.

Actual operation of the tactile input/output apparatus structured as described above will be described below.

First, “TOKKYO HITOSUJI KUN” who is a visually impaired person wears a pair of headphones and turns power of the personal computer 200 on to start using a tactile input/output apparatus. Then, operation proceeds as described above, in particular, at S2, a specification of the tactile input/output apparatus used by, “TOKKYO KUN” is automatically read. TOKKYO KUN has a low-priced popular tactile input/output apparatus having key tops with eight rows by eight columns to use at home. The tactile input/output apparatus is connected the personal computer 200. Therefore, at S2, it is set that KEY-X=8 and KEY-Y=8. After that, index data is displayed applicable to the tactile input/output apparatus used by TOKKYO KUN.

Next, at S3, a voice message to the effect that “please move your hands off from the key top to perform initialization” is output, so that TOKKYO KUN moves his hands off from the key tops. Because a force from fingers are not unnecessarily applied to the key tops, the pulse motors 18 are smoothly driven. As a result, all the key tops 1 are in one plane once.

At S4, when TOKKYO KUN speaks “TOKKYO KUN's bookshelf” into the microphone 400, a document control file shown in FIG. 3 is opened at S6 and “TOKKYO KUN's bookshelf” is set in RootName and TopName.

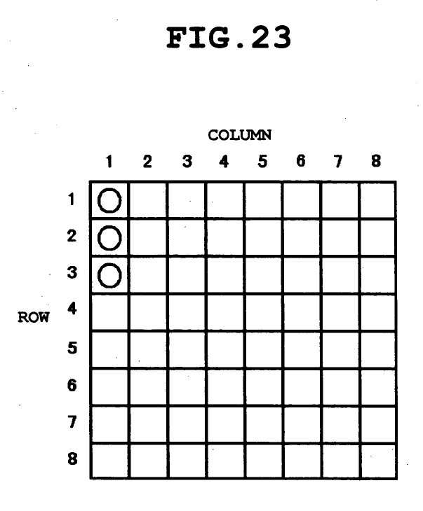

Next, at S10, the “DispIndex” is performed and the key tops 1 are brought into correspondence with directories. After that, the key tops 1 are driven and finally set in a state shown in FIG. 23. Description of a document being browsed is displayed on the CRT 211. In the drawing, “⊚” shows a key top which is set in a high-raised state and flushes with red on the CRT 211. “◯” shows a key top which is set in a low-raised state and lights on with red on the CRT 211. “.” shows a key top which is in a plane state and whose the KeyMode is 1 which shows an “area”. The key top lights with green. No indication shows a key top which is in a plane state and whose KeyMode is 0 which shows “unassigned”. Hereinafter, the same indication method is used throughout the several figures showing a setting state of the key tops.

As described above, according to the invention, the light-dependent person staying beside the visually impaired person can confirm a setting state of key tops to be touched by the visually impaired person, on the CRT 211, without touching the key tops. Therefore, the light-dependent person can provide proper advice to the user when the user is embarrassing.

while the key tops are being driven, sound effects to the effect that the key top are being driven are heard from the headphones. When the driving is finished, the sound effects are stopped.

As described above, according to the invention, a state of key tops which are being set can be confirmed by sound. Accordingly, the key top which is being set its state can be prevented from being accidentally operated due to misunderstanding.

When the driving is finished, the sound effects is stopped. Then, the surface of the operating panel is touched with hands and the protruding key tops are sensed by a tactile sense. Most of the key tops having slightly protrusion are in a plane state. However, it can be recognized that three key tops from the top in a leftmost column are positioned at a low-protruding position. With this tactile operation, it can be understand that an uppermost level in a hierarchy of a library file controlling a bookshelf of TOKKYO KUN includes three folders.

Next, TOKKYO KUN pressed the uppermost key top. Then, by the processing at S11, it is determined that the key top in the first row and the first column is single-clicked. At S20, operation of “display attribute” is selected and a sound/voice massage as described below is output from the upper left portion of the headphones.

“PI. Research and development, four items.”

Thus, it can be understand that the key top is a directory named as “research and development” and there are four directories below the “research and development”. Therefore, TOKKYO KUN continues pressing the key top. The processing proceeds to S31 and it is set that ClickMode=C. Then, the processing proceeds to “display hierarchy” performed at S20 and the following steps and a voice sequentially reading out the names of the subordinate directories can be heard from the headphones this time.

“Budget, design drawing, communication record, patent.”

With this voice, TOKKYO KUN now confirmed that a directory of the “communication record” storing a letter which he would like to see is included under the directory related to this key top. Therefore, TOKKYO KUN double-clicked the same key top 1.

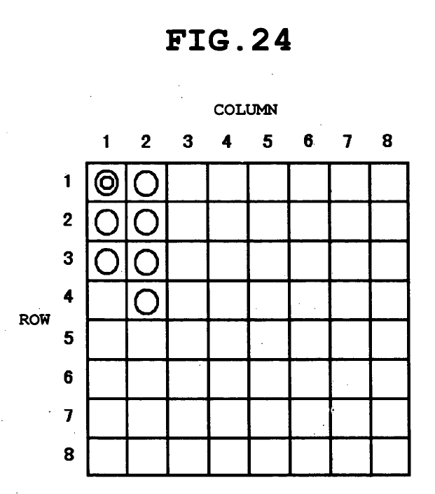

Then, at S11, the double-click is detected. At S17, “expand the view” is selected. At S27, the “research and development” is newly set in the TopName. The “DispIndex” is performed again and the tactile input/output apparatus becomes in a state that the key tops protrude as shown in FIG. 24.

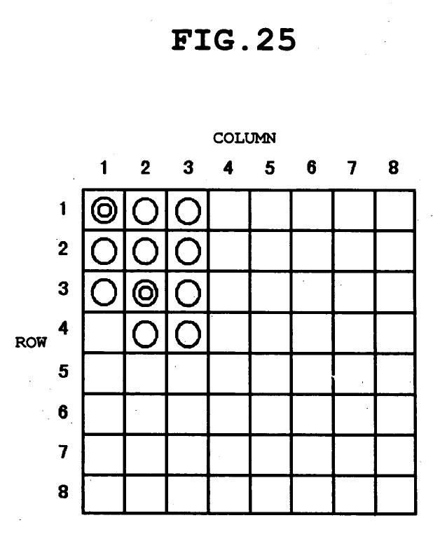

Likewise, the key top in the second column and the third row is double-clicked. This key top is assigned to the “communication record” which is a third directory. Then, the tactile input/output apparatus becomes in a state shown in FIG. 25.

As shown in FIG. 25, key tops corresponding to directories included in the level protrude in the rows of the tactile input/output apparatus. Among them, as to the key top which is set to a high protruding position, its subordinate directories are expanded into an immediately right column and its higher-level directories immediately above are expanded into an immediately left column.

As described above, according to the invention, the user can easily recognize the depth of a currently expanded hierarchy, a positional relationship between an expanded item and other items in the same level, and names of other items, by reading the setting states of key tops by a tactile sense.

It is needless to say that the invention is useful to read information while the user is properly understanding a structure of information having a hierarchical structure, such as classification control data of books and dictionaries in a library, a menu structure of a personal computer, and an operating condition of a program, in addition to the control of the bookshelf.

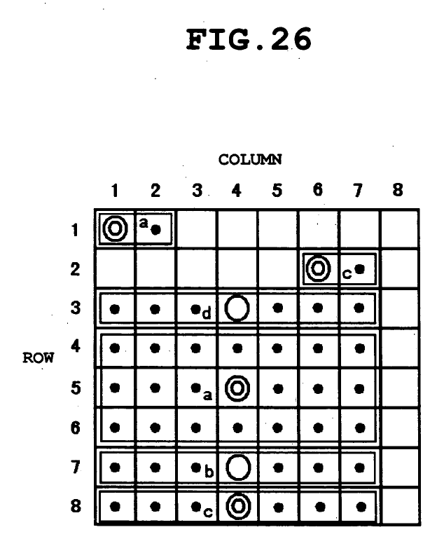

Next, when the key top in the first row and the third column is clicked, sound/voice such that “PI. A letter.” is heard from the headphones. Therefore, it is determined that it is a desired document, so that the key top is double-clicked. Thus, a document file of a “letter” is newly read and a desired letter to GANBA SENSEI is displayed on the key tops of the tactile input/output apparatus as shown in FIG. 26.

In the drawings, a key top indicated with “◯” or “⊚” can be recognized that the key top is assigned with fields only by touching the key top. In particular, it can be easily recognized that the key top indicated with “⊚” include a subordinate level. A layout of fields can be easily recognized.

As described above, according to the invention, the key tops can be set in three different identification states. Therefore, a predetermined key top can be represented as distinguished from other key tops. When directories of a document control data is displayed, it is possible to highlight a directory that is currently expanded. Further, it is possible to highlight a key top to which a subordinate field is assigned in document data. Data is represented so as to be recognized by a tactile sense, not only by sound/voice. Accordingly, a layout and a structure of data can be easily understand.

In particular, in each embodiment of the tactile input/output apparatus of the invention, a setting state of tactile operation means according to tactile operation can be represented by amount of protrusion, vibration pattern, and sound/voice. Accordingly, a setting states of the tactile operation means can be easily recognized. Further, tactile operation means can provided with three or more setting states within a limited space in a plane direction to discriminate the setting state from each other.

Further, when the low-raised key top in the third row and the fourth column is single-clicked, a message such that “PI. The compliments of the season of 36 characters.” is represented by sound/voice. Therefore, it can be understand that description having a concept of “compliments of the season” of a letter is described in an upper portion of the letter. Further, when the key top indicated with “.” in the figure which is set to a plane state and is in the third row, is single-clicked with the finger, a message such that “PI. The compliments of the season of 36 characters.” is output. The area identification sound “PI”, which first sounds, is set with a different sound (a sound d in the figure) from other area identification sounds for adjacent areas. It can be recognized that the key top attributes to the same area as the “compliments of the season” by hearing the area identification sound. The area to which the “compliments of the season” is assigned can be recognized by single-clicking key tops one after another.

As described above, according to the invention, a general structure and a positional relationship of information can be recognized by distribution and setting states of key tops 1 on the two-dimensional matrix. When a key top 1 is single-clicked, attribute information of a field assigned to the key top 1 can be confirmed by sound/voice. Therefore, each area occupied with a field can be confirmed by an area identification sound included in the attribute information, so that a structure and a layout of a document can be easily understood. In particular, as the embodiment, the number of times driving key tops preferably lessen in a tactile input/output apparatus in which the key tops are mechanically driven. Accordingly, it is advantageous that the tactile input/output apparatus that can be recognized the area as necessary even though key tops are in a plane state.

Next, when the key top in the third row and the fourth column is double-clicked or single-clicked and then the key top is kept on pressing, the operation moves to “display content”. The compliments of the season such that “Dear Sir, the sky in early autumn . . . ” is output by a sound/voice.

As described above, according to the invention, for example, even though details of information includes a plurality of characters in reality, the details is grouped into block unit information which is a field and is assigned to a single key top. The details is output by sound/voice when the key top is pressed, so that the key tops need not be provided every character, like a conventional apparatus. Therefore, a document can be easy to be read on a low-priced tactile input/output apparatus that has limited number of key tops. Because sound/voice does not come out even when a key top is touched to confirm a layout, the tactile input/output apparatus is easily used without any inconvenience.

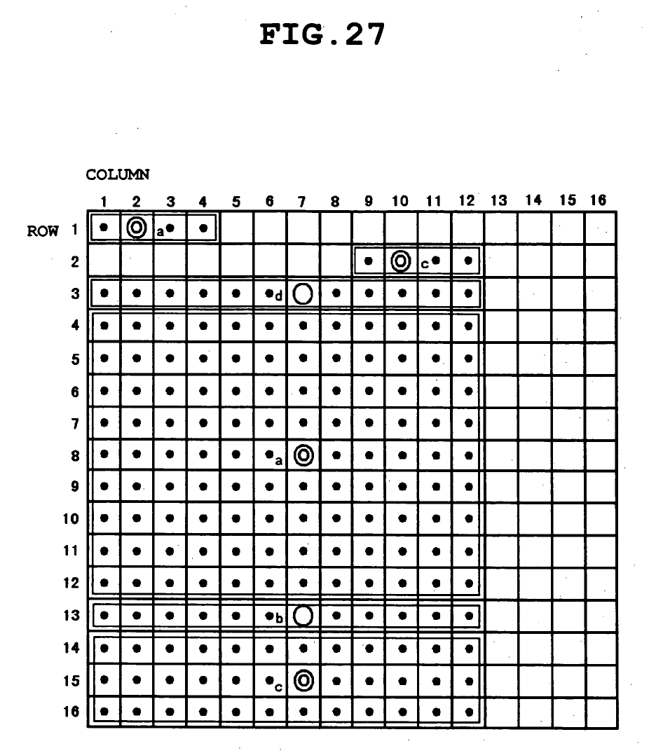

In the embodiment, the tactile input/output apparatus having the key tops with eight rows by eight columns is used. However, a tactile input/output apparatus having key tops with 16 rows by 16 columns may be used though it is somewhat high priced. In this case, a specification of the tactile input/output apparatus is also automatically determined by the program. When the same “letter” is browsed, a display pattern will be a pattern as shown in FIG. 27. As the display pattern is compared with the display pattern shown in FIG. 26, the “closing” in the seventh row and the “postscript” in the eighth row are represented by one line of an area and three lines of an area, respectively, in the tactile input/output apparatus having a high-display capability in FIG. 27 though the “closing” and the “postscript” are both represented by one line of an area in FIG. 26. As is known from the above description, it is possible to represent the layout of the “letter” close to a real document.

As described above, according to the invention, a correspondence between key tops and fields is properly set and processed according to a determined specifications a tactile input/output apparatus. Accordingly, documents can be appropriately browsed according the tactile input/output apparatus to be used.

The document used in the embodiment is document data that can be represented by the key tops with eight rows by eight columns. However, in a document having a complicated layout, one level may not be represented on the key tops with eight rows by eight columns because index data of the document maybe stored as data for key tops with 16 rows by 16 columns. In this case, the data for key tops with 16 rows by 16 columns are divided into four areas of data, in which one area of data is data for key tops with eight rows and eight columns. Four scroll designation switches are provided to the tactile input/output apparatus. The divided areas are switched therebetween and displayed according to operation of the scroll designation switches. By doing so, a document having a complicated layout can be browsed using a low-priced tactile input/output apparatus.

To be more specific, description of an upper left area A in the figure is displayed by operating a scroll switch disposed at upper left portion. At that time, an operational status of the scroll switch is preferably represented by the amount of protrusion of the key top. By doing so, it can be recognized that an area presently represented is which part of the data. The scroll switch may be fixedly structured.

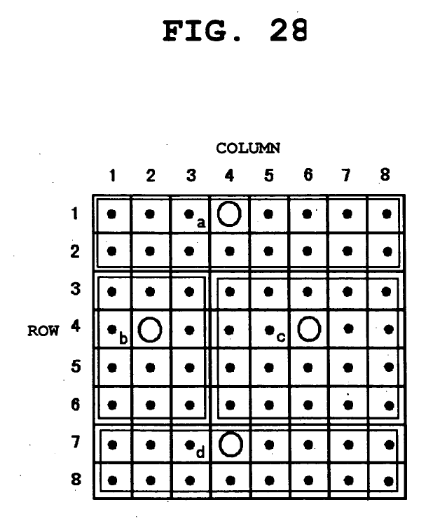

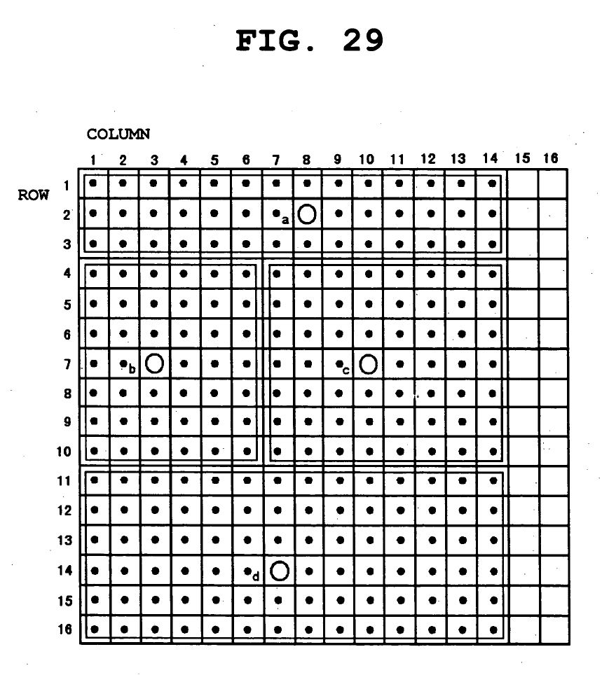

Next, in FIG. 26, when the high-raised key top in the fifth row and the fourth column is single-clicked, a sound/voice message such that “PO. Body, four items.” is output. Therefore, it can be recognized that the body having four items is assigned to the key top. Then, the key top is double-clicked. As a result, the operation of “expand the view” is performed and details of the “body” is represented. The key tops become in a state shown in FIG. 28. For reference, when the tactile input/output apparatus having the key tops with 16 rows by 16 columns is used, the key tops become in a state shown in FIG. 29.

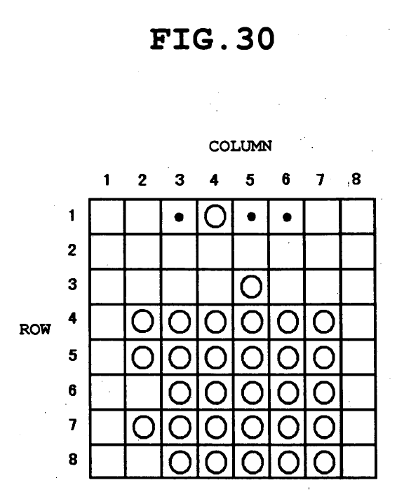

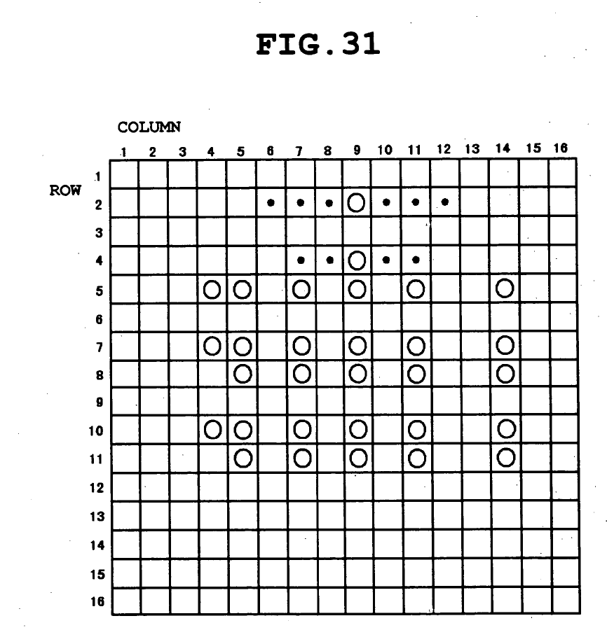

When the key tops are touched in this state, it can be read that an “introduction”, an “experimental result table”, an “explanation of experimental result”, and “consideration of experiment” each occupy a predetermined area at a predetermined position. Further, when the key top indicating the “experimental result table” in the fourth row and the eighth column is double-clicked, data “c:¥result.dat” shown in FIG. 7 is newly read. Then, the “experimental result table” is set in the TopName and a predetermined operation is performed. As a result, the key tops become in a state shown in FIG. 30 (when the key tops are formed with a matrix of 16 rows by 16 columns, the key tops become in a state shown in FIG. 31.). In each figure, each key top is assigned with such as a subject, items in rows and columns in a table, and cells in the table. For example, when a key top corresponding to a predetermined cell in the table is double-clicked, description of data of the cell can be confirmed by sound/voice.

As described above, according to the invention, even when the number of key tops is not enough to represent information having several fields like a table on one display, a document can be represented by dividing into appropriate levels and can be browsed while an outline of the document is being understood. This is because data is hierarchically structured and a correspondence between the key tops and the fields are appropriately set in accordance with the hierarchical structure.

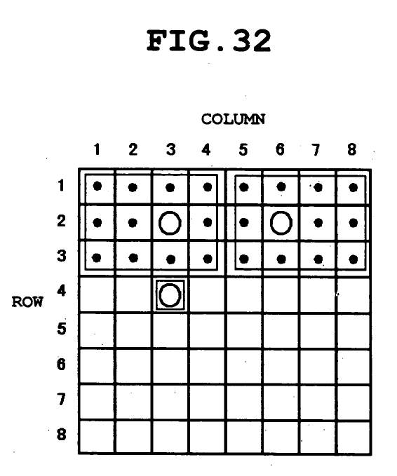

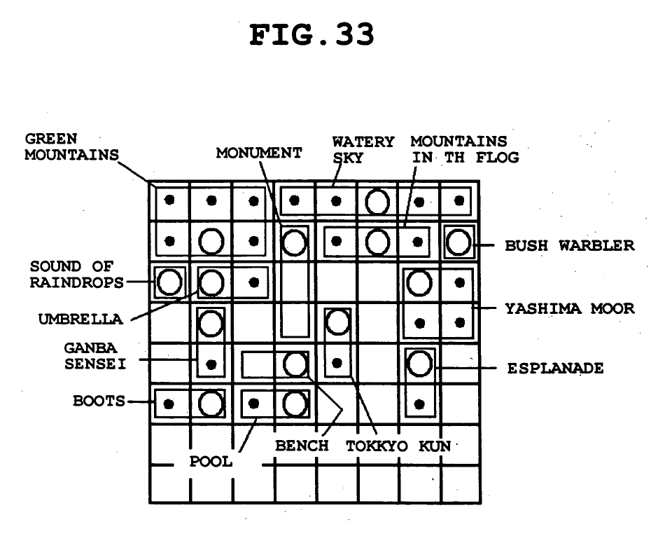

With such the browsing method, likewise, the “snap” (data representing a snapshot shown in FIG. 6) in the “postscript” of the “letter” can be seen. To be more specific, when the key top in the eighth row and the fourth column is double-clicked in FIG. 26, the key tops become in a state shown in FIG. 32. After that, when the key top in the second row and the sixth row is double-clicked, the data “c:¥picture.dat” is read and the data is represented as shown in FIG. 33.

The visually impaired can hardly see an original picture shown in FIG. 6. There has been proposed a device on which an image formed in relief with tactile pins, which can be controlled the amount of protrusions with a small pitch, can be fingered to feel. However, it is extremely expensive. Details of the picture can not be understood only by representing light and dark of the picture in relief. Therefore, it is not in practical use. However, if the invention is applied to appreciating pictures and paintings, these problems can be solved.

To be more specific, the picture shown in FIG. 6 is divided into areas which should be focused on and each divided areas is registered as a field. The divided areas are displayed with text data or sound data representing image of the picture.

When the data created as described above (shown FIG. 5) is displayed on the tactile, input/output apparatus, the key tops are in a state shown in FIG. 33. For reference, a name of each field is attached to corresponding key top area. In the embodiment, for example, the “GANBA SENSEI” is represented by one field to be simplified. It is possible to represent the “GANBA SENSEI” with a plurality of subordinate fields, such as a “pitiful face” and a “head looks cold”. It is needless to say that it is easy to implement this by applying the concept of the technology described above.

The visually impaired can easily understand details of pictures and paintings, which can not previously be appreciated by the visually impaired. As described above, information of pictures or paintings is handled as “information having a data structure that can be two-dimensionally expanded.” Information explaining distinctive portions is stored as block unit information using the invention.

The embodiment regarding the picture shown in FIG. 6 is unexciting because the picture was drawn by the applicant who does not have a sense of the art. The visually impaired do not have any connection to famous paintings painted by such as Van Gogh and Renoir. However, if artists of each field cooperate to represent impressions of the paintings using sound/voice or music, a new artistry of the paintings can be passed to the visually impaired exceeding visual information.

A command for storing a state that predetermined information is expanded into key tops of the tactile input/output apparatus is prepared. This command is performed in the middle of using the tactile input/output apparatus. Arbitrary name is specified for the state, and the state is stored in the HDD 204. When the tactile input/output apparatus is started using again, the name is directed and read so that the key tops are returned to the state when the tactile input/output apparatus is stopped using. The tactile input/output apparatus can resume a state, so that an operability of the tactile input/output apparatus is improved. When such information is stored, information in a higher level, which brought representation of the information to be stored, is also stored. By dosing so, the state of the tactile input/output apparatus can be returned to the information in the higher level when the tactile input/output apparatus is started using again.

Next, TOKKYO KUN found that he forgot to write a date in the letter, so that he speaks “edit” into the microphone 400. Then, at S14, the word spoken by TOKKYO KUN is determined and the mode is changed from a browse mode to an edit mode.

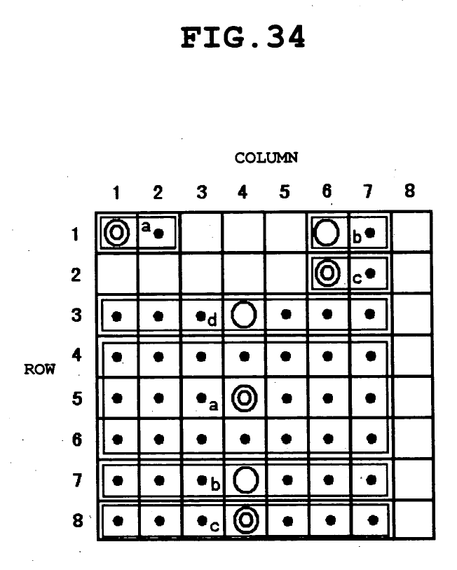

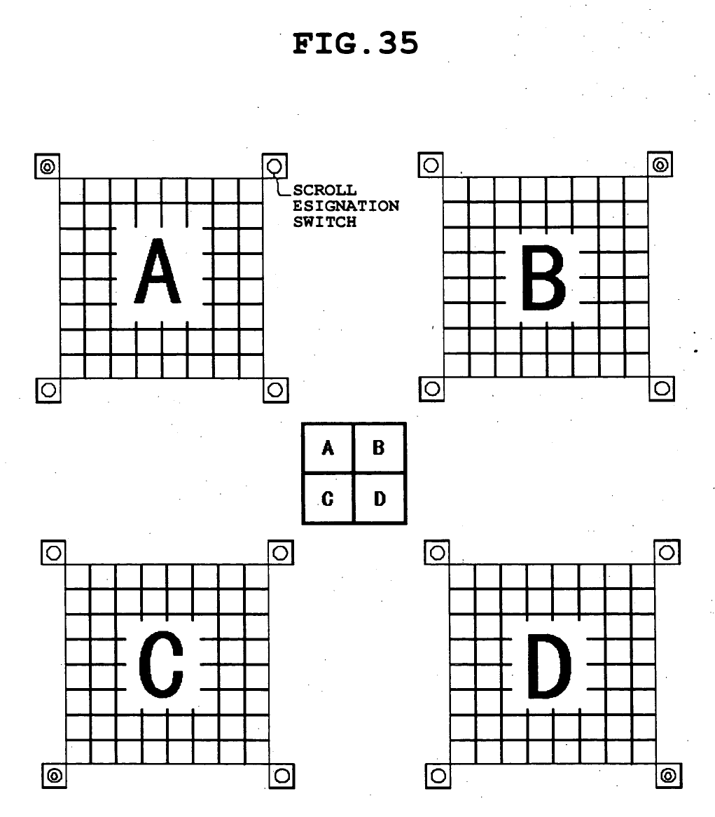

Next, in the state of FIG. 26, the key top in the first row and the seventh column is double-clicked as a representative point of a position where the date is desired to be written. Then, at S20, “creation” is selected and the subroutine “NewIndex” is performed. According to sound/voice announcement, it is specified that a field name is a “date”, an upper left point and a lower right point are “the first row and the sixth column” and “the first row and the seventh column”, respectively, and NewType is a “document”. After that, “Sep. 13, 1998” is input into the microphone 400 according to announcement. Then, a field named as the “date” is added to the document data of the “letter”. The data is edited and becomes data shown in FIG. 4. The state of the tactile input/output apparatus is also changed according to the new data and the key tops become in a state shown in FIG. 34.

As described above, a portion desired to be modified can be specified in a predetermined position using a key top while the layout is being confirmed. By inputting a voice of the user, stored description of a field corresponding to an operated key top can be updated by selecting information included in the information vocalized the user. Therefore, the description of the document can be effectively edited.

It is difficult to provide timing of performing maintenance, such as a cleaning function described above, for the visually impaired because they can not confirm dirt on the surface of operating panel by the sense of sight. Therefore, the number of calls of the subroutine “DispIndex” is stored in a nonvolatile recording medium, such as the HDD 204, and a message to the effect that it is time to perform cleaning is output after the number of predetermined times the subroutine is called. Accordingly, the timing of the cleaning is obtained so that the operating panel can be kept clean.

Further, when predetermined information is browsed one after another, stored contents of the storage area set in the memory 202 shown in FIG. 13 (hereinafter referred to as state information) is successively changed according to browsing operation. For example, every time the “DispIndex” is called, state information at that time is stored in a predetermined storage area in the HDD 204. By doing so, when power suddenly fails or is shut down by the user, it is possible to return the tactile input/output apparatus to its latest state based on the state information stored in the HDD 204.

State information at any point is preferably stored in the HDD 204 with a name attached by the user, so that the state information can be used at a later time. In the embodiment, at S14, a command of “store the state” may be recognized. At the next step, a name to be stored may be input by the user and state information of that time may be stored with the name. A desired state to be reproduced is specified by its name and read from a plurality of pieces of state information stored in the HDD 204 and is set in the memory 202. As a result, the tactile input/output apparatus can be returned to the desired state without performing operation to bring the state to the desired state.

Up to this point, the embodiment of the invention has been described using specific data and detailed flowcharts described above. Hereinafter, embodiments that are effective if the invention is applied to will be briefly described with reference to the drawings. Specific data and detailed flowcharts will not be disclosed in an explanation below because the embodiments described below can be achieved if a technology concept of the invention clarified in the above-described explanation is properly applied.

First, an embodiment that the invention is applied to a user interface for selectively performing functions of a predetermined apparatus, such as a personal computer, will be described.

FIG. 55 hierarchically illustrates predetermined functions of a personal computer. The functions are expanded from top functions, such as “browse homepage”, “send/receive mails” and “browse document”, to subordinate functions each constituting functions. As described above, in a case where the functions of the personal computer are hierarchically handled as a group of unit functions, an application such that a predetermined function is directed and performed while the functions are hierarchically represented using the tactile input/output apparatus of the invention can be achieved.

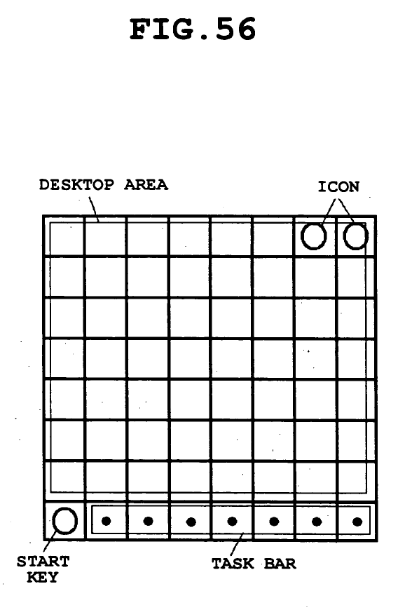

FIG. 56 is a diagram showing an example of use of key tops of a tactile input/output apparatus that is the user interface applicable to access the functions of the personal computer of FIG. 55.

A lower left key top in FIG. 56 is fixedly assigned with a function as a “start key”. The “start key” corresponds with as a “start” key adopted in the mainstream OS of the current personal computers. The visually impaired person can access the function of the personal computer by operating the “start key”.

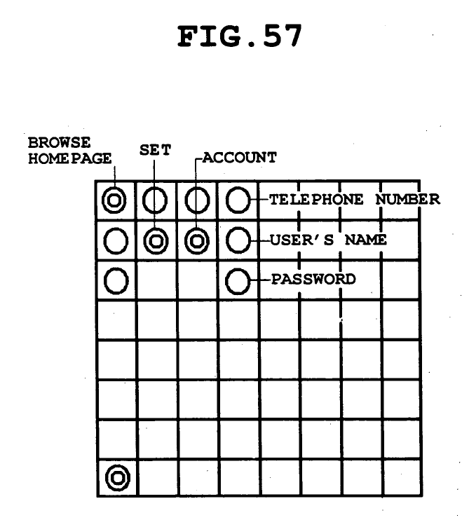

FIG. 57 shows a state that key tops corresponding to input items to be finally set, such as a “telephone number”, a “user's name” and a “password” after displaying a hierarchical structure of the function of the personal computer shown in FIG. 55 in a “desktop area” of FIG. 56 and selecting the “browse homepage”, a “setting”, and an “account” in the order by actually operating the “start key” by the user.

When the key top of “telephone number” is clicked, attribute information that is an item for inputting a telephone number of an access point of the Internet is displayed. When the key top of “telephone number” is double-clicked, it is determined that the “telephone number” is command data at S22, and then an unit function of the personal computer specified in “SetTelNo.bat” is executed. To be more specific, a message such that “please input the telephone number” is output and then a function for setting the telephone number via the microphone is executed.

As described above, block unit information includes not only information regarding to display but also information regarding unit functions of a personal computer. Therefore, a desired unit function can be executed by easily specifying the desired unit function from the hierarchically structured unit functions of the personal computer.

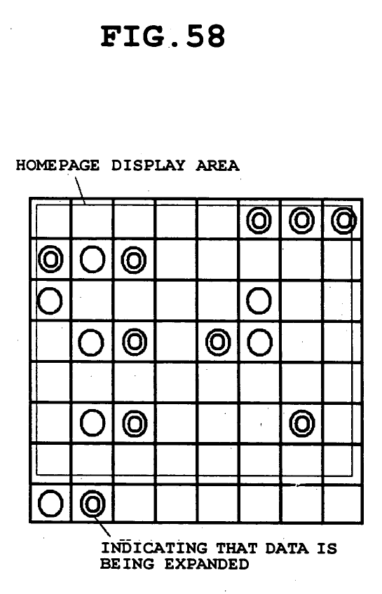

Next, the user confirms that a function of “connect” is assigned to a key top in a level under the “browse homepage” by clicking a key top, and then double-clicks the key top of “connect”. Then, a homepage browsing program connects the personal computer with the Internet by controlling a modem and downloads homepage data of a predetermined address. Then, the homepage browsing program analyzes structural descriptors included in HTML data as necessary and appropriately represents the homepage according to the number of the key tops that can be used in the desktop area. Accordingly, the homepage is represented with a setting state of the key tops shown in FIG. 58. Therefore, the user can browse necessary information by properly operating the key tops.

On the other hand, as shown in FIG. 56, a group of key tops next the “start key” on the right in the bottom row is a “task bar”, which corresponds to a “task bar” adopted in the mainstream OS. The key tops 1 attributing to the “task bar” are assigned a window which is generated by the program booted according to the “start key”. In FIG. 58, a window of the homepage browsing software being displayed in the desktop area is assigned.

The key tops included in the task bar are highlighted such that the key tops are raised to a high position when subordinate information included in the window corresponding to the key tops are expanded and displayed. When the subordinate information is not expanded, the key tops included in the tack bar are set to a low position. This display form corresponds to the invention claimed in claim 9. As to the key top included in the task bar which is obvious that subordinate information ahs already been assigned to the key top, a setting of identification state of the key top is used to determine whether the information has been expanded.

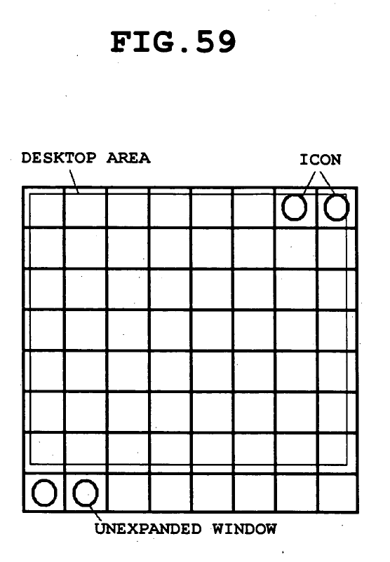

If the control program is appropriately implemented so that states between an expanded state and an unexpanded state to the desktop area can be switched when the key top in the task bar is double-clicked, the key top in the limited desktop area can be used while a plurality of windows are being switched. To be more specific, when the key top in the task bar of FIG. 58 is double-clicked, nothing is displayed in the desktop area and the key tops become in a state shown in FIG. 59.

A document or a program to be frequently used may be assigned to a key top at a predetermined position in the desktop and may be stored as an “icon”. The two key tops in the upper right position in FIG. 56 show key tops to which the “letter” and the “snap” are assigned according to additional predetermined procedure.

If the key top is used as an icon, a document or a function can be easily accessed only by operating the icon in a customary place on the tactile input/output apparatus when none of windows is expanded in the desktop. To be more specific, when a key top is clicked, a document name assigned to the key top is represented. When the key top is double-clicked, the document can be expanded and represented.

As described above, the function of the personal computer is executed as necessary by operating the start key, and information can be browsed and edited using a desired function of the personal computer while the desktop area is effectively used. Therefore, the visually impaired person who is unaccustomed to operation can easily use the tactile input/output apparatus.

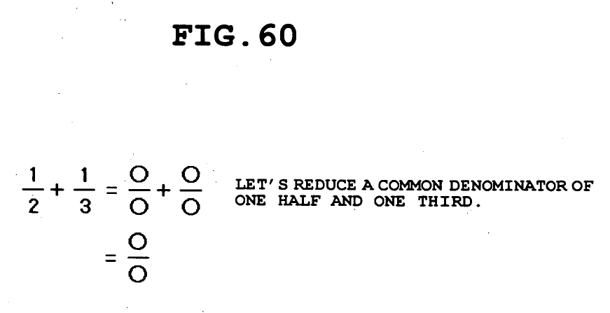

Finally, an application that is useful to a case in which a child who is visually impaired learns arithmetic will be described. FIG. 60 is a diagram showing a material for learning a fraction in which children have trouble.

In the figure, a question is an addition of one-half and one-third. An equation in which no numerals are provided is descried in accordance with a step of reducing to a common denominator and a step of adding a numerator of a fraction which is reduced its common denominator. On the question sheet, an explanation is written to tell which numerals are provided in the blanks. Children solve the question referring the advice.

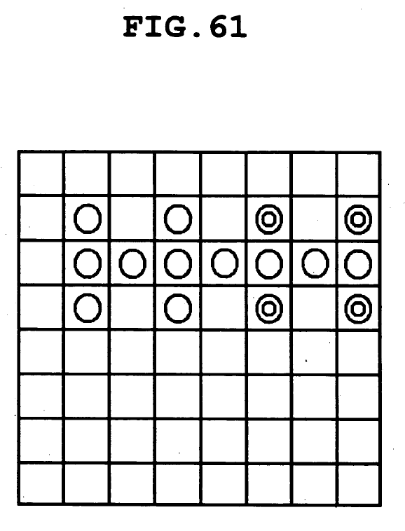

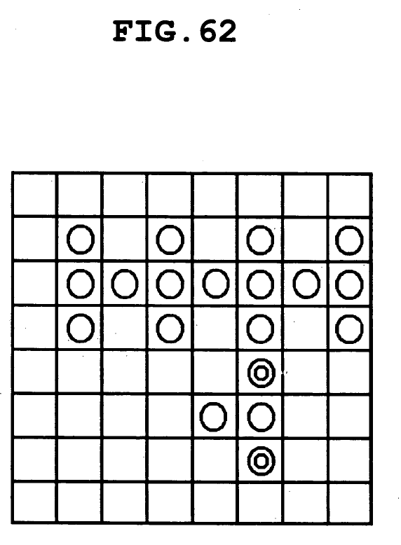

FIG. 61 is a diagram showing an early step of the question represented using the tactile input/output apparatus of the invention. FIG. 62 is a diagram showing a final step of the learning.

As is seen from the figures, the key tops are displayed at position where correspond to numerals, a bar of a fraction, a plus, and an equal sign. For example, three key tops aligned on the extreme left correspond to “1”, “-” and “3” in this order from the top. When the key tops are clicked in the order from the bottom, a voice that “three”, “over”, “one” is represented. The key tops aligned on the extreme right correspond to an “answer space”, “-”, and an “answer space” in this order from the bottom. The key tops correspond to the “answer space” are highlighted and show that they are a space for an answer. When the child keeps pressing on the key of the common denominator, a voice message such that “let's reduce to a common denominator of one-half and one-third” is represented for a hint for thinking.

As the child heard the hint, the child confirms that the common denominators of the fraction in a left part are “2” and “3” by touching the key tops and the child should answer “6” in each common denominator of a right part. Then, the child clicks the key tops of the common denominators of the right part and input “six” by voice. As a result, the answer “6” can be input in the spaces for the common denominators.

Likewise, the child inputs an answer into the numerators. The control program determines that the answer is correct and proceeds to a next step. The key tops become a display pattern as shown in FIG. 62.

By touching the display pattern of newly displayed key tops, the child obtains a hint that the fractions can be combined. Therefore, the child inputs “5” and “6” into the blanks of the key tops in the same manner. Then, the control program determined that the question is solved and a voice massage such that “good.” is output.

As described above, question of arithmetic, which needs to be recognized using a hierarchical conception, such as a positional relationship of numerals and symbols can be effectively performed by applying the invention.

The question sheet of the fraction calculation is an easy example such that blanks of the predetermined equation are input by numerals. However, it is needless to say that an equation having a complicated structure can be used for high-level learning by hierarchically inputting the structure by the user if the invention is applied.

### INDUSTRIAL APPLICABILITY

As described above, an information processing apparatus for the visually impaired according to the invention is useful as an information browsing apparatus and a document preparing apparatus for the visually impaired, and a tactile input/output apparatus according to the invention is useful as an input/output apparatus for the information processing apparatus for the visually impaired.

1. An information processing apparatus for the visually impaired, comprising:
a plurality of tactile operation means that can be set in two or more identification states based on tactile operation with a fingertip in a predetermined area that is one of areas individually set, the tactile operation means that are arranged in a two-dimensional matrix with rows and columns so that the operation performed in the predetermined area can be detected;
operation signal selecting means that selects and outputs an operation signal corresponding to a predetermined operating method based on the operation performed in the predetermined area;
information storage means that stores information having a data structure that can be two-dimensionally expanded, by dividing the information into a plurality of pieces of block unit information, and stores a correspondence between the block information and the plurality of tactile operation means;
information setting means that sets predetermined information in the information storage means;
tactile operation means setting means that sets the plurality of the tactile operation means in respective predetermined states based on the tactile operation means setting information;
tactile operation means setting information supply means that receives input of information related to a correspondence with the tactile operation means stored in the information storage means and supplies the tactile operation means setting information to the tactile operation means setting means;
sound generating means that generates sound by inputting sound related information;
sound related information supply means that receives input of the operation signal and selects and supplies the sound related information by reading the block unit information corresponding to the operated tactile operation means; and
information modification means that receives input of the operation signal and modifies a content in the information storage means in accordance with the operated tactile operation means.

2. The information processing means for the visually impaired as claimed in claim 1, wherein at least one piece of block unit information include display information regarding a display and attribute information regarding the display information, the operation signal selecting means selects at least a display browse signal according to operation for browsing the display information and an attribute browse signal according to operation for browsing the attribute information, and the sound related information supply means generates sound related to the display information of the block unit information assigned to the tactile operation means when receiving input of the display browse signal, and generates sound related to the attribute information of the block unit information assigned to the tactile operation means when receiving the attribute browse signal.

3. The information processing apparatus for the visually impaired as claimed in claim 1, wherein the information having a data structure that can be two-dimensionally expanded includes information related to functions of a predetermined apparatus structured with unit functions, at least one piece of the block unit information includes unit function information regarding performance of the unit function and attribute information that is attribute information of the unit function, the operation signal selecting means selects at least unit function performing operation signal according to operation for performing the unit function and attribute browse information according to operation for browsing the attribute information, the sound related information supply means generates sound related to the attribute information of the block unit information assigned to the tactile operation means when receiving input of the attribute browse information and the sound related information supply means includes unit function performing means that performs the unit function, and the unit function performing means performs the unit function based on the unit function information included in the block unit information assigned to the tactile operation means when receiving input of the unit function performing operation signal.

4. The information processing apparatus for the visually impaired as claimed in claim 1, wherein the block unit information can be hierarchically structured so that one piece of the block unit information is assigned to one or more pieces of subordinate block unit information, the operation signal selecting means can select a subordinate level expanding signal generated according to operation for expanding information in a subordinate level of the block unit information corresponding to the operated tactile operation means, and the information modification means modifies at least the information related to a correspondence with the tactile operation means so that the block unit information in the subordinate level of the block unit information corresponding to the operated tactile operation means is newly assigned to the tactile operation means when receiving input of the subordinate level expanding signal.

5. The information processing apparatus for the visually impaired as claimed in claim 4, wherein the information related to a correspondence with the tactile operation means is set so that the plurality of block information included in a corresponding level correspond to a layout at the time when the block unit information are displayed or printed.

6. The information processing apparatus for the visually impaired as claimed in claim 4, wherein a direction of depth of a hierarchical structure of data of the information related to a correspondence with the tactile operation means is assigned to one direction in the matrix of the tactile operation means and a direction of a list of the block unit information included in the same level is assigned to a direction perpendicular to the one direction.

7. The information processing apparatus for the visually impaired as claimed in claim 6, wherein the information modification means is structured to modify the information related to a correspondence with the tactile operation means so that the information in the subordinate level of the block unit information corresponding to the operated tactile operation means is assigned to the tactile operation means other than the operated tactile means when receiving input of the subordinate level expanding signal.

8. The information processing apparatus for the visually impaired as claimed in claim 4, wherein the identification states that are set to the tactile operation means can be set in at least three states or more, wherein at least one identification state is used to indicate to effect that the block unit information corresponding to predetermined tactile operation means can be expanded in associated with the block unit information in the subordinate level or that the block unit information corresponding to the predetermined tactile operation means has been already expanded and displayed by other tactile operation means.

9. The information processing apparatus for the visually impaired as claimed in claim 8, wherein the tactile operation means can be set in a another state, which indicates the block unit information in the subordinate level corresponding to the predetermined tactile operation means has been already expanded and displayed by the other tactile operation means, being different from a state indicating that the block unit information has not been expanded yet, when the block unit information corresponding to the tactile operation means is expandable in conjunction with the block unit information in the subordinate level.

10. The information processing apparatus for the visually impaired as claimed in claim 1, wherein the tactile operation means are classified into a plurality of groups, and the sound related information supply means outputs an area identification sound assigned to each block unit information to discriminate a group, to which the operated tactile operation means attributes, from other groups when generating sound regarding the attribute information.

11. The information processing apparatus for the visually impaired as claimed in claim 1, wherein the tactile operation means setting means is structured so that a setting operational status can be recognized by sound.

12. The information processing apparatus for the visually impaired as claimed in claim 1, wherein the tactile operation means provides a plurality of identification states with amount of protrusion of an operating portion from a predetermined reference plane.

13. The information processing apparatus for the visually impaired as claimed in claim 1, wherein the tactile operation means provides the plurality of identification states by a sound pattern output based on pressing operation performed on the operating portion set in the predetermined area which is one of the areas individually set.

14. The information processing apparatus for the visually impaired as claimed in claim 1, further comprising:
vibration means that can transmit vibrations to a fingertip touching the predetermined area which is one of the areas individually set,
wherein the tactile operation means provides the plurality of the identification states by a vibration pattern of the vibration means.

15. The information processing apparatus for the visually impaired as claimed in claim 14, wherein the tactile operation means includes fingertip detecting means that detects an approach of the fingertip to the predetermined area which is one of the area individually set, and the vibration means vibrates upon detecting the approach of the fingertip by the fingertip detecting means.

16. The information processing apparatus for the visually impaired as claimed in claim 1, wherein the tactile operation means includes a tactile portion, such as a protrusion, that is disposed in the predetermined area which is one of the areas individually set and that can be recognized by tactile sense and includes the fingertip detecting means that detects the approach of the fingertip to the tactile portion, and the tactile operation means provides the plurality of the identification means by sound output upon detecting the approach of the fingertip by the fingertip detecting means.

17. The information processing apparatus for the visually impaired as claimed in claim 1, wherein the tactile operation means is structured to detect a pressing operated by the fingertip in the predetermined area which is one of the areas individually set.

18. The information processing apparatus for the visually impaired as claimed in claim 1, wherein a sequence of setting operation of the plurality of the tactile operation means is changed in accordance with a position of the operated tactile operation means.

19. The information processing apparatus for the visually impaired as claimed in claim 1, wherein the tactile operation means includes the fingertip detecting means that detects existence of the fingertip in the predetermined area, which is one of the areas individually set, and is provided with auxiliary operation means that detects auxiliary input operation performed out of the predetermined area, and the operation signal selecting means is structured to select and output an operation signal corresponding to a predetermined operation based on the auxiliary input operation via the auxiliary operation means and results of detection by the fingertip detecting means.

20. The information processing apparatus for the visually impaired as claimed in claim 1, further comprising:
updated information input means that receives input of updated information,
wherein the information modification means changes the stored content of the information storage means related to the operated tactile operation means based on information input from the updated information input means on the basis of the operated tactile operation means.

21. The information processing apparatus for the visually impaired as claimed in claim 20, wherein the updated information input means includes voice input means that selects text information from a voice signal input from a microphone.

22. The information processing apparatus for the visually impaired as claimed in claim 1, further comprising:
operating time totaling means that sums operating time information of the information processing apparatus,
wherein t operation for directing to perform maintenance of the information processing apparatus is started based on the operating time information.

23. The information processing apparatus for the visually impaired as claimed in claim 1, wherein the information setting means includes information input means that receives input of information having a data structure that can be two-dimensionally expanded, grouping means that divides information into a plurality of groups based on a structural descriptor included in the input information, hierarchical structure selecting means that selects a hierarchical structure of the groups when a parent-child relationship is established between the plurality of the groups, group area selecting means that obtains information related to an area which is occupied by information included in the groups at the time when the information is displayed or printed, and mapping means: that sets a correspondence between the plurality of the groups and at least one of the tactile operation means to be used in a display state of any level, wherein the information setting means sets the block unit information and the information related to a correspondence with the tactile operation means based on the information included in the groups and the information set by the mapping means.

24. A tactile input/output apparatus that includes a mechanical clutch mechanism disposed at some midpoint in a drive force-transfer path to selectively drive a plurality of up-and-down key tops using a single drive motor, the tactile input/output apparatus comprising:
a frame;
a motor mounting frame;
a plurality of drive motors fixed to the motor mounting frame;
a drive motor controller;
drive force output units attached to an output shaft of each drive motor;
a plurality of key units that each includes an up-and-down key top having an operation input portion, up-and-down key top moving means that moves the up-and-down key top in up and down directions, and an operation detector that detects pressing operation by a fingertip touching the up-and-down key top, the key units disposed to the frame at positions with respect to one drive motor; and
positioning driving means that respectively drives the frame and the motor mounting frame in a parallel direction without rotation, and connects the drive force output units of the drive motors to the up-and-down key top moving means of arbitrary key units of the plurality of the key units disposed to the frame with respect to the drive motor.

25. The tactile input/output apparatus as claimed in claim 24, wherein the key units are disposed at corners of a rectangular formed by which the drive force output unit of the corresponding drive motor is as its center.

26. The tactile input/output apparatus as claimed in claim 24, wherein the drive motors are pulse motors, the drive force output units are drive gears fixedly attached to a rotation output shaft of each drive motor, the up-and-down key top moving means is structured with a driven gear that is rotated by engaging the drive gear, and the key units are structured so as to take a first mounting position that the drive gear normally engages the driven gear and a second mounting position that the key unit is displaced to absorb an abutment of teeth of the drive gear and the driven gear and is structured to return to the first mounting position from the second mounting position by a urging force from an elastic member.

27. The tactile input/output apparatus having the up-and-down key tops as claimed in claim 26, wherein an upper portion of the up-and-down key tops is slidably guided in the up-and-down direction along a guide hole formed in the frame, a lower portion of the up-and-down key tops is connected to the up-and-down key top moving means, and the up-and-down key tops swing about a portion guided by the guide holes with evacuation of the driven gear in a horizontal direction.

28. The tactile input/output apparatus as claimed in claim 25, wherein the up-and-down key tops are formed with a portion input pressing operation at their upper portion, the up-and-down key tops and the up-and-down moving means are connected each other by screws or cams and are structured so that the up-and-down key tops move up and down with respect to the up-and-down key top moving means with rotation of the up-and-down key top moving means, some of the up-and-down moving means contact the operation detecting means and are supported by operation detecting means from a bottom, and the some of the up-and-down moving means are structured so that pressing operation input to the up-and-down key top is detected by the operation detecting means via the up-and-down key top moving means.

29. The tactile input/output apparatus as claimed in claim 28, wherein the key top moving means is regulated its upward movement with respect to the frame, the up-and-down key tops and the key top moving means are structured so that origin pressing means, that presses the operation detecting means at a portion where the up-and-down key top moving means contacts the operation detecting means under the up-and-down key top moving means, protrudes as the up-and-down key top reaches a standard position with respect to the up-and-down key top moving means of the up-and-down key top by descending and to detect the standard position with respect to the up-and-down key top moving means by detecting a pressing of the operation detecting means by the origin pressing means.

30. The information processing apparatus for the visually impaired as claimed in claim 1, further comprising:
state information storing means that stores state information, that includes at least correspondence information included in the information storage means and can reproduce a state of the information processing apparatus that reflects a history of the operation performed by the user, into nonvolatile information storage means; and
state information reading means that reproduces a state of the information processing apparatus by reading the stored state information.
